(19) United States
(12) Patent Application Publication
(10) Pub. No.: US 2025/0301854 A1
(43) Pub. Date: Sep. 25, 2025

(54) ORGANIC OPTOELECTRONIC DEVICE AND DISPLAY DEVICE

(71) Applicant: SAMSUNG SDI CO., LTD., Yongin-si (KR)

(72) Inventors: Youngkyoung JO, Suwon-si (KR); Seungchul LYU, Suwon-si (KR); Youngmook LIM, Suwon-si (KR); Kyoungrok KIM, Suwon-si (KR); Ho Kuk JUNG, Suwon-si (KR); Mijin LEE, Suwon-si (KR); Hyung Sun KIM, Suwon-si (KR); Jongwoo WON, Suwon-si (KR); Sunwoong SHIN, Suwon-si (KR); Junghoon KIM, Suwon-si (KR); Gibeom PARK, Suwon-si (KR); Hyunseung KIM, Suwon-si (KR)

(21) Appl. No.: 19/052,419

(22) Filed: Feb. 13, 2025

(30) Foreign Application Priority Data
Mar. 22, 2024 (KR) 10-2024-0039902

(51) Int. Cl. H10K 50/13; H10K 50/15; H10K 50/16; H10K 50/19; H10K 59/12; H10K 85/60

(52) U.S. Cl. CPC H10K 50/13; H10K 50/15; H10K 50/16; H10K 50/19; H10K 59/12; H10K 85/633

(57) ABSTRACT

An organic optoelectronic device includes an anode and a cathode facing each other, at least one first light emitting layer between the anode and the cathode, the at least one first light emitting layer being configured to emit light of a first wavelength, at least one second light emitting layer between the anode and the cathode, the at least one second light emitting layer being configured to emit light of a second wavelength different from the first wavelength, and at least one charge generation layer between the first light emitting layer and the second light emitting layer, the charge generation layer including a first compound represented by Chemical Formula 1 and a second compound represented by Chemical Formula 2,

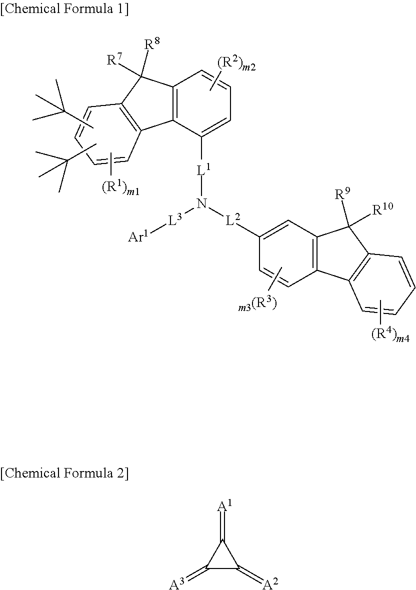

### CROSS-REFERENCE TO RELATED APPLICATION

This application claims priority to and the benefit of Korean Patent Application No. 10-2024-0039902, filed in the Korean Intellectual Property Office on Mar. 22, 2024, the entire contents of which are incorporated herein by reference.

### BACKGROUND

### 1. Field

An organic optoelectronic device and a display device are disclosed.

### 2. Description of the Related Art

An organic optoelectronic device (e.g., organic optoelectronic diode) is a device capable of converting electrical energy and optical energy to each other. Organic optoelectronic devices may be largely divided into two types according to a principle of operation. One is a photoelectric device that generates electrical energy by separating excitons formed by light energy into electrons and holes, and transferring the electrons and holes to different electrodes, respectively, and the other is a light emitting device that generates light energy from electrical energy by supplying voltage or current to the electrodes.

Examples of the organic optoelectronic devices include an organic photoelectric device, an organic light emitting diode, an organic solar cell, and an organic photoconductor drum. Among the organic optoelectronic devices, organic light emitting diodes (OLEDs) are attracting much attention in recent years due to increasing demands for flat panel display devices. The organic light emitting diode is a device that converts electrical energy into light, and the performance of the organic light emitting diode is greatly influenced by the organic material between the electrodes of the organic light emitting diode.

### SUMMARY

According to some embodiments, an organic optoelectronic device includes an anode and a cathode facing each other, at least one first light emitting layer that emits light of a first wavelength and at least one second light emitting layer that emits light of a second wavelength different from the first wavelength which are located between the anode and the cathode, and at least one charge generation layer between the first light emitting layer and the second light emitting layer, wherein the charge generation layer includes a first compound represented by Chemical Formula 1 and a second compound represented by Chemical Formula 2.

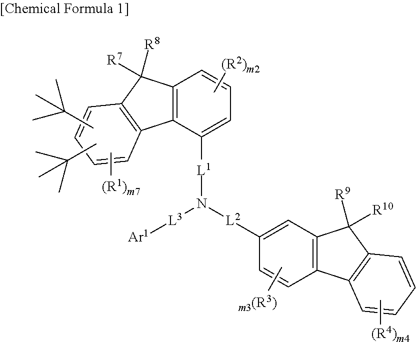

In Chemical Formula 1, L¹ to L³ are each independently a single bond, a substituted or unsubstituted C6 to C20 arylene group, or a substituted or unsubstituted C2 to C30 heterocyclic group, Ar¹ is a substituted or unsubstituted C6 to C20 aryl group or a substituted or unsubstituted C2 to C30 heterocyclic group, R¹ to R⁴ are each independently hydrogen, deuterium, a cyano group, a substituted or unsubstituted C1 to C30 alkyl group, a substituted or unsubstituted C6 to C30 aryl group, or a substituted or unsubstituted C2 to C30 heterocyclic group, R⁷ to R¹⁰ are each independently a substituted or unsubstituted C1 to C30 alkyl group, or a substituted or unsubstituted C6 to C30 aryl group, m1 is an integer of 1 or 2, m2 and m3 are each independently one of integers of 1 to 3, m4 is one of integers of 1 to 4, when m1 is 2, each R¹ is the same or different from each other, when m2 is 2 or more, each R² is the same or different from each other, when m3 is 2 or more, each R³ is the same or different from each other, and when m4 is 2 or more, each R⁴ is the same or different from each other,

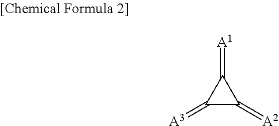

wherein, in Chemical Formula 2, A¹ is represented by Chemical Formula 2a,

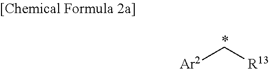

A² is represented by Chemical Formula 2b,

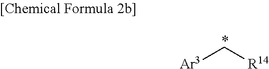

A³ is represented by Chemical Formula 2c,

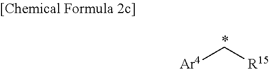

wherein, in Chemical Formula 2a, Chemical Formula 2b, and Chemical Formula 2c, Ar² to Ar⁴ are each independently a substituted or unsubstituted C6 to C20 aryl group or a substituted or unsubstituted C2 to C30 heterocyclic group, R¹³ to R¹⁵ are each independently hydrogen, deuterium, halogen, a cyano group, a nitro group, a substituted or unsubstituted C1 to C30 alkyl group, a substituted or unsubstituted C1 to C30 alkoxy group, a substituted or unsubstituted C6 to C20 aryl group, or a substituted or unsubstituted C2 to C30 heterocyclic group, and * is a linking point with the double bond.

According to some embodiments, a display device including the aforementioned organic optoelectronic device is provided.

### BRIEF DESCRIPTION OF THE DRAWINGS

Features will become apparent to those of skill in the art by describing in detail exemplary embodiments with reference to the attached drawings, in which:

FIGS. 1 to 4 are cross-sectional views showing organic light emitting diodes according to various embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

As used herein, when a definition is not otherwise provided, “substituted” refers to replacement of at least one hydrogen of a substituent or a compound by deuterium, a halogen, a hydroxyl group, an amino group, a substituted or unsubstituted C1 to C30 amine group, a nitro group, a substituted or unsubstituted C1 to C40 silyl group, a C1 to C30 alkyl group, a C1 to C10 alkylsilyl group, a C6 to C30 arylsilyl group, a C3 to C30 cycloalkyl group, a C3 to C30 heterocycloalkyl group, a C6 to C30 aryl group, a C2 to C30 heteroaryl group, a C1 to C20 alkoxy group, a C1 to C10 trifluoroalkyl group, a cyano group, or a combination thereof.

In one example of embodiments, the “substituted” refers to replacement of at least one hydrogen of a substituent or a compound by deuterium, a C1 to C30 alkyl group, a C1 to C30 haloalkyl group, a C1 to C10 alkylsilyl group, a C6 to C30 arylsilyl group, a C3 to C30 cycloalkyl group, a C3 to C30 heterocycloalkyl group, a C6 to C30 aryl group, a C2 to C30 heteroaryl group, a halogen, a nitro group, or a cyano group. In example embodiments, the “substituted” refers to replacement of at least one hydrogen of a substituent or a compound by deuterium, a C1 to C20 alkyl group, a fluoroalkyl group, a perfluoroalkyl group, C6 to C30 aryl group, fluoro, chloro, or a cyano group. In example embodiments, the “substituted” refers to replacement of at least one hydrogen of a substituent or a compound by deuterium, a C1 to C5 alkyl group, a fluoroalkyl group, a perfluoroalkyl group, a C6 to C18 aryl group, fluoro, chloro, or a cyano group. In example embodiments, the “substituted” refers to replacement of at least one hydrogen of a substituent or a compound by deuterium, a cyano group, fluoro, chloro, a methyl group, an ethyl group, a propyl group, a butyl group, a fluoroalkyl group, a perfluoroalkyl group, a phenyl group, a biphenyl group, a terphenyl group, or a naphthyl group.

“Unsubstituted” refers to non-replacement of a hydrogen atom by another substituent and remaining of the hydrogen atom.

In the present specification, “hydrogen substitution (—H)” may include “deuterium substitution (-D)” or “tritium substitution (-T).”

As used herein, when a definition is not otherwise provided, “hetero” refers to one including one to three heteroatoms selected from N, O, S, P, and Si, and remaining carbons in one functional group.

As used herein, “aryl group” refers to a group including at least one hydrocarbon aromatic moiety, and all elements of the hydrocarbon aromatic moiety have p-orbitals which form conjugation, e.g., a phenyl group, a naphthyl group, and the like, two or more hydrocarbon aromatic moieties may be linked by a sigma bond and may be, e.g., a biphenyl group, a terphenyl group, a quarterphenyl group, and the like, and two or more hydrocarbon aromatic moieties are fused directly or indirectly to provide a non-aromatic fused ring, e.g., a fluorenyl group.

The aryl group may include a monocyclic, polycyclic, or fused ring polycyclic (i.e., rings sharing adjacent pairs of carbon atoms) functional group.

As used herein, “heterocyclic group” is a generic concept of a heteroaryl group, and may include at least one heteroatom selected from N, O, S, P, and Si instead of carbon (C) in a cyclic compound such as aryl group, a cycloalkyl group, a fused ring thereof, or a combination thereof. When the heterocyclic group is a fused ring, the entire ring or each ring of the heterocyclic group may include one or more heteroatoms.

For example, “heteroaryl group” may refer to aryl group including at least one heteroatom selected from N, O, S, P, and Si. Two or more heteroaryl groups are linked by a sigma bond directly, or when the heteroaryl group includes two or more rings, the two or more rings may be fused. When the heteroaryl group is a fused ring, each ring may include one to three heteroatoms.

More specifically, the substituted or unsubstituted C6 to C30 aryl group may be a substituted or unsubstituted phenyl group, a substituted or unsubstituted naphthyl group, a substituted or unsubstituted anthracenyl group, a substituted or unsubstituted phenanthrenyl group, a substituted or unsubstituted naphthacenyl group, a substituted or unsubstituted pyrenyl group, a substituted or unsubstituted biphenyl group, a substituted or unsubstituted p-terphenyl group, a substituted or unsubstituted m-terphenyl group, a substituted or unsubstituted o-terphenyl group, a substituted or unsubstituted chrysenyl group, a substituted or unsubstituted benzophenanthrenyl group, a substituted or unsubstituted triphenylene group, a substituted or unsubstituted perylenyl group, a substituted or unsubstituted fluorenyl group, a substituted or unsubstituted indenyl group, or a combination thereof.

More specifically, the substituted or unsubstituted C2 to C30 heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzothiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted carbazolyl group, a substituted or unsubstituted dibenzofuranyl group, a substituted or unsubstituted dibenzothiophenyl group, a substituted or unsubstituted benzonaphthofuranyl group, a substituted or unsubstituted benzonaphthothiophenyl group, a substituted or unsubstituted benzofuranofluorenyl group, a substituted or unsubstituted benzothiophenefluorenyl group, or a combination thereof.

As used herein, hole characteristics refer to an ability to donate an electron to form a hole when an electric field is applied and that a hole formed in the anode may be easily injected into the light emitting layer and transported in the light emitting layer due to conductive characteristics according to a highest occupied molecular orbital (HOMO) level.

In addition, electron characteristics refer to an ability to accept an electron when an electric field is applied and that electron formed in the cathode may be easily injected into the light emitting layer and transported in the light emitting layer due to conductive characteristics according to a lowest unoccupied molecular orbital (LUMO) level.

In this specification, Dn refers to the number of deuterium substitutions and can be selected from any integer of 1 or more.

The organic optoelectronic device may be a suitable device to convert electrical energy into photoenergy and vice versa, e.g., an organic photoelectric device, an organic light emitting diode, an organic solar cell, or an organic photoconductor drum.

Here, an organic light emitting diode, which is an example of an organic optoelectronic device, is described as an example, but may be equally applied to other organic optoelectronic devices.

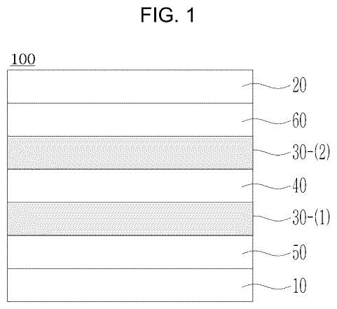

FIGS. 1 to 4 are cross-sectional views showing organic light emitting diodes according to various embodiments. Hereinafter, an organic light emitting diode according to some embodiments will be described with reference to FIGS. 1 to 4.

Referring to FIG. 1, an organic light emitting diode 100 according to some embodiments may include an anode 10 and a cathode 20 facing each other, and a first light emitting layer 30-(1) between the anode 10 and the cathode 20 and a second light emitting layer 30-(2). At least one charge generation layer 40 may be located between the first light emitting layer 30-(1) and the second light emitting layer 30-(2).

The anode 10 may be made of a conductor having a large work function to help hole injection, and may be, e.g., a metal, a metal oxide and/or a conductive polymer. The anode 10 may be, e.g., a metal such as nickel, platinum, vanadium, chromium, copper, zinc, gold, or silver or an alloy thereof, a metal oxide such as zinc oxide, indium oxide, indium tin oxide (ITO), or indium zinc oxide (IZO); a combination of a metal and an oxide such as ITO and Ag, ZnO and Al, or SnO₂ and Sb, and may have, e.g., a two-layer structure of ITO/Ag and a three-layer structure of ITO/Ag/ITO. In addition, the conductive polymer, e.g., poly(3-methylthiophene), poly(3,4-(ethylene-1,2-dioxy)thiophene) (polyethylenedioxythiophene: PEDOT), polypyrrole, and polyaniline may be included.

The cathode 20 may be made of a conductor having a small work function to help electron injection, and may be, e.g., a metal, a metal oxide, and/or a conductive polymer. The cathode 20 may be, e.g., a metal such as magnesium, calcium, sodium, potassium, titanium, indium, yttrium, lithium, gadolinium, aluminum silver, tin, lead, cesium, barium, and the like, or an alloy thereof; a multi-layer structure material such as LiF/Al, LiO₂/Al, LiF/Ca, and BaF₂/Ca.

In addition, a hole transport region 50 may be located between the anode 10 and the first light emitting layer 30-(1), and an electron transport region 60 may be located between the cathode 20 and the second light emitting layer 30-(2).

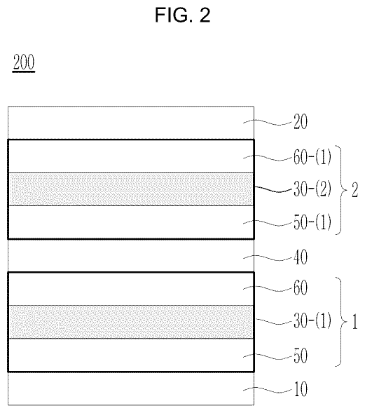

Meanwhile, FIG. 2 illustrates an example of a tandem-type organic light emitting diode having a plurality of stacks between a pair of electrodes as an organic light emitting diode 200 according to some embodiments.

Referring to FIG. 2, the organic light emitting diode 200 according to some embodiments may include a first stack 1 located between the anode 10 and the cathode 20 and including the first light emitting layer 30-(1); and a second stack 2 located between the first stack 1 and the cathode 20 and including the second light emitting layer 30-(2). The organic light emitting diode 200 may further include at least one charge generation layer 40 between the first stack 1 and the second stack 2, wherein the first stack 1 and the second stack 2 each independently form hole transport regions 50 and 50-(1) and electron transport regions 60 and 60-(1) between the anode 10 and the cathode 20.

The configurations of the first light emitting layer 30-(1) and the second light emitting layer 30-(2) may be the same or different from each other. The first light emitting layer 30-(1) may emit light of a first wavelength, and the second light emitting layer 30-(2) may emit light of a second wavelength different from the first wavelength. For example, the first wavelength may be greater than or equal to about 420 nm and less than or equal to about 480 nm, and the second wavelength may be greater than or equal to about 520 nm and less than or equal to about 600 nm.

The charge generation layer 40 has the function of injecting electrons into one stack and holes into the other stack when a voltage is applied to the anode 10 and the cathode 20. In the case of this embodiment, when a voltage is applied to the cathode 20 so that the potential is higher than that of the anode 10, electrons are injected from the charge generation layer 40 into the first stack 1 and holes are injected into the second stack 2.

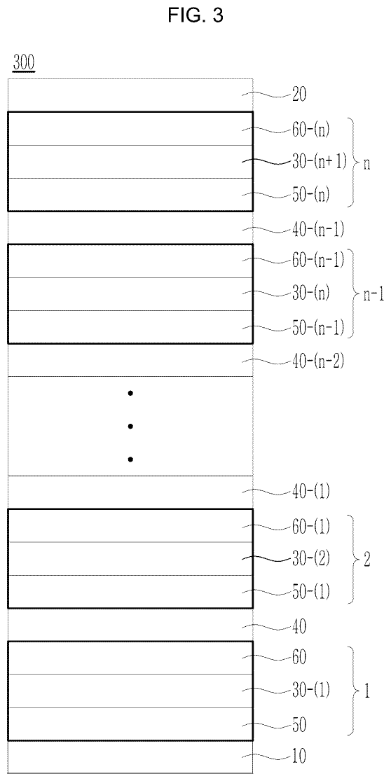

For example, referring to FIG. 2, an organic light emitting diode may include a two-layer stack. In another example, referring to FIG. 3, an organic light emitting diode 300 may include more than two stacks, e.g., in which stacks (1) to (n) of n layers (where n is 3 or more) are stacked, that are implemented in the same way.

Referring to FIG. 3, when having a plurality of stacks between a pair of electrodes, charge generation layers 40 to 40-(n−1) may be located between the stacks, and the configuration of each stack is the same as described above. When a charge generation layer is included between a plurality of stacks, light emission in a high luminance region is possible while maintaining a low current density. Because the current density can be kept low, a long life-span device can be realized. Additionally, because the voltage drop due to the resistance of the electrode material can be reduced, uniform light emission over a large area becomes possible.

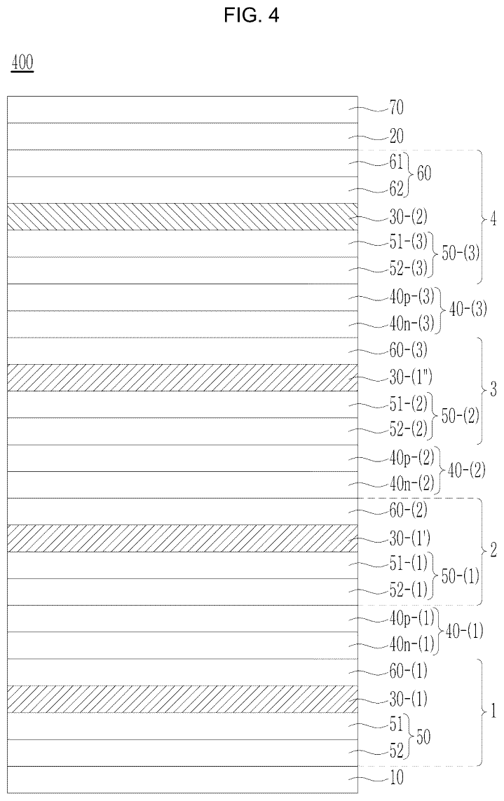

Meanwhile, an example of a tandem-type organic light emitting diode 400, which is an organic light emitting diode including a plurality of stacks according to FIG. 3 and has four stacks between a pair of electrodes, will be described in FIG. 4.

Referring to FIG. 4, the organic light emitting diode 400 according to some embodiments includes a plurality of stacks 1, 2, 3, and 4 located between the anode 10 and the cathode 20 facing each other. The plurality of stacks 1, 2, 3, and 4 may include a first stack 1, a second stack 2, a third stack 3 and a fourth stack 4. Each of the first stack 1, the second stack 2, the third stack 3, and the fourth stack 4 may include a light emitting layer. For example, in FIG. 4, the organic light emitting diode 400 is exemplarily shown to include a total of four stacks 1, 2, 3, and 4, but the organic light emitting diode may include two, three, or five or more stacks. For example, in the structure of the organic light emitting diode 400 shown in FIG. 4, the second stack 2 and the third stack 3 are omitted, and the first stack 1 and the fourth stack 4 are two stacks. An organic light emitting diode structure having two stacks is illustrated in FIG. 2.

In the organic light emitting diode 400 according to some embodiments, the hole transport region 50 may be located between the anode 10 and the plurality of stacks 1, 2, 3, and 4. The electron transport region 60 may be located between the cathode 20 and the plurality of stacks 1, 2, 3, and 4. In some embodiments, the organic light emitting diode 400 may emit light from the anode 10 to the cathode 20. For example, the organic light emitting diode 400 according to some embodiments, may have a structure in which, based on the direction in which light is emitted, the hole transport region 50 is located under the plurality of stacks 1, 2, 3, and 4, and the electron transport region 60 is located on the plurality of stacks 1, 2, 3, and 4. In another example, the organic light emitting diode 400 may have an inverted device structure in which, based on the direction in which light is emitted, the electron transport region 60 may be located under the plurality of stacks 1, 2, 3, and 4, and the hole transport region 50 may be located on the plurality of stacks 1, 2, 3, and 4.

The organic light emitting diode 400 of some embodiments may include the electron transport region 60 located under the cathode 20. The electron transport region 60 may include an electron transport layer 62 on the first light emitting layers 30-(1), 30-(1′), and 30-(1″) and the second light emitting layer 30-(2), and an electron injection layer 61 on the electron transport layer 62. An auxiliary electron transport layer may be further included between the second light emitting layer 30-(2) and the electron transport layer 62. The electron injection layer 61 may be located under the cathode 20 and may serve to smoothly move electrons injected from the cathode 20 to the light emitting layer 30-(1), 30-(1′), 30-(1″), and 30-(2). For example, in the organic light emitting diode 400 shown in FIG. 4, the electron injection layer 61 serves to smoothly move electrons injected into the cathode 20 to the second light emitting layer 30-(2). The electron injection layer 61 may be located between the cathode 20 and the electron transport layer 62. The electron injection layer 61 may be located directly on the lower surface of the cathode 20. The upper surface of the electron injection layer 61 and the lower surface of the cathode 20 may be in contact (e.g., direct contact) with each other. The electron injection layer 61 may include magnesium (Mg) and ytterbium (Yb). The electron injection layer 61 may be composed (e.g., consist essentially) of magnesium (Mg) and ytterbium (Yb).

The organic light emitting diode 400 according to some embodiments may include charge generation layers 40-(1), 40-(2), and 40-(3) disposed between a plurality of stacks 1, 2, 3, and 4. The organic light emitting diode 400 according to some embodiments may include a first charge generation layer 40-(1) between the first stack 1 and the second stack 2, a second charge generation layer 40-(2) between the second stack 2 and third stack 3, and a third charge generation layer 40-(3) between the third stack 3 and the fourth stack 4.

Each of the charge generation layers 40-(1), 40-(2), and 40-(3) may have a layer structure that each n-type charge generation layer 40n-(1), 40n-(2), and 40n-(3) and each p-type charge generation layers 40p-(1), 40p-(2), and 40p-(3) are joined to each other. The first charge generation layer 40-1 may have a layer structure that the first n-type charge generation layer 40n-(1) and the first p-type charge generation layer 40p-(1) are joined to each other. The second charge generation layer 40-(2) may have a layer structure that the second n-type charge generation layer 40n-(2) and the second p-type charge generation layer 40p-(2) are joined to each other. The third charge generation layer 40-(3) may have a layer structure that the third n-type charge generation layer 40n-(3) and the third p-type charge generation layer 40p-(3) are joined to each other.

The n-type charge generation layers 40n-(1), 40n-(2), and 40n-(3) are a charge generation layer providing electrons to its adjacent stacks. The n-type charge generation layers 40n-(1), 40n-(2), and 40n-(3) may be a layer in which a base material is doped with an n-dopant. The p-type charge generation layers 40p-(1), 40p-(2), and 40p-(3) may be a charge generation layer providing holes to its adjacent stacks. Between each of the n-type charge generation layers 40n-(1), 40n-(2), and 40n-(3) and each of the p-type charge generation layers 40p-(1), 40p-(2), and 40p-(3), a buffer layer may be further disposed.

Each of the charge generation layers 40-(1), 40-(2), and 40-(3) may include an n-type charge generation layer, in which a phenanthroline-based compound is doped with a metal, and a p-type charge generation layer, in which an amine-based compound is doped with a p-dopant.

In the organic light emitting diode 400 according to an example embodiment, the first stack 1, the second stack 2, and the third stack 3 respectively may include each of the first light emitting layers 30-(1), 30-(1′), and 30-(1″) emitting light at a first wavelength. The light at a first wavelength may be light of a blue wavelength region. In an example embodiment, the first wavelength may be greater than or equal to about 420 nm and less than or equal to about 480 nm. The first light emitting layers 30-(1), 30-(1′), and 30-(1″) may include an organic material emitting light of a wavelength of greater than or equal to about 420 nm and less than or equal to about 480 nm. The first light emitting layers 30-(1), 30-(1′), and 30-(1″), e.g., may include a host and a dopant.

In an example embodiment, the first light emitting layers 30-(1), 30-(1′), and 30-(1″) may be the light emitting layer 30-(1) included in the first stack 1, the light emitting layer 30-(1′) included in the second stack 2, and the light emitting layer 30-(1″) included in the third stack 3.

Each of the first light emitting layers 30-(1), 30-(1′), and 30-(1″) may independently have a monolayer structure or a bilayer structure, wherein if it has the bilayer structure, different host materials may be included. The host included in the first light emitting layers 30-(1), 30-(1′), and 30-(1″) may be a blue fluorescent host, and the dopant may be a blue fluorescent dopant.

The hosts included in each of the first light emitting layers may be the same or different each other.

As shown in FIG. 1, the first light emitting layer 30-(1) and the second light emitting layer 30-(2) may be disposed adjacently to the charge generation layer 40. As shown in FIGS. 2 to 4, in a tandem structure including two or more stacks, the first light emitting layer 30-(1) and the second light emitting layer 30-(2) may be each independently disposed in each stack, and between the stacks, each charge generation layers 40, 40-(1), 40-(2), 40-(3), 40-(n−2), and 40-(n−1) may be disposed. Each stack may further include a hole transport region 50, an intermediate hole transport region 50-(1), 50-(2), 50-(3), . . . 50-(n−1), and 50-(n), an electron transport region 60, an intermediate electron transport region 60-(1), 60-(2), 60-(3), . . . 60-(n−1), and 60-(n), and a light emitting layer 30-(1), 30-(1′), 30-(1″), 30-(2), . . . 30-(n), and 30-(n+1) between the anode 10 and the cathode 20.

An organic optoelectronic device according to some embodiments may include an anode and a cathode facing each other, at least one first light emitting layer that emits light of a first wavelength and at least one second light emitting layer that emits light of a second wavelength different from the first wavelength which are located between the anode and the cathode, and at least one charge generation layer between the first light emitting layer and the second light emitting layer, wherein the charge generation layer includes a first compound represented by Chemical Formula 1 and a second compound represented by Chemical Formula 2.

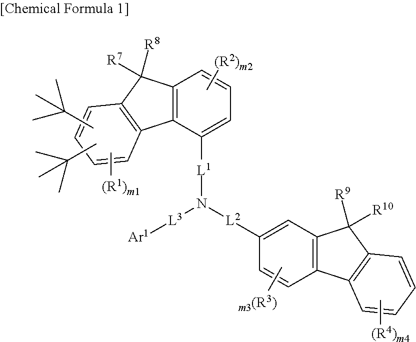

In Chemical Formula 1, L¹ to L³ may be each independently a single bond, a substituted or unsubstituted C6 to C20 arylene group, or a substituted or unsubstituted C2 to C30 heterocyclic group, Ar¹ may be a substituted or unsubstituted C6 to C20 aryl group or a substituted or unsubstituted C2 to C30 heterocyclic group, R¹ to R⁴ may be each independently hydrogen, deuterium, a cyano group, a substituted or unsubstituted C1 to C30 alkyl group, a substituted or unsubstituted C6 to C30 aryl group, or a substituted or unsubstituted C2 to C30 heterocyclic group, R⁷ to R¹⁰ may be each independently a substituted or unsubstituted C1 to C30 alkyl group, or a substituted or unsubstituted C6 to C30 aryl group, m1 may be an integer of 1 or 2, m2 and m3 may be each independently one of integers of 1 to 3, m4 may be one of integers of 1 to 4, when m1 is 2 or more, each R¹ may be the same or different from each other, when m2 is 2 or more, each R² may be the same or different from each other, when m3 is 2 or more, each R³ may be the same or different from each other, and when m4 is 2 or more, each R⁴ may be the same or different from each other.

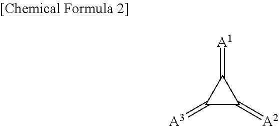

In Chemical Formula 2, A¹ may be represented by Chemical Formula 2a,

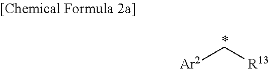

A² may be represented by Chemical Formula 2b,

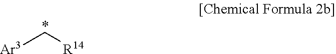

A³ may be represented by Chemical Formula 2c,

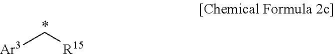

In Chemical Formula 2a, Chemical Formula 2b, and Chemical Formula 2c, Ar² to Ar⁴ may be each independently a substituted or unsubstituted C6 to C20 aryl group or a substituted or unsubstituted C2 to C30 heterocyclic group, R¹³ to R¹⁵ may be each independently hydrogen, deuterium, halogen, a cyano group, a nitro group, a substituted or unsubstituted C1 to C30 alkyl group, a substituted or unsubstituted C1 to C30 alkoxy group, a substituted or unsubstituted C6 to C20 aryl group, or a substituted or unsubstituted C2 to C30 heterocyclic group, and * is a linking point with the double bond.

By disposing a charge generation layer between a plurality of light emitting layers, light emission in a high luminance region is possible while keeping the current density low, and because the current density can be kept low, a long life-span device can be implemented. In particular, the first compound represented by Chemical Formula 1 has a fast hole mobility that facilitates hole transfer, thereby balancing the charge in the light emitting layer, enabling the implementation of a long life-span device.

In Chemical Formula 1, Ar¹ may be a substituted or unsubstituted phenyl group, a substituted or unsubstituted biphenyl group, a substituted or unsubstituted terphenyl group, a substituted or unsubstituted fluorenyl group, a substituted or unsubstituted dibenzofuranyl group, or a substituted or unsubstituted dibenzothiophenyl group. As an example, Ar¹ may be a substituted or unsubstituted fluorenyl group.

-L³-Ar¹ may be selected from the substituents listed in Group I, below.

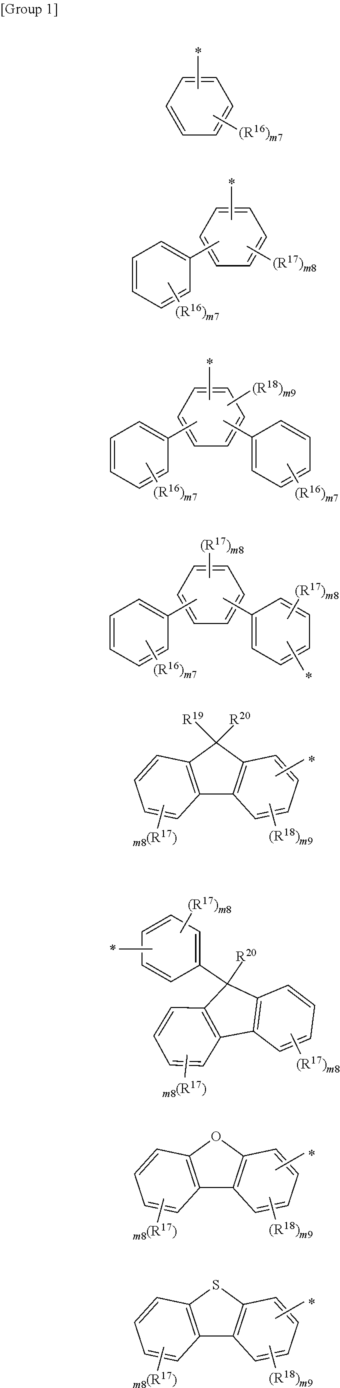

In Group I, R¹⁶ to R¹⁸ may be each independently hydrogen, deuterium, a cyano group, a substituted or unsubstituted C1 to C10 alkyl group, or a substituted or unsubstituted C6 to C12 aryl group, R¹⁹ and R²⁰ may be each independently a substituted or unsubstituted C1 to C10 alkyl group or a substituted or unsubstituted C6 to C12 aryl group, m7 may be one of integers of 1 to 5, m8 may be one of integers of 1 to 4, m9 may be one of integers of 1 to 3, and * is a linking point.

As a specific example, the first compound may be represented by Chemical Formula 1A, below.

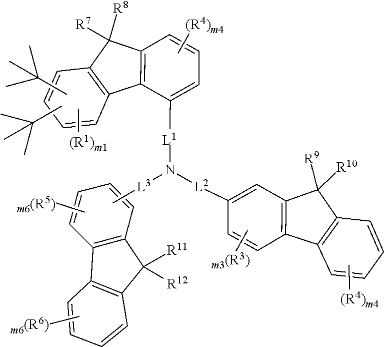

In Chemical Formula 1A, L¹ to L³ may be each independently a single bond, a substituted or unsubstituted C6 to C20 arylene group, or a substituted or unsubstituted C2 to C30 heterocyclic group, R¹ to R⁶ may be each independently hydrogen, deuterium, a cyano group, a substituted or unsubstituted C1 to C30 alkyl group, a substituted or unsubstituted C6 to C30 aryl group, or a substituted or unsubstituted C2 to C30 heterocyclic group, R⁷ to R¹² may be each independently a substituted or unsubstituted C1 to C30 alkyl group, or a substituted or unsubstituted C6 to C30 aryl group, m1 may be an integer of 1 or 2, m2, m3, and m5 may be each independently one of integers of 1 to 3, and m4 and m6 may be each independently one of integers of 1 to 4. When m1 is 2 or more, each R¹ may be the same or different from each other. When m2 is 2 or more, each R² may be the same or different from each other. When m3 is 2 or more, each R³ may be the same or different from each other. When m4 is 2 or more, each R⁴ may be the same or different from each other. When m5 is 2 or more, each R⁵ may be the same or different from each other. When m6 is 2 or more, each R⁶ may be the same or different from each other.

For example, Chemical Formula 1A may be represented by any one of Chemical Formula 1A-1 to Chemical Formula 1A-4.

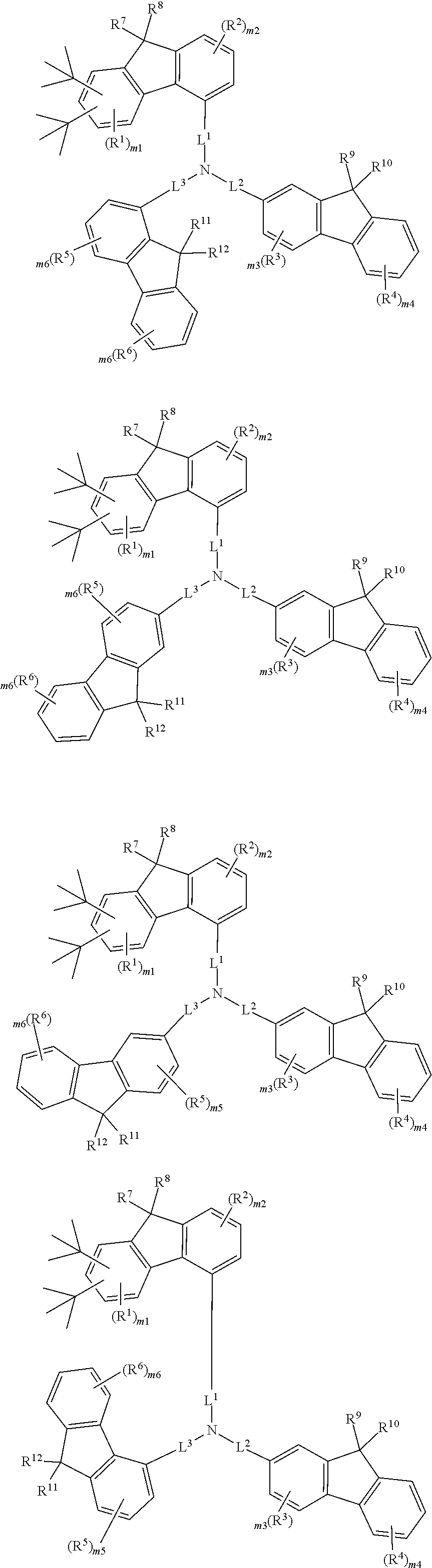

In Chemical Formula 1A-1 to Chemical Formula 1A-4, L¹ to L³, R¹ to R¹², and m1 to m6 may be the same as described above.

The first compound may be, e.g., one selected from the compounds listed in Group 1.

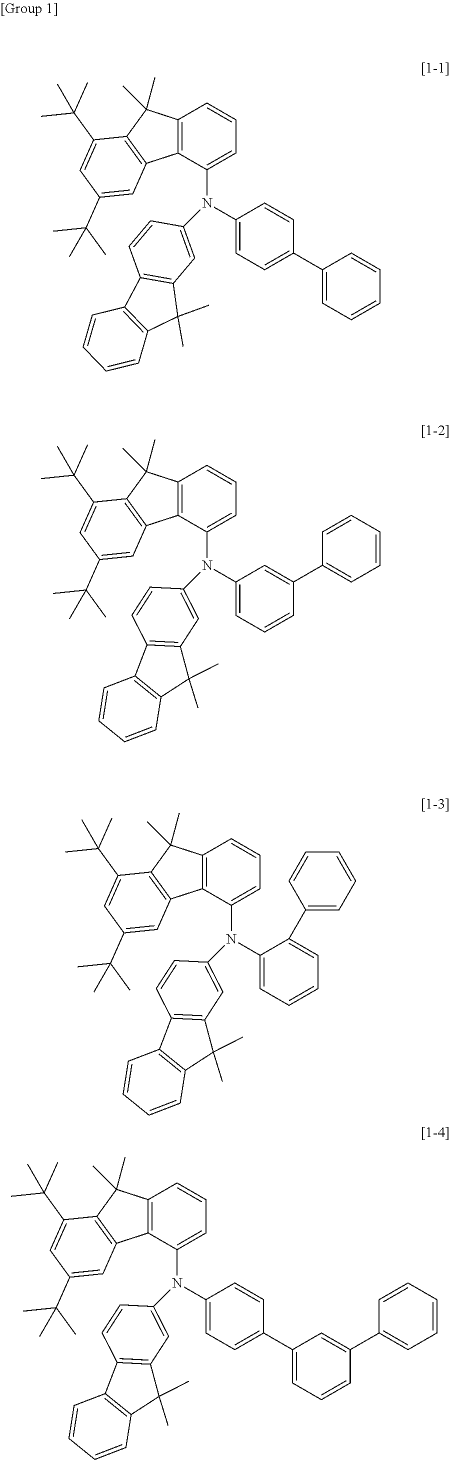 [SMILES: CC(C)(C)c1cc2c(c(C(C)(C)C)c1)C(C)(C)c1cccc(N(c3ccc(-c4ccccc4)cc3)c3ccc4c(c3)C(C)(C)c3ccccc3-4)c1-2 ; CC(C)(C)c1cc2c(c(C(C)(C)C)c1)C(C)(C)c1cccc(N(c3cccc(-c4ccccc4)c3)c3ccc4c(c3)C(C)(C)c3ccccc3-4)c1-2 ; CC(C)(C)c1cc2c(c(C(C)(C)C)c1)C(C)(C)c1cccc(N(c3ccc4c(c3)C(C)(C)c3ccccc3-4)c3ccccc3-c3ccccc3)c1-2 ; CC(C)(C)c1cc2c(c(C(C)(C)C)c1)C(C)(C)c1cccc(N(c3ccc(-c4cccc(-c5ccccc5)c4)cc3)c3ccc4c(c3)C(C)(C)c3ccccc3-4)c1-2]

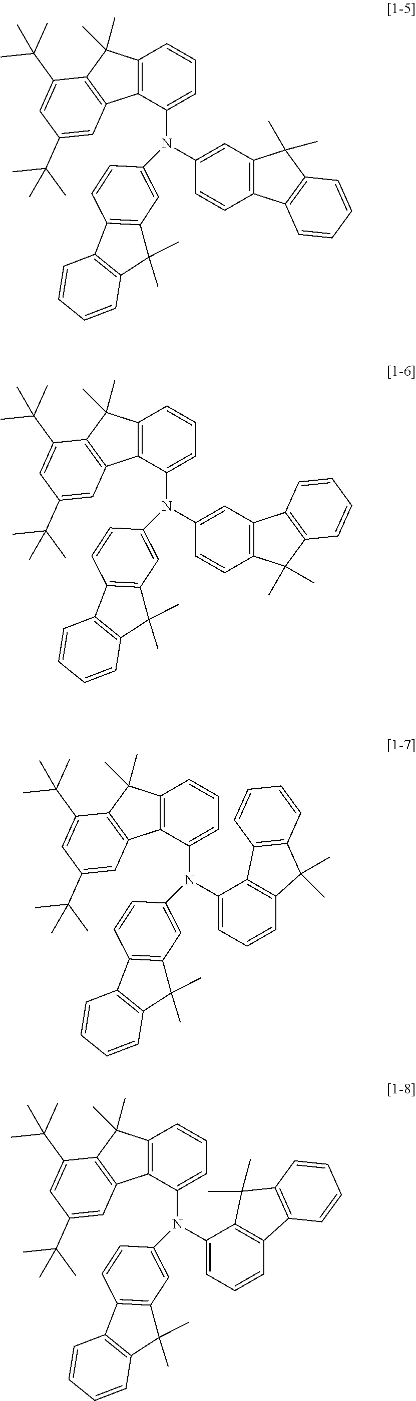

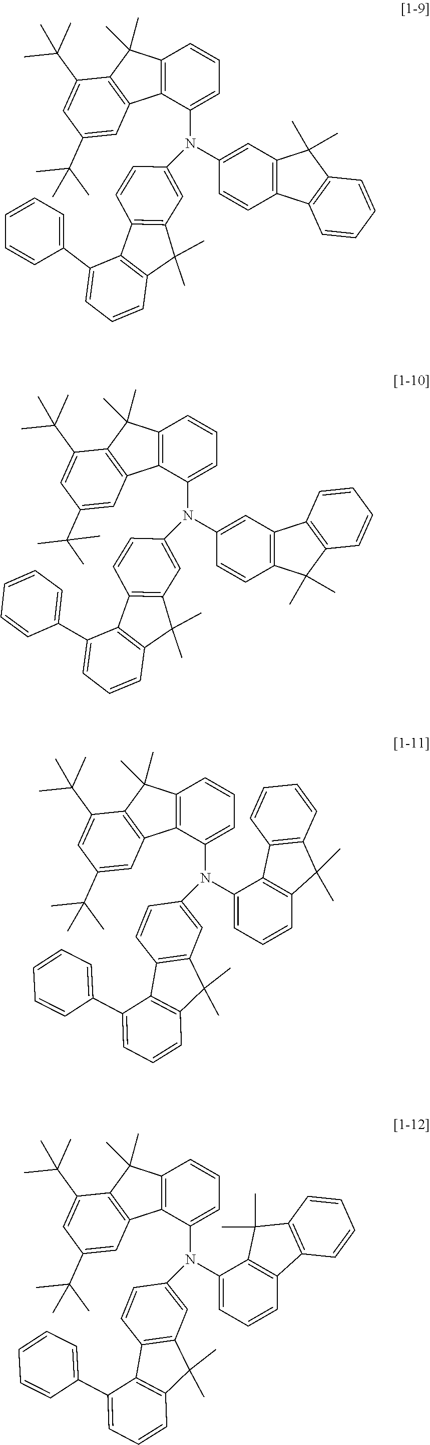 [SMILES: CC(C)(C)c1cc2c(c(C(C)(C)C)c1)C(C)(C)c1cccc(N(c3ccc4c(c3)C(C)(C)c3ccccc3-4)c3ccc4c(c3)C(C)(C)c3cccc(-c5ccccc5)c3-4)c1-2 ; CC(C)(C)c1cc2c(c(C(C)(C)C)c1)C(C)(C)c1cccc(N(c3ccc4c(c3)-c3ccccc3C4(C)C)c3ccc4c(c3)C(C)(C)c3cccc(-c5ccccc5)c3-4)c1-2 ; CC(C)(C)c1cc2c(c(C(C)(C)C)c1)C(C)(C)c1cccc(N(c3ccc4c(c3)C(C)(C)c3cccc(-c5ccccc5)c3-4)c3cccc4c3-c3ccccc3C4(C)C)c1-2 ; CC(C)(C)c1cc2c(c(C(C)(C)C)c1)C(C)(C)c1cccc(N(c3ccc4c(c3)C(C)(C)c3cccc(-c5ccccc5)c3-4)c3cccc4c3C(C)(C)c3ccccc3-4)c1-2]

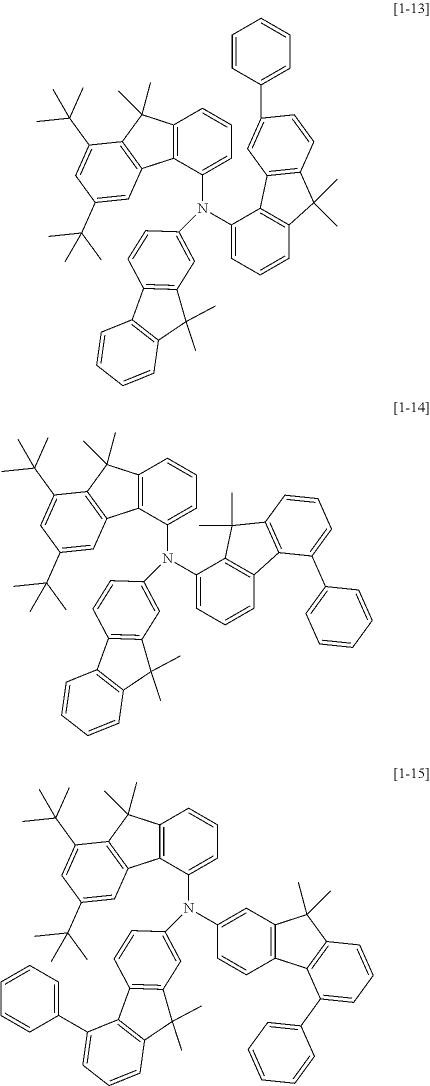

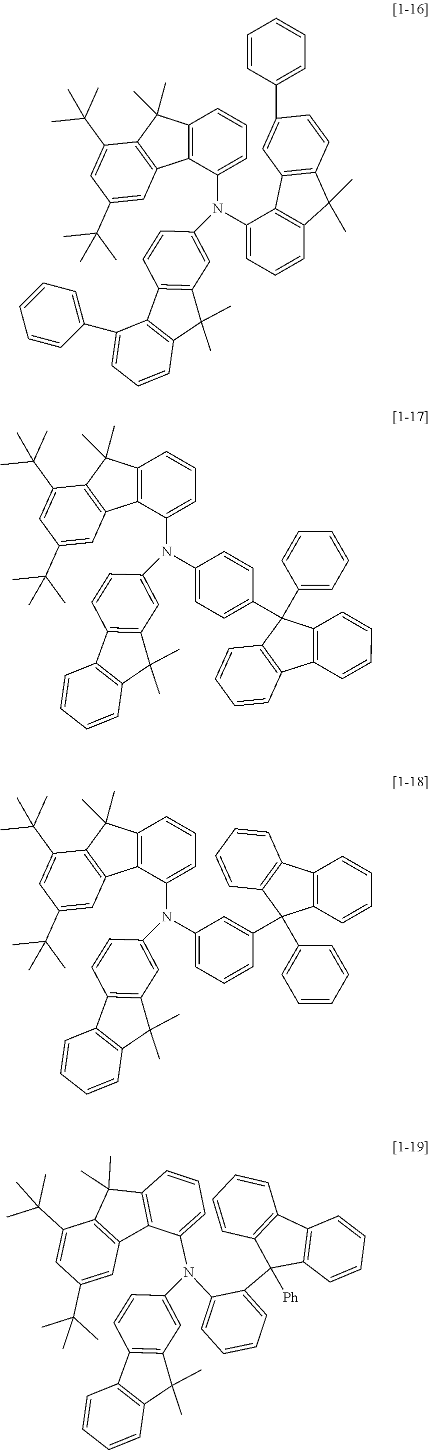

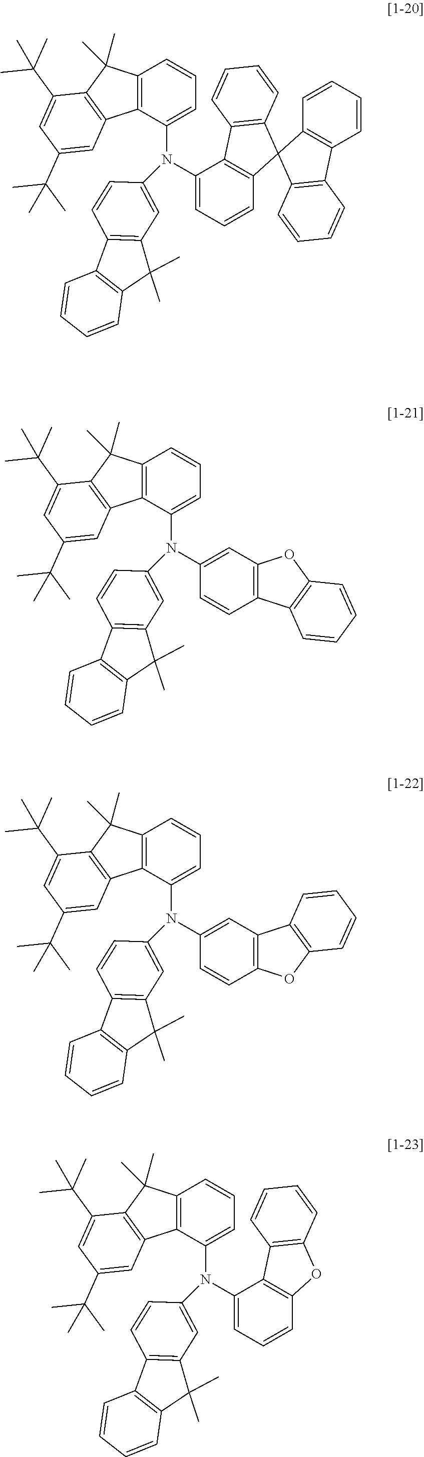 [SMILES: CC(C)(C)c1cc2c(c(C(C)(C)C)c1)C(C)(C)c1cccc(N(c3ccc4c(c3)C(C)(C)c3ccccc3-4)c3cccc4c3-c3ccccc3C43c4ccccc4-c4ccccc43)c1-2 ; CC(C)(C)c1cc2c(c(C(C)(C)C)c1)C(C)(C)c1cccc(N(c3ccc4c(c3)C(C)(C)c3ccccc3-4)c3ccc4c(c3)oc3ccccc34)c1-2 ; CC(C)(C)c1cc2c(c(C(C)(C)C)c1)C(C)(C)c1cccc(N(c3ccc4c(c3)C(C)(C)c3ccccc3-4)c3ccc4oc5ccccc5c4c3)c1-2 ; CC(C)(C)c1cc2c(c(C(C)(C)C)c1)C(C)(C)c1cccc(N(c3ccc4c(c3)C(C)(C)c3ccccc3-4)c3cccc4oc5ccccc5c34)c1-2]

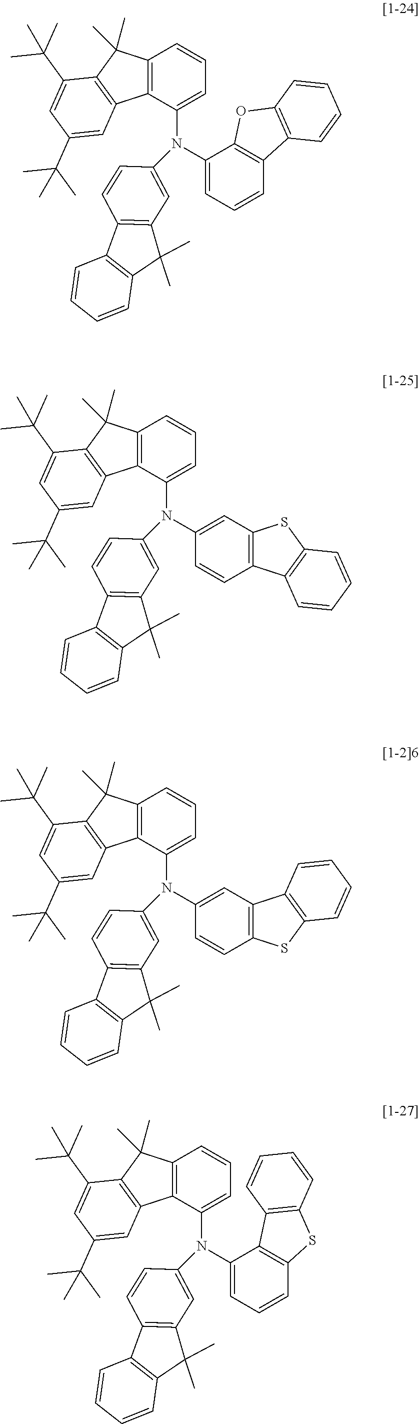 [SMILES: CC(C)(C)c1cc2c(c(C(C)(C)C)c1)C(C)(C)c1cccc(N(c3ccc4c(c3)C(C)(C)c3ccccc3-4)c3cccc4c3oc3ccccc34)c1-2 ; CC(C)(C)c1cc2c(c(C(C)(C)C)c1)C(C)(C)c1cccc(N(c3ccc4c(c3)C(C)(C)c3ccccc3-4)c3ccc4c(c3)sc3ccccc34)c1-2 ; CC(C)(C)c1cc2c(c(C(C)(C)C)c1)C(C)(C)c1cccc(N(c3ccc4c(c3)C(C)(C)c3ccccc3-4)c3ccc4sc5ccccc5c4c3)c1-2 ; CC(C)(C)c1cc2c(c(C(C)(C)C)c1)C(C)(C)c1cccc(N(c3ccc4c(c3)C(C)(C)c3ccccc3-4)c3cccc4sc5ccccc5c34)c1-2]

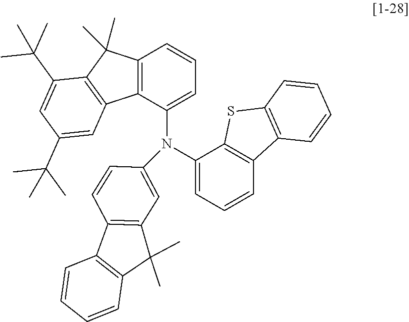 [SMILES: CC(C)(C)c1cc2c(c(C(C)(C)C)c1)C(C)(C)c1cccc(N(c3ccc4c(c3)C(C)(C)c3ccccc3-4)c3cccc4c3sc3ccccc34)c1-2]

As an example, the second compound may be represented by any one of Chemical Formula 2-1 to Chemical Formula 2-8.

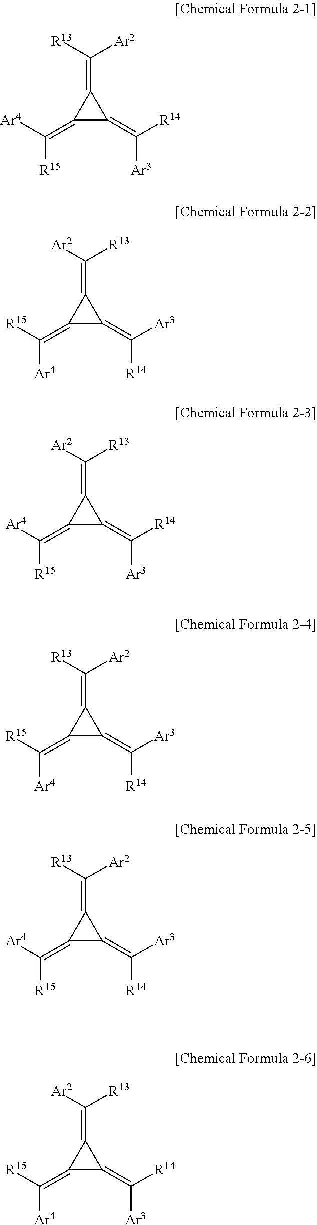

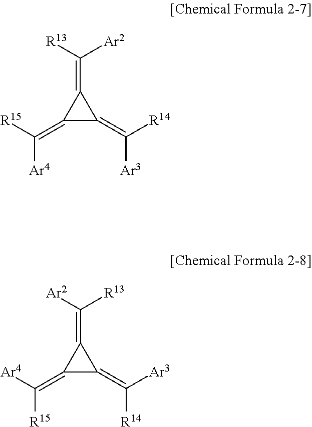

In Chemical Formula 2-1 to Chemical Formula 2-8, Ar² to Ar⁴ and R¹³ to R¹⁵ may be the same as described above.

As an example, at least one of A¹ to A³ may include at least one of a halogen, a cyano group, and a nitro group. For example, at least one of R¹³ to R¹⁵ may be at least one of a halogen group, a cyano group, and a nitro group. As an example, at least one of Ar² to Ar⁴ may be a C6 to C20 aryl group substituted with at least one of CN, NO₂, F, and a trifluoromethyl group or a C2 to C30 heterocyclic group substituted with at least one of CN, NO₂, F, and a trifluoromethyl group.

As a specific example, Ar² to Ar⁴ may each independently be selected from a substituted or unsubstituted phenyl group, a substituted or unsubstituted biphenyl group, a substituted or unsubstituted naphthyl group, a substituted or unsubstituted pyridyl group, a substituted or unsubstituted pyrimidinyl group, a substituted or unsubstituted triazinyl group, and a substituted or unsubstituted pyrazinyl group.

In some embodiments, at least one of R¹³ to R¹⁵ may be a cyano group or a nitro group, and at least one of Ar² to Ar⁴ may be a phenyl group substituted with at least one of CN, NO₂, F, and a trifluoromethyl group; a biphenyl group substituted with at least one of CN, NO₂, F, and a trifluoromethyl group; a naphthyl group substituted with at least one of CN, NO₂, F, and a trifluoromethyl group; a pyridyl group substituted with at least one of CN, NO₂, F, and a trifluoromethyl group; a pyrimidinyl group substituted with at least one of CN, NO₂, F, and a trifluoromethyl group; a triazinyl group substituted with at least one of CN, NO₂, F, and a trifluoromethyl group; or a pyrazinyl group substituted with at least one of CN, NO₂, F, and a trifluoromethyl group.

In some embodiments, at least one of Ar² to Ar⁴ may be represented by Chemical Formula I-1.

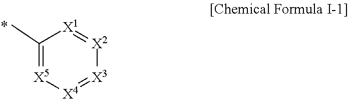

In Chemical Formula I-1, X¹ to X⁵ may be each independently N or CR^{a}, R^{a} may be each independently hydrogen, deuterium, fluoro, a trifluoro group, a cyano group, or a nitro group, and * is a linking point.

In some embodiments, R¹³ to R¹⁵ may each be a cyano group.

For example, Ar² to Ar⁴ may each independently be selected from the substituents listed in Group I.

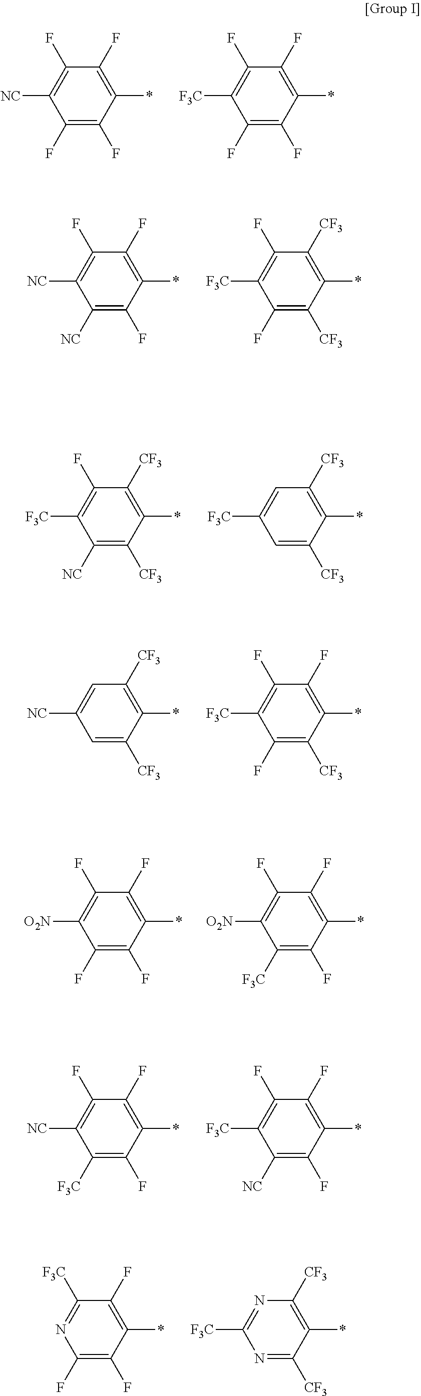

In Group I, * is a linking point.

The second compound may be, e.g., one selected from the compounds listed in Group 2.

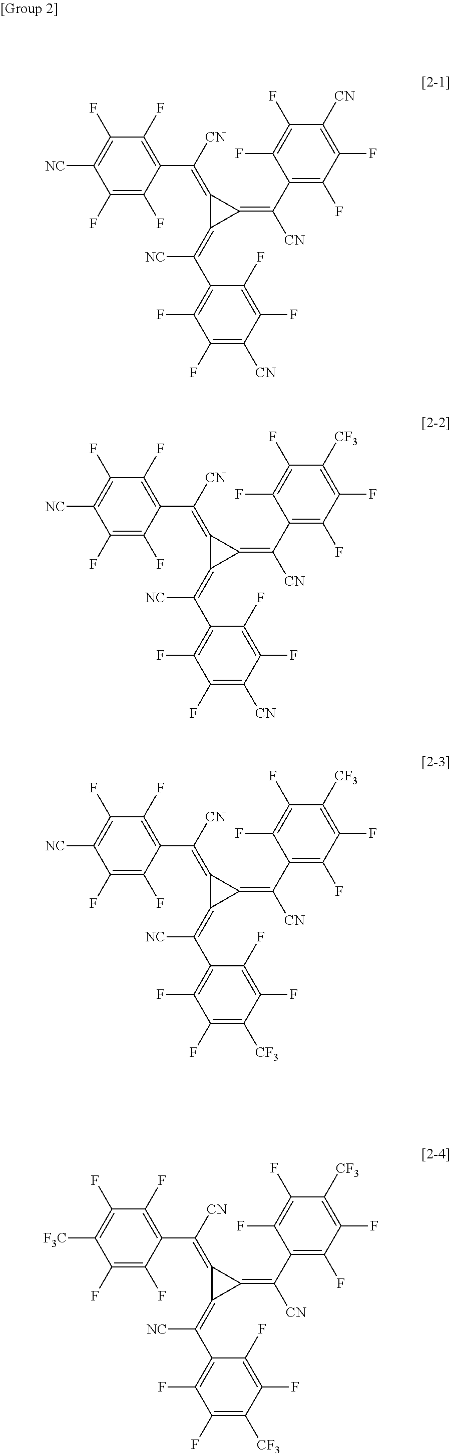 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#C/C(=C1/C(=C(\C#N)c2c(F)c(F)c(C#N)c(F)c2F)/C1=C(\C#N)c1c(F)c(F)c(C(F)(F)F)c(F)c1F)c1c(F)c(F)c(C#N)c(F)c1F ; N#C/C(=C1\C(=C(\C#N)c2c(F)c(F)c(C(F)(F)F)c(F)c2F)\C1=C(\C#N)c1c(F)c(F)c(C(F)(F)F)c(F)c1F)c1c(F)c(F)c(C#N)c(F)c1F ; N#CC(=C1C(=C(C#N)c2c(F)c(F)c(C(F)(F)F)c(F)c2F)C1=C(C#N)c1c(F)c(F)c(C(F)(F)F)c(F)c1F)c1c(F)c(F)c(C(F)(F)F)c(F)c1F]

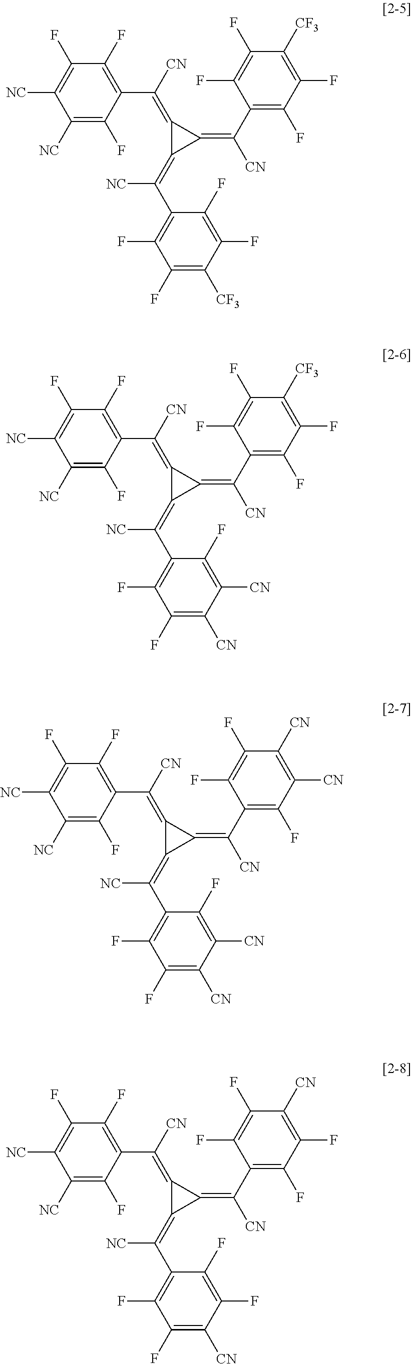 [SMILES: N#C/C(=C1/C(=C(\C#N)c2c(F)c(F)c(C#N)c(C#N)c2F)/C1=C(\C#N)c1c(F)c(F)c(C(F)(F)F)c(F)c1F)c1c(F)c(F)c(C(F)(F)F)c(F)c1F ; N#C/C(=C1\C(=C(\C#N)c2c(F)c(F)c(C(F)(F)F)c(F)c2F)\C1=C(\C#N)c1c(F)c(F)c(C#N)c(C#N)c1F)c1c(F)c(F)c(C#N)c(C#N)c1F ; N#CC(=C1C(=C(C#N)c2c(F)c(F)c(C#N)c(C#N)c2F)C1=C(C#N)c1c(F)c(F)c(C#N)c(C#N)c1F)c1c(F)c(F)c(C#N)c(C#N)c1F ; N#C/C(=C1/C(=C(\C#N)c2c(F)c(F)c(C#N)c(C#N)c2F)/C1=C(\C#N)c1c(F)c(F)c(C#N)c(F)c1F)c1c(F)c(F)c(C#N)c(F)c1F]

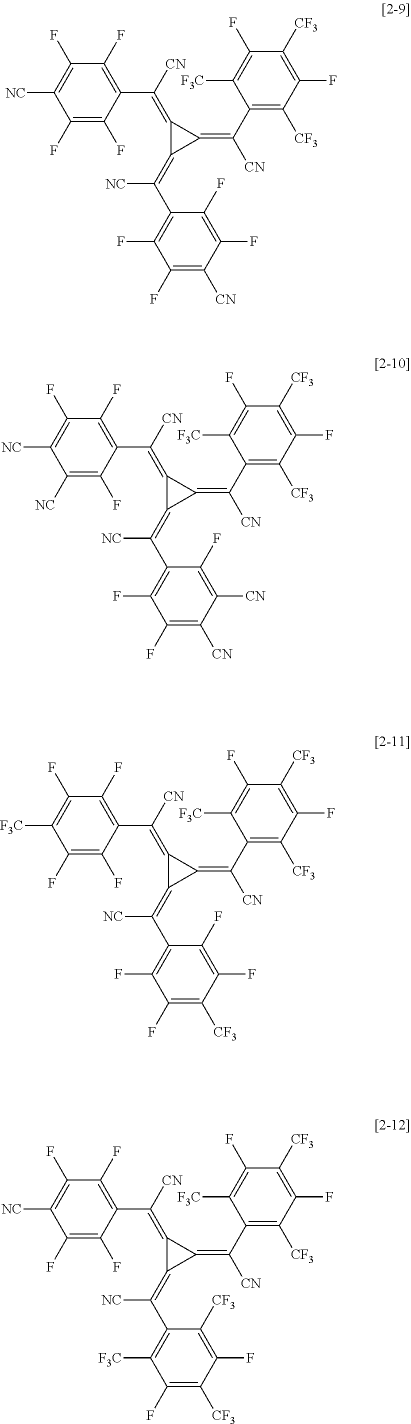

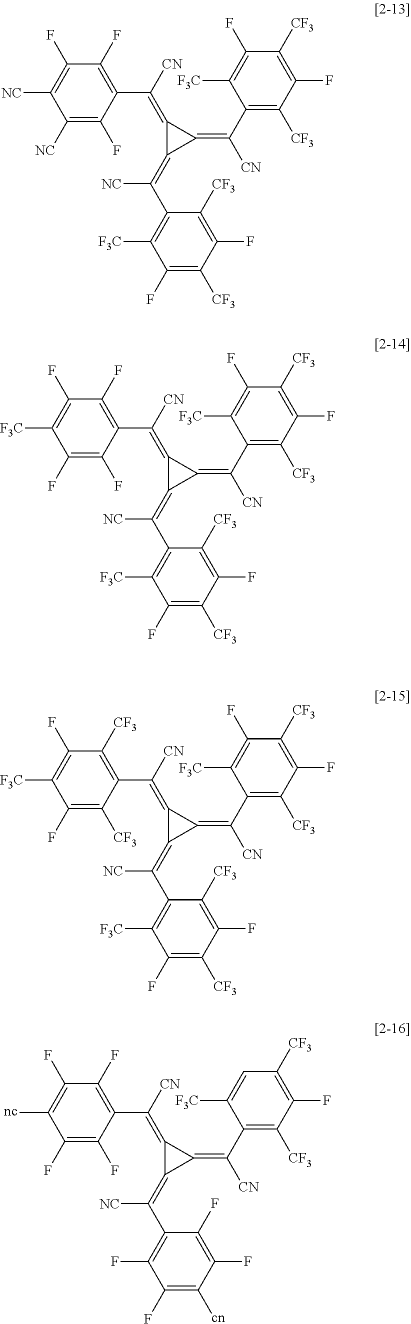

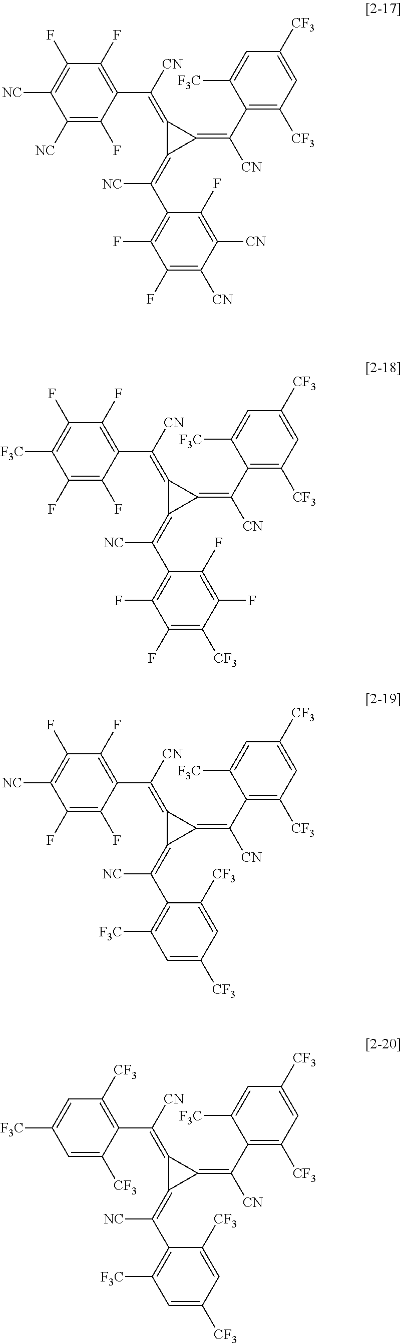

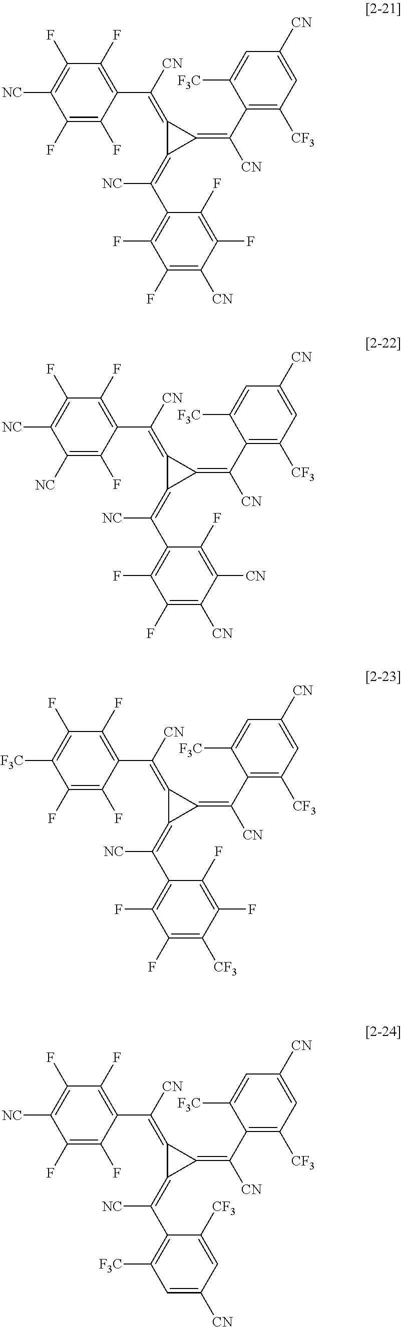 [SMILES: N#C/C(=C1\C(=C(\C#N)c2c(F)c(F)c(C#N)c(F)c2F)\C1=C(\C#N)c1c(F)c(F)c(C#N)c(F)c1F)c1c(C(F)(F)F)cc(C#N)cc1C(F)(F)F ; N#C/C(=C1\C(=C(\C#N)c2c(F)c(F)c(C#N)c(C#N)c2F)\C1=C(\C#N)c1c(F)c(F)c(C#N)c(C#N)c1F)c1c(C(F)(F)F)cc(C#N)cc1C(F)(F)F ; N#C/C(=C1\C(=C(\C#N)c2c(F)c(F)c(C(F)(F)F)c(F)c2F)\C1=C(\C#N)c1c(F)c(F)c(C(F)(F)F)c(F)c1F)c1c(C(F)(F)F)cc(C#N)cc1C(F)(F)F ; N#C/C(=C1/C(=C(\C#N)c2c(C(F)(F)F)cc(C#N)cc2C(F)(F)F)/C1=C(\C#N)c1c(F)c(F)c(C#N)c(F)c1F)c1c(C(F)(F)F)cc(C#N)cc1C(F)(F)F]

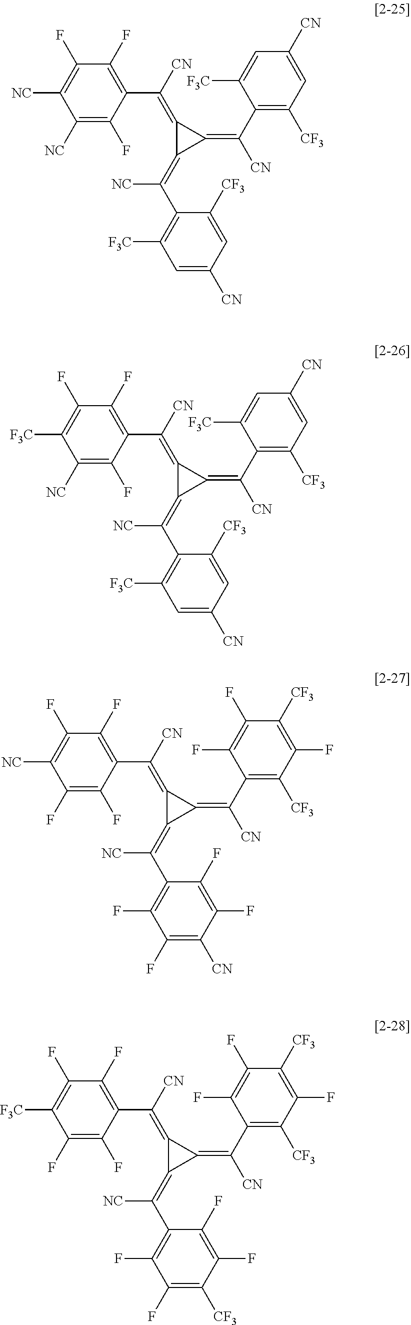 [SMILES: N#C/C(=C1/C(=C(\C#N)c2c(C(F)(F)F)cc(C#N)cc2C(F)(F)F)/C1=C(\C#N)c1c(F)c(F)c(C#N)c(C#N)c1F)c1c(C(F)(F)F)cc(C#N)cc1C(F)(F)F ; N#C/C(=C1/C(=C(\C#N)c2c(C(F)(F)F)cc(C#N)cc2C(F)(F)F)/C1=C(\C#N)c1c(F)c(F)c(C(F)(F)F)c(C#N)c1F)c1c(C(F)(F)F)cc(C#N)cc1C(F)(F)F ; N#C/C(=C1/C(=C(\C#N)c2c(F)c(F)c(C(F)(F)F)c(F)c2C(F)(F)F)/C1=C(\C#N)c1c(F)c(F)c(C#N)c(F)c1F)c1c(F)c(F)c(C#N)c(F)c1F ; N#C/C(=C1/C(=C(\C#N)c2c(F)c(F)c(C(F)(F)F)c(F)c2C(F)(F)F)/C1=C(\C#N)c1c(F)c(F)c(C(F)(F)F)c(F)c1F)c1c(F)c(F)c(C(F)(F)F)c(F)c1F]

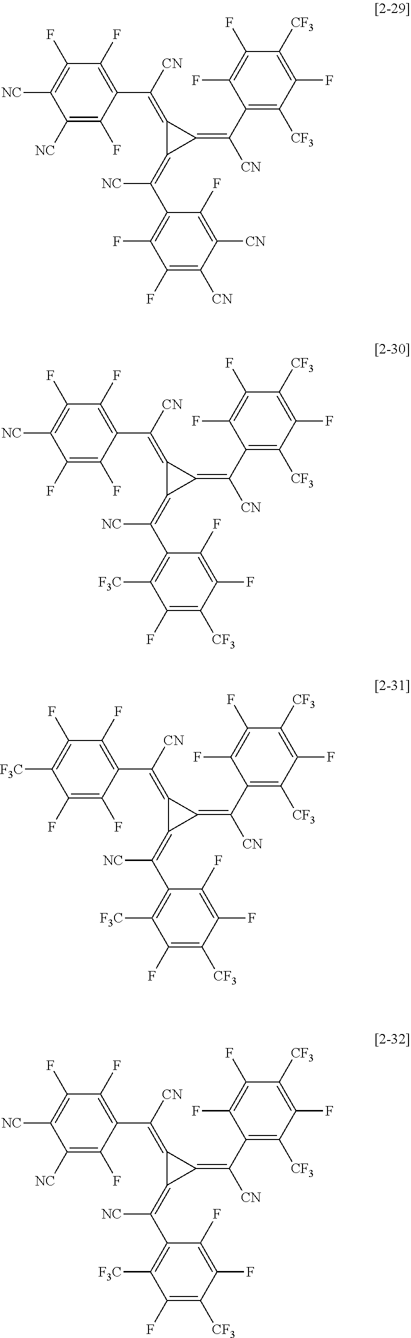

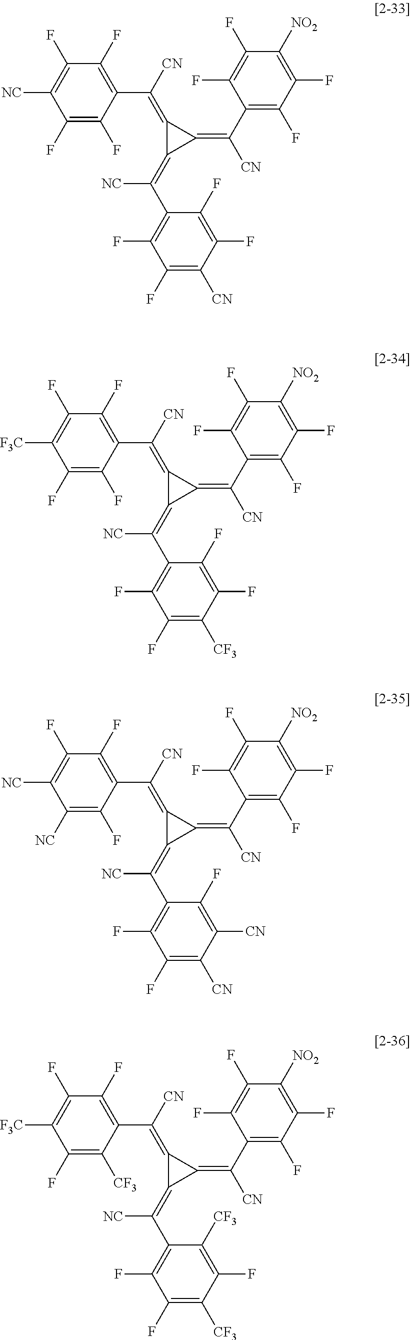 [SMILES: N#C/C(=C1/C(=C(\C#N)c2c(F)c(F)c(C#N)c(F)c2F)/C1=C(\C#N)c1c(F)c(F)c([N+](=O)[O-])c(F)c1F)c1c(F)c(F)c(C#N)c(F)c1F ; N#C/C(=C1\C(=C(\C#N)c2c(F)c(F)c([N+](=O)[O-])c(F)c2F)\C1=C(\C#N)c1c(F)c(F)c(C(F)(F)F)c(F)c1F)c1c(F)c(F)c(C(F)(F)F)c(F)c1F ; N#C/C(=C1\C(=C(\C#N)c2c(F)c(F)c([N+](=O)[O-])c(F)c2F)\C1=C(\C#N)c1c(F)c(F)c(C#N)c(C#N)c1F)c1c(F)c(F)c(C#N)c(C#N)c1F ; N#C/C(=C1\C(=C(\C#N)c2c(F)c(F)c([N+](=O)[O-])c(F)c2F)\C1=C(\C#N)c1c(F)c(F)c(C(F)(F)F)c(F)c1C(F)(F)F)c1c(F)c(F)c(C(F)(F)F)c(F)c1C(F)(F)F]

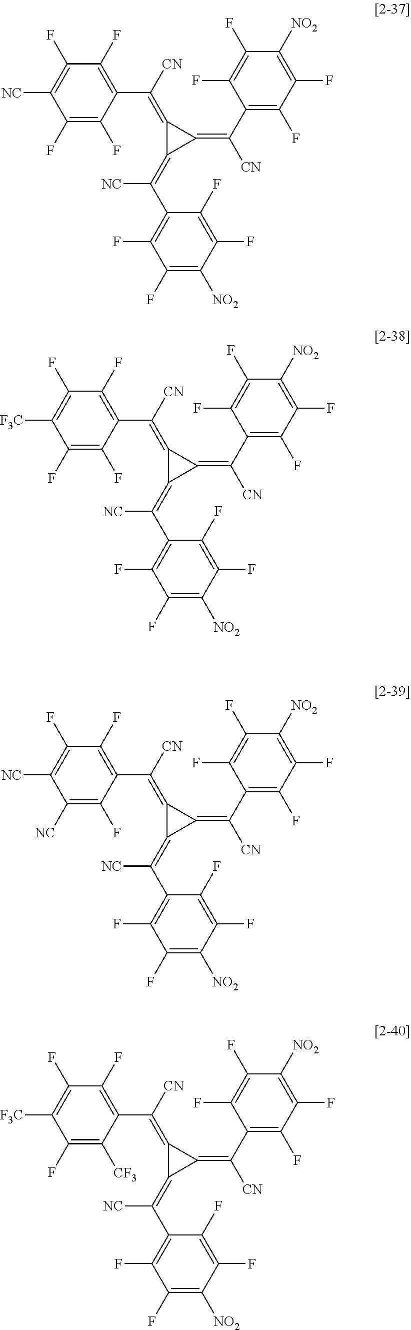

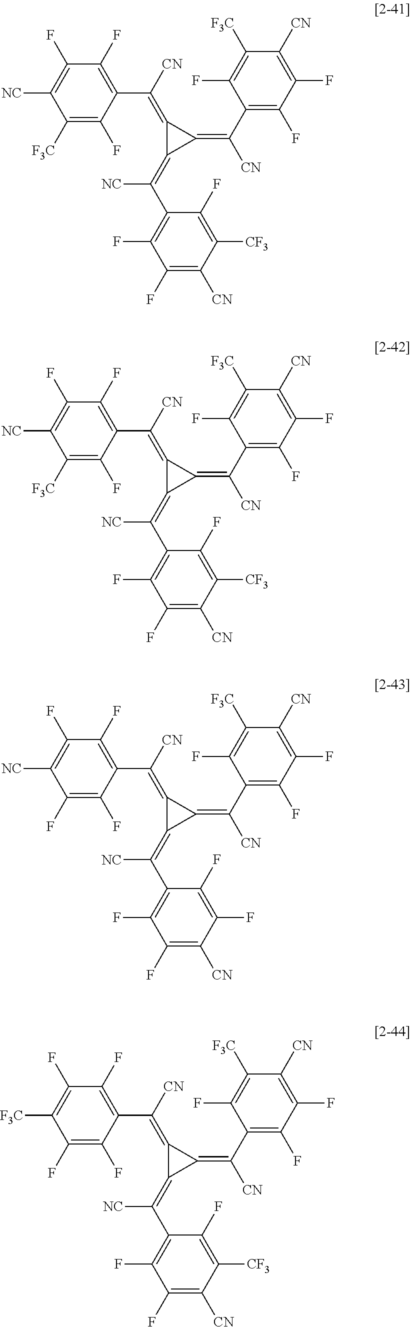 [SMILES: N#CC(=C1C(=C(C#N)c2c(F)c(F)c(C#N)c(C(F)(F)F)c2F)C1=C(C#N)c1c(F)c(F)c(C#N)c(C(F)(F)F)c1F)c1c(F)c(F)c(C#N)c(C(F)(F)F)c1F ; N#CC(=C1C(=C(C#N)c2c(F)c(F)c(C#N)c(C(F)(F)F)c2F)C1=C(C#N)c1c(F)c(F)c(C#N)c(C(F)(F)F)c1F)c1c(F)c(F)c(C#N)c(C(F)(F)F)c1F ; N#C/C(=C1/C(=C(\C#N)c2c(F)c(F)c(C#N)c(C(F)(F)F)c2F)/C1=C(\C#N)c1c(F)c(F)c(C#N)c(F)c1F)c1c(F)c(F)c(C#N)c(F)c1F ; N#C/C(=C1\C(=C(\C#N)c2c(F)c(F)c(C(F)(F)F)c(F)c2F)\C1=C(\C#N)c1c(F)c(F)c(C#N)c(C(F)(F)F)c1F)c1c(F)c(F)c(C#N)c(C(F)(F)F)c1F]

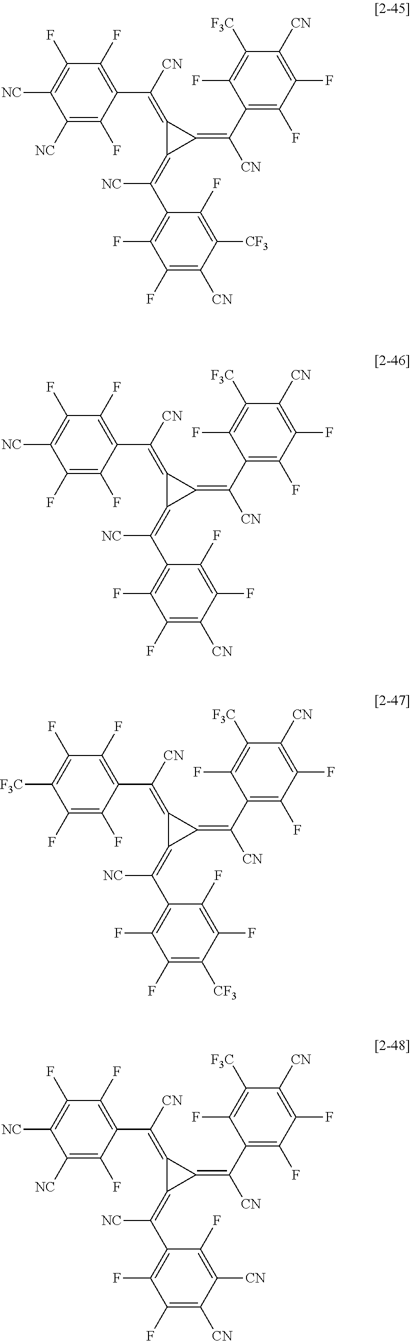 [SMILES: N#C/C(=C1\C(=C(\C#N)c2c(F)c(F)c(C#N)c(C(F)(F)F)c2F)\C1=C(\C#N)c1c(F)c(F)c(C#N)c(C(F)(F)F)c1F)c1c(F)c(F)c(C#N)c(C#N)c1F ; N#C/C(=C1/C(=C(\C#N)c2c(F)c(F)c(C#N)c(C(F)(F)F)c2F)/C1=C(\C#N)c1c(F)c(F)c(C#N)c(F)c1F)c1c(F)c(F)c(C#N)c(F)c1F ; N#C/C(=C1/C(=C(\C#N)c2c(F)c(F)c(C#N)c(C(F)(F)F)c2F)/C1=C(\C#N)c1c(F)c(F)c(C(F)(F)F)c(F)c1F)c1c(F)c(F)c(C(F)(F)F)c(F)c1F ; N#C/C(=C1/C(=C(\C#N)c2c(F)c(F)c(C#N)c(C#N)c2F)/C1=C(\C#N)c1c(F)c(F)c(C#N)c(C(F)(F)F)c1F)c1c(F)c(F)c(C#N)c(C#N)c1F]

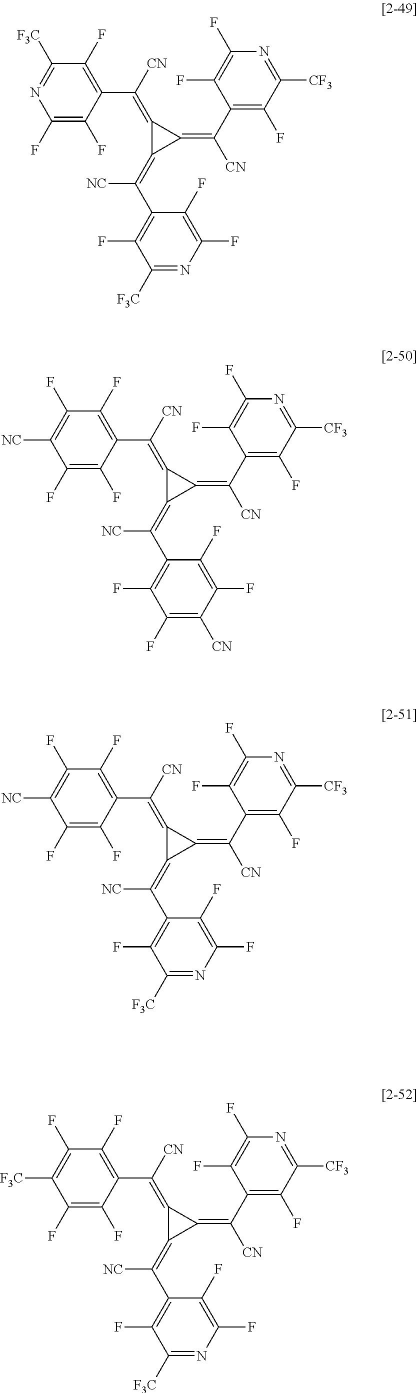 [SMILES: N#CC(=C1C(=C(C#N)c2c(F)c(F)nc(C(F)(F)F)c2F)C1=C(C#N)c1c(F)c(F)nc(C(F)(F)F)c1F)c1c(F)c(F)nc(C(F)(F)F)c1F ; N#C/C(=C1\C(=C(\C#N)c2c(F)c(F)nc(C(F)(F)F)c2F)\C1=C(\C#N)c1c(F)c(F)c(C#N)c(F)c1F)c1c(F)c(F)c(C#N)c(F)c1F ; N#C/C(=C1/C(=C(\C#N)c2c(F)c(F)c(C#N)c(F)c2F)/C1=C(\C#N)c1c(F)c(F)nc(C(F)(F)F)c1F)c1c(F)c(F)nc(C(F)(F)F)c1F ; N#C/C(=C1/C(=C(\C#N)c2c(F)c(F)c(C(F)(F)F)c(F)c2F)/C1=C(\C#N)c1c(F)c(F)nc(C(F)(F)F)c1F)c1c(F)c(F)nc(C(F)(F)F)c1F]

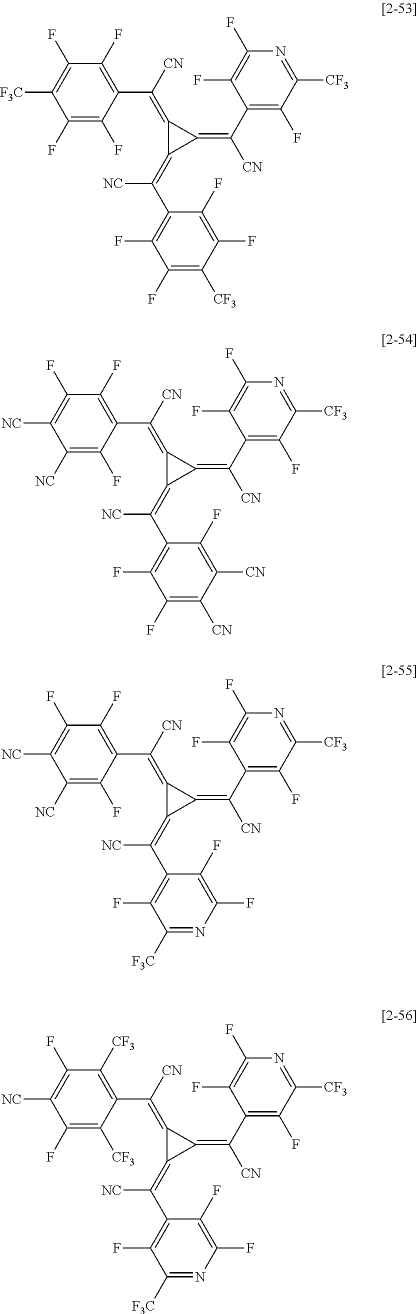 [SMILES: N#C/C(=C1\C(=C(\C#N)c2c(F)c(F)nc(C(F)(F)F)c2F)\C1=C(\C#N)c1c(F)c(F)c(C(F)(F)F)c(F)c1F)c1c(F)c(F)c(C(F)(F)F)c(F)c1F ; N#C/C(=C1\C(=C(\C#N)c2c(F)c(F)nc(C(F)(F)F)c2F)\C1=C(\C#N)c1c(F)c(F)c(C#N)c(C#N)c1F)c1c(F)c(F)c(C#N)c(C#N)c1F ; N#C/C(=C1/C(=C(\C#N)c2c(F)c(F)c(C#N)c(C#N)c2F)/C1=C(\C#N)c1c(F)c(F)nc(C(F)(F)F)c1F)c1c(F)c(F)nc(C(F)(F)F)c1F ; N#C/C(=C1/C(=C(\C#N)c2c(C(F)(F)F)c(F)c(C#N)c(F)c2C(F)(F)F)/C1=C(\C#N)c1c(F)c(F)nc(C(F)(F)F)c1F)c1c(F)c(F)nc(C(F)(F)F)c1F]

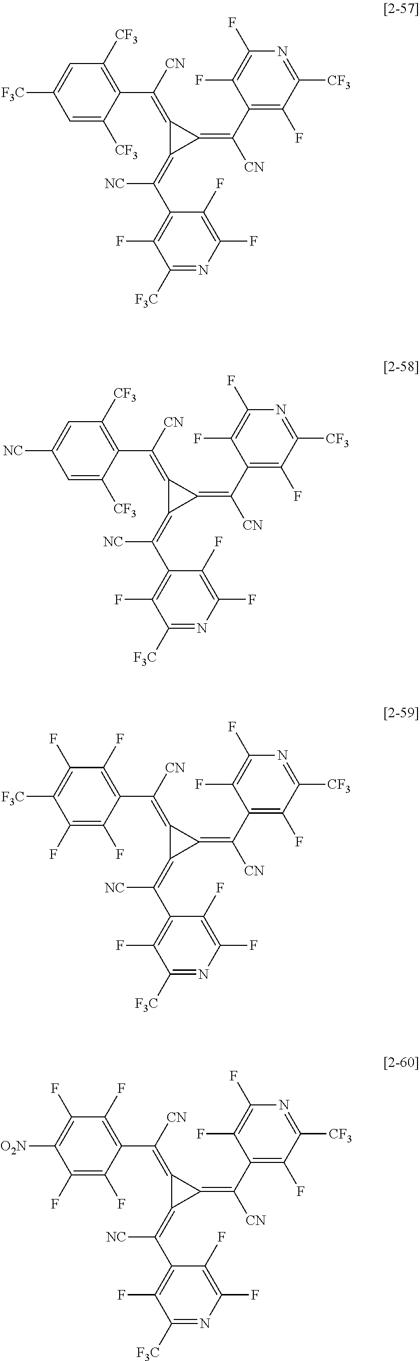 [SMILES: N#C/C(=C1\C(=C(\C#N)c2c(F)c(F)nc(C(F)(F)F)c2F)\C1=C(\C#N)c1c(F)c(F)nc(C(F)(F)F)c1F)c1c(C(F)(F)F)cc(C(F)(F)F)cc1C(F)(F)F ; N#C/C(=C1\C(=C(\C#N)c2c(F)c(F)nc(C(F)(F)F)c2F)\C1=C(\C#N)c1c(F)c(F)nc(C(F)(F)F)c1F)c1c(C(F)(F)F)cc(C#N)cc1C(F)(F)F ; N#C/C(=C1/C(=C(\C#N)c2c(F)c(F)c(C(F)(F)F)c(F)c2F)/C1=C(\C#N)c1c(F)c(F)nc(C(F)(F)F)c1F)c1c(F)c(F)nc(C(F)(F)F)c1F ; N#C/C(=C1/C(=C(\C#N)c2c(F)c(F)c([N+](=O)[O-])c(F)c2F)/C1=C(\C#N)c1c(F)c(F)nc(C(F)(F)F)c1F)c1c(F)c(F)nc(C(F)(F)F)c1F]

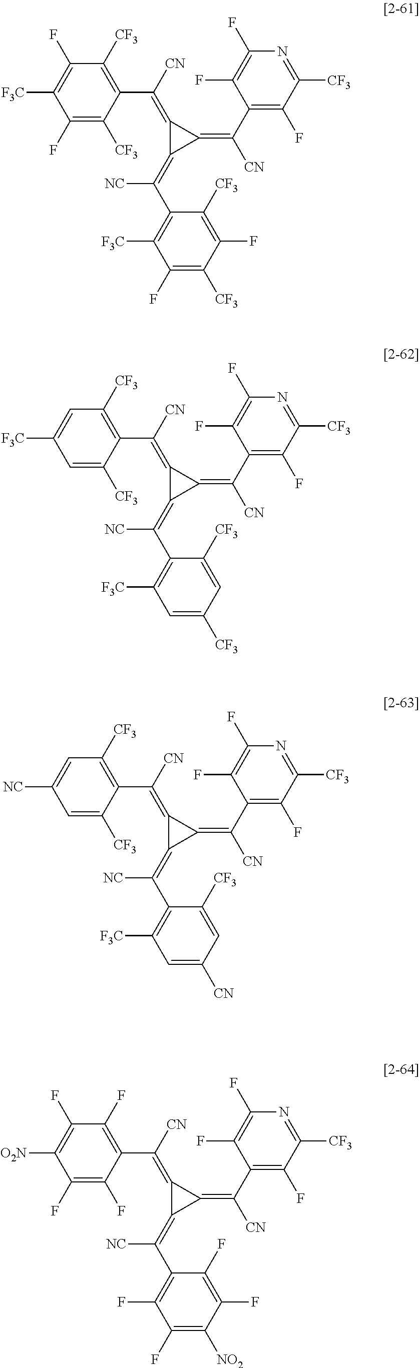

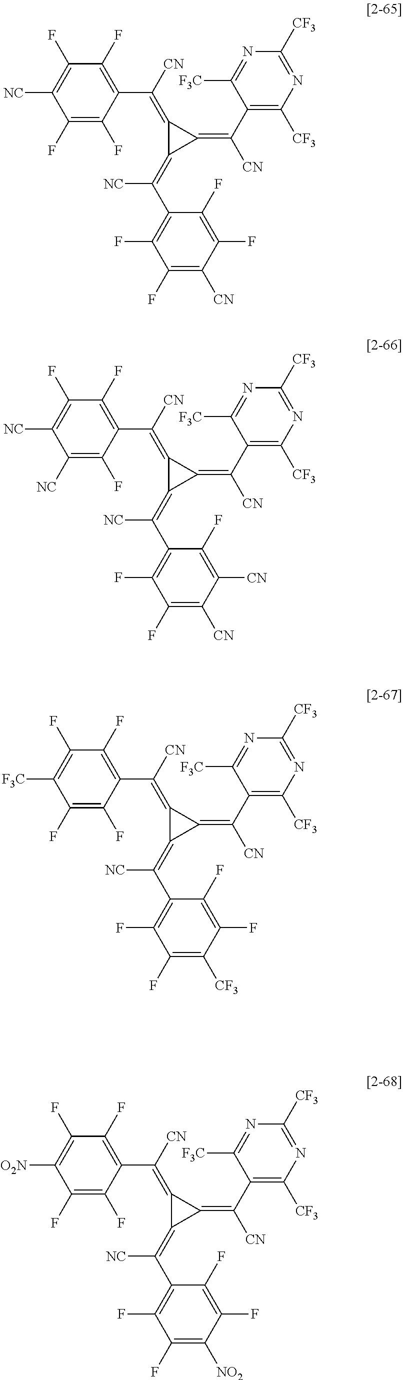

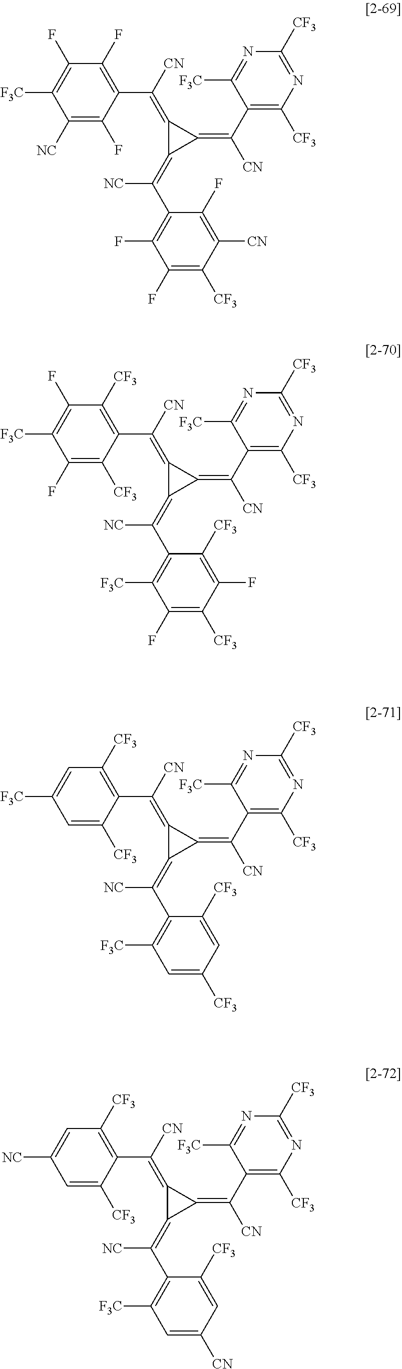

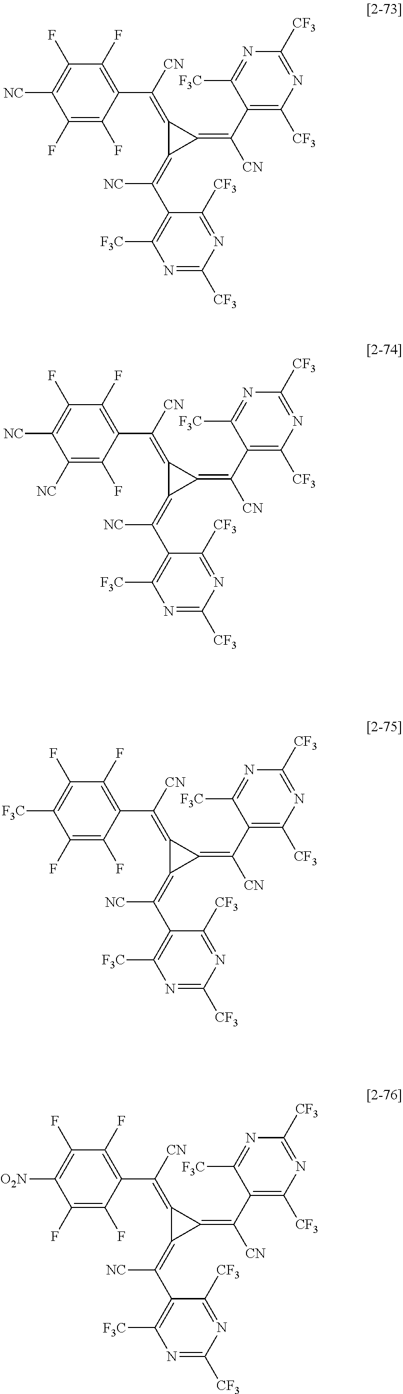

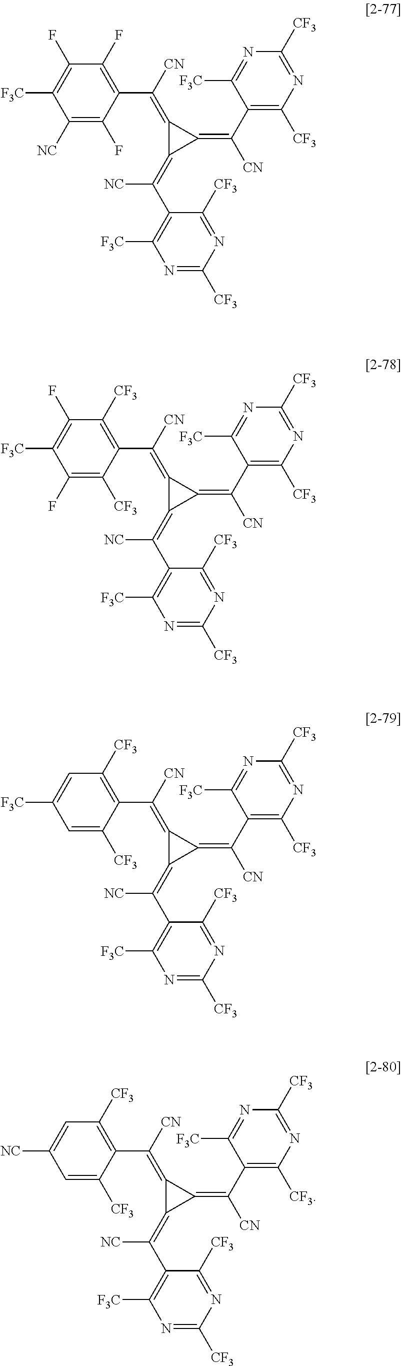

In some embodiments, the charge generation layer may be a p-type charge generation layer including a composition in which a first compound is doped with a second compound. For example, the first compound and the second compound may be included in a weight ratio of about 99:1 to about 60:40. Within the above range, they may be included at a weight ratio of, e.g., about 99:1 to about 70:30, about 99:1 to about 80:20, e.g., about 99:1 to about 90:10.

The first wavelength may be greater than or equal to about 420 nm and less than or equal to about 480 nm, and the second wavelength may be greater than or equal to about 520 nm and less than or equal to about 600 nm.

Some embodiments include a first stack and a second stack disposed between the anode and the cathode facing each other, and at least one charge generation layer disposed between the first stack and the second stack, wherein the first stack may include the first light emitting layer, the second stack may include the second light emitting layer, and an intermediate hole transport region and an intermediate electron transport region may be further included between the first light emitting layer and the second light emitting layer.

For example, the first light emitting layer may include a blue fluorescent host and a first dopant that emits light of a first wavelength.

For example, the first wavelength may be greater than or equal to about 420 nm and less than or equal to about 480 nm, and the first dopant may be a blue fluorescent dopant. For example, the host included in the first light emitting layer may be at least one of the compounds listed in Group A, below.

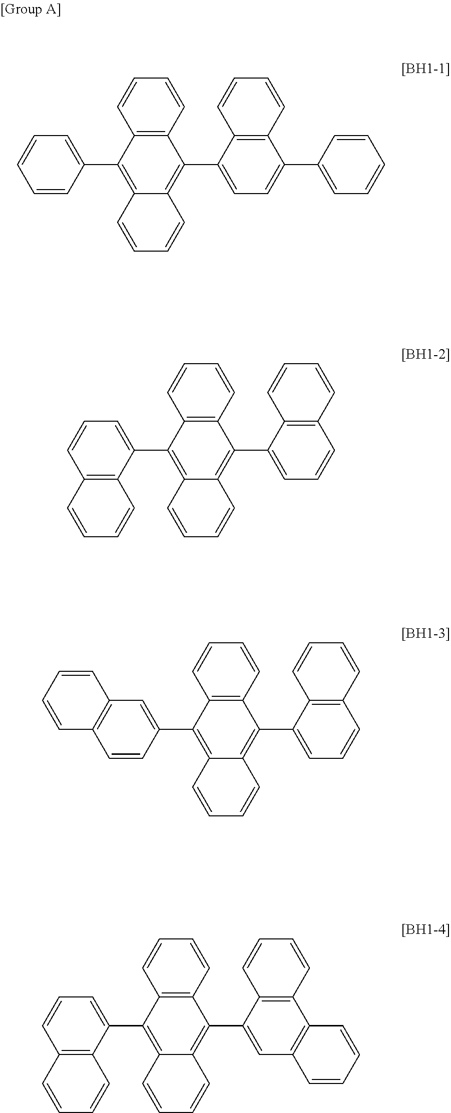

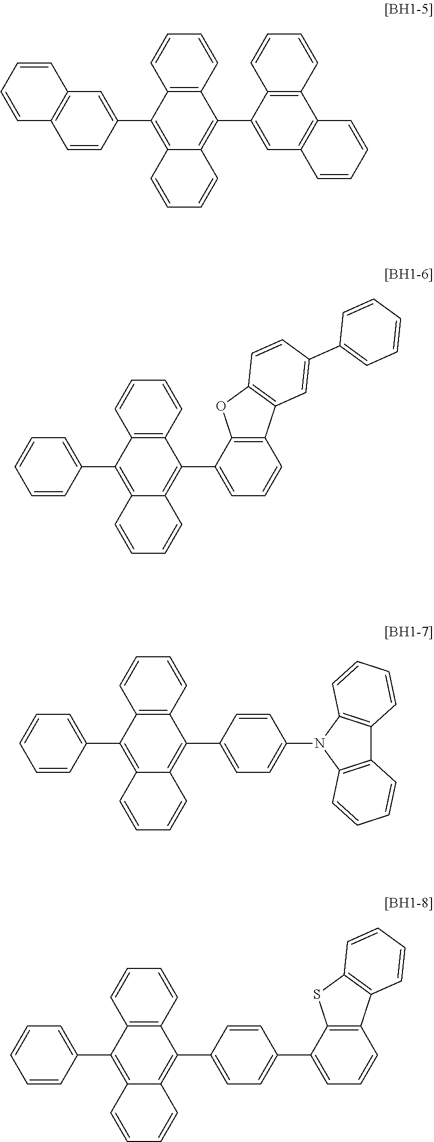

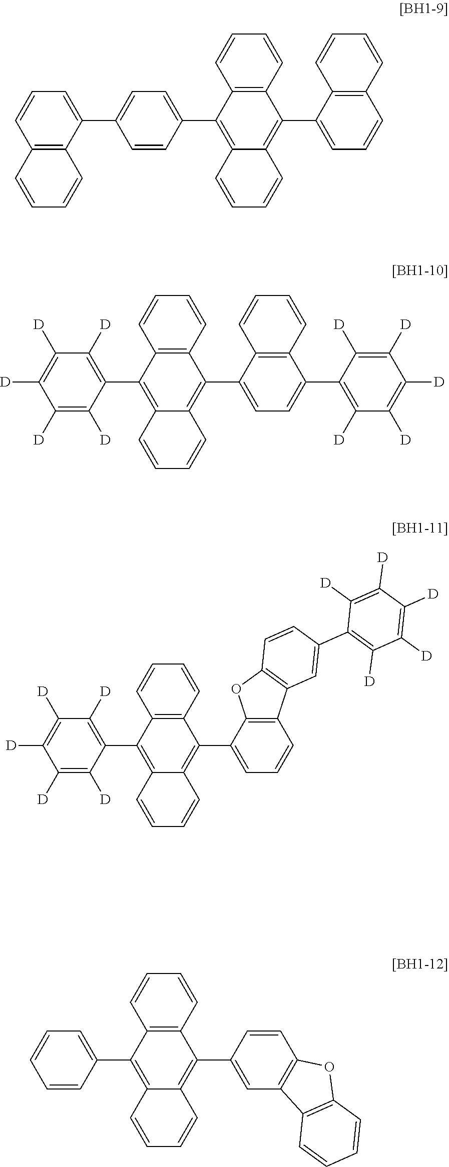

In some embodiments, one of the hydrogen atoms of the compounds BH1-1 to BH1-9 may be independently replaced with a deuterium atom. For example, the dopant included in the first light emitting layer may be at least one of the compounds listed in Group B, below.

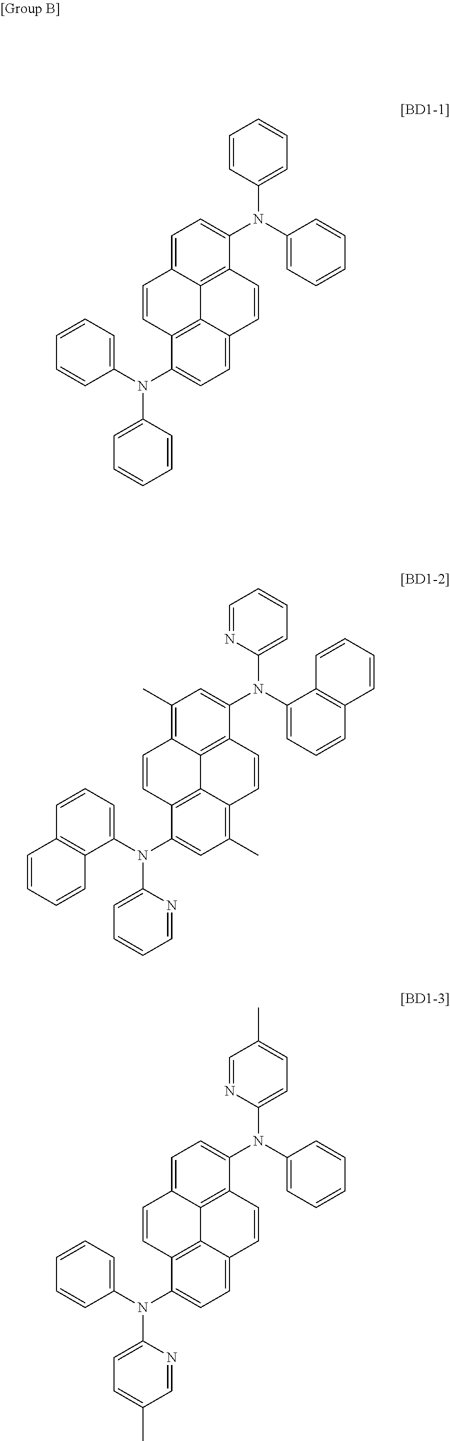 [SMILES: c1ccc(N(c2ccccc2)c2ccc3ccc4c(N(c5ccccc5)c5ccccc5)ccc5ccc2c3c54)cc1 ; Cc1cc(N(c2ccccn2)c2cccc3ccccc23)c2ccc3c(C)cc(N(c4ccccn4)c4cccc5ccccc45)c4ccc1c2c34 ; Cc1ccc(N(c2ccccc2)c2ccc3ccc4c(N(c5ccccc5)c5ccc(C)cn5)ccc5ccc2c3c54)nc1]

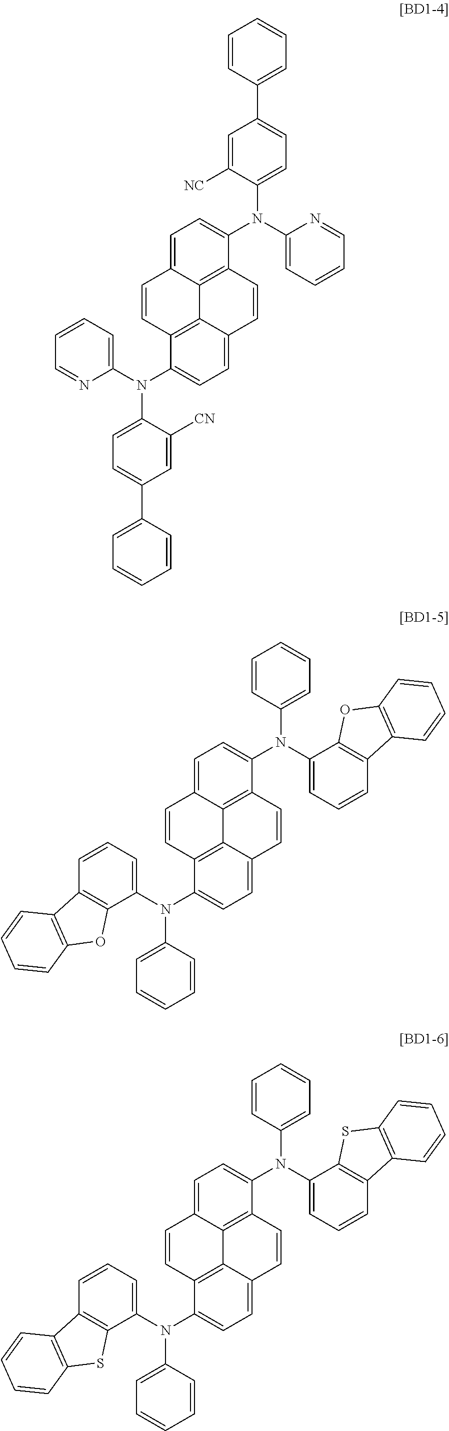 [SMILES: N#Cc1cc(-c2ccccc2)ccc1N(c1ccccn1)c1ccc2ccc3c(N(c4ccccn4)c4ccc(-c5ccccc5)cc4C#N)ccc4ccc1c2c43 ; c1ccc(N(c2ccc3ccc4c(N(c5ccccc5)c5cccc6c5oc5ccccc56)ccc5ccc2c3c54)c2cccc3c2oc2ccccc23)cc1 ; c1ccc(N(c2ccc3ccc4c(N(c5ccccc5)c5cccc6c5sc5ccccc56)ccc5ccc2c3c54)c2cccc3c2sc2ccccc23)cc1]

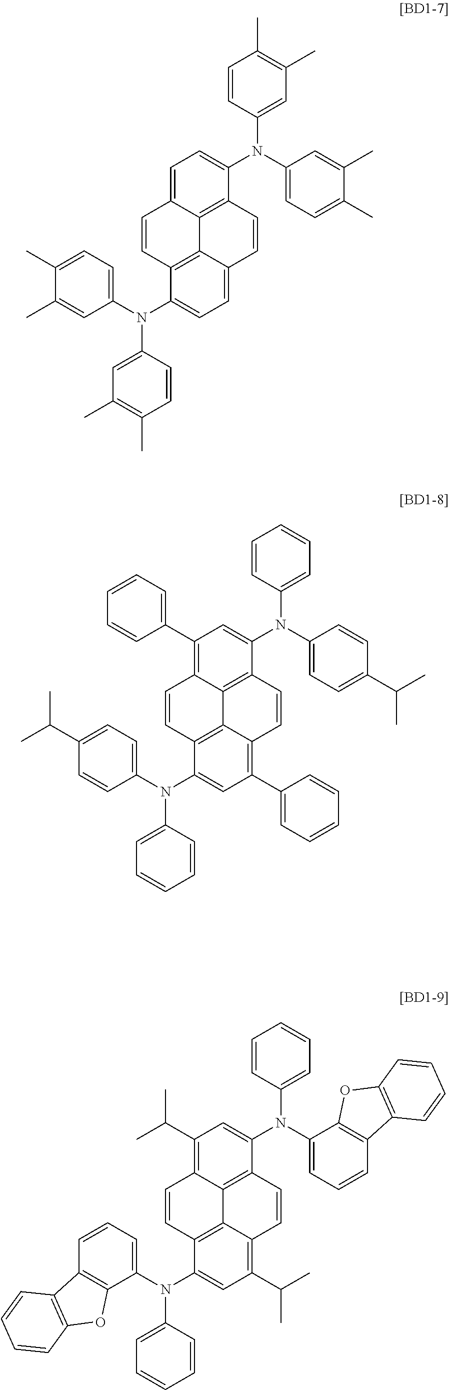

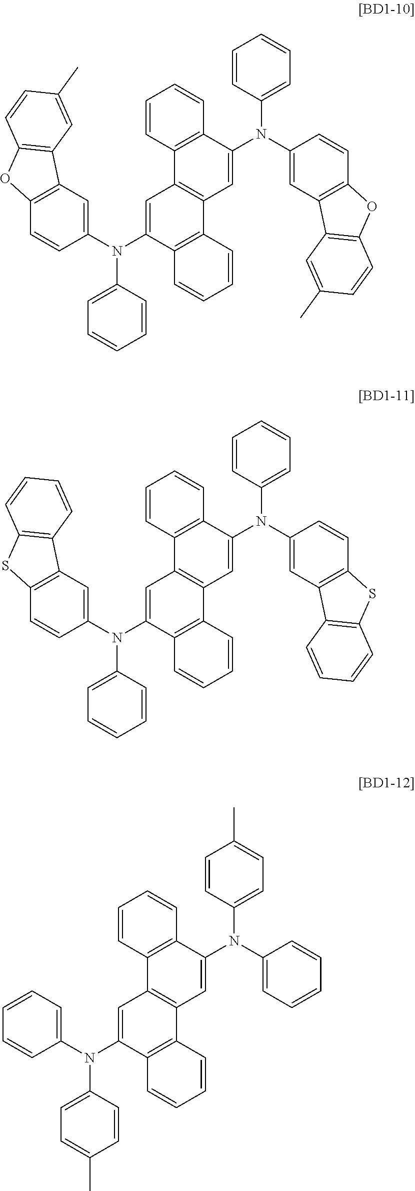 [SMILES: Cc1ccc2oc3ccc(N(c4ccccc4)c4cc5c6ccccc6c(N(c6ccccc6)c6ccc7oc8ccc(C)cc8c7c6)cc5c5ccccc45)cc3c2c1 ; c1ccc(N(c2ccc3sc4ccccc4c3c2)c2cc3c4ccccc4c(N(c4ccccc4)c4ccc5sc6ccccc6c5c4)cc3c3ccccc23)cc1 ; Cc1ccc(N(c2ccccc2)c2cc3c4ccccc4c(N(c4ccccc4)c4ccc(C)cc4)cc3c3ccccc23)cc1]

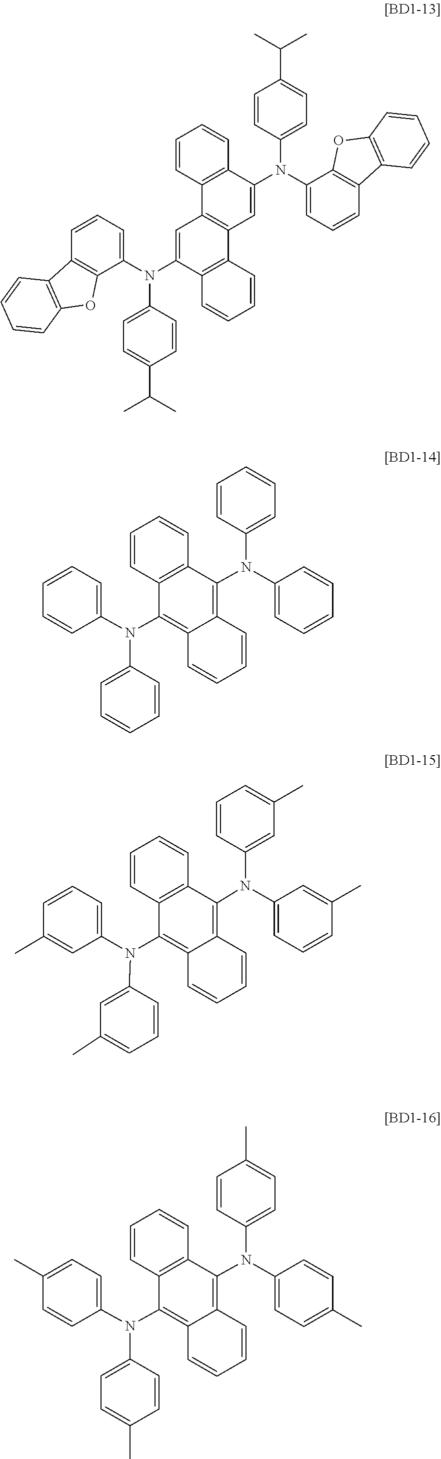

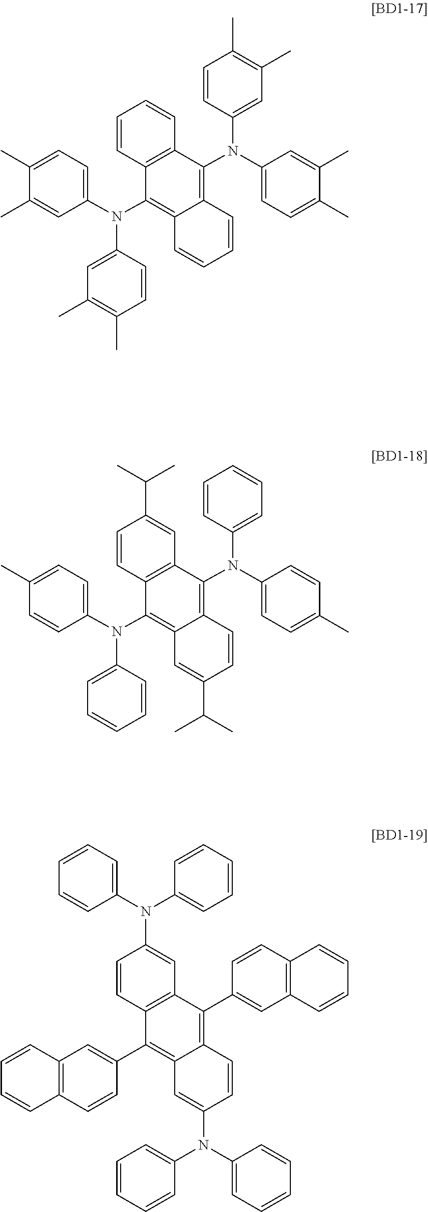

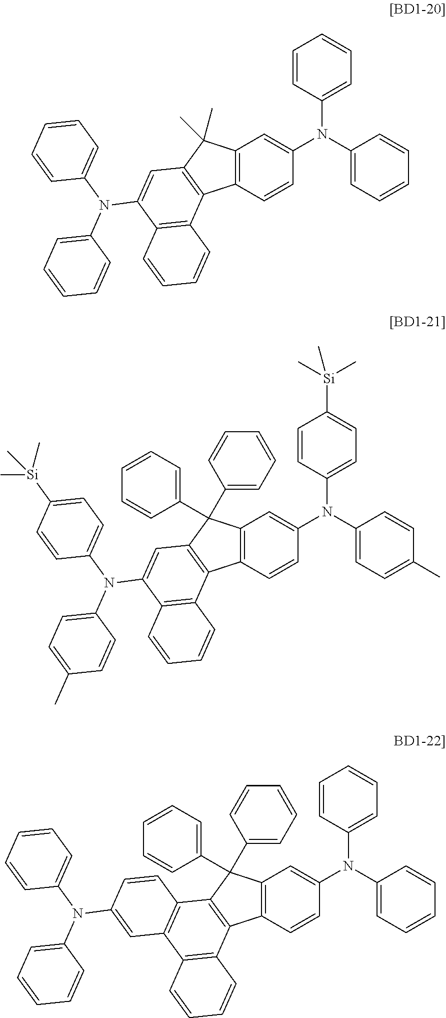

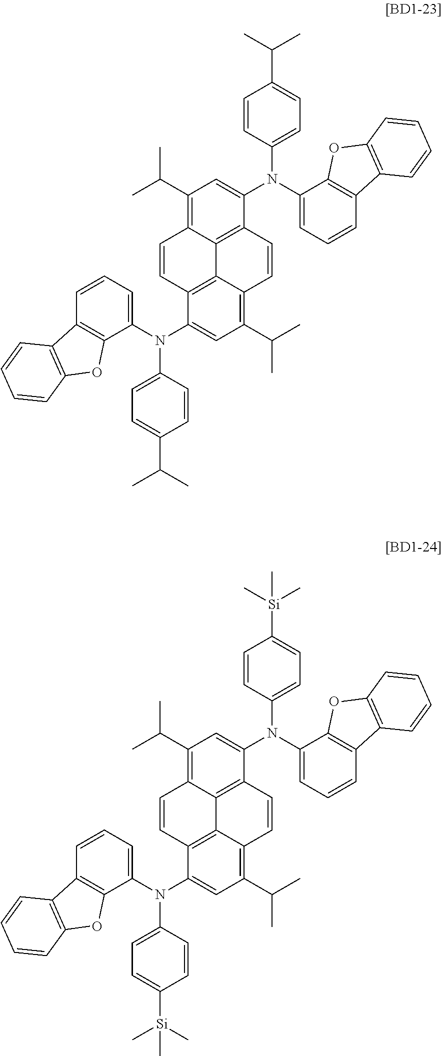 [SMILES: CC(C)c1ccc(N(c2cc(C(C)C)c3ccc4c(N(c5ccc(C(C)C)cc5)c5cccc6c5oc5ccccc56)cc(C(C)C)c5ccc2c3c54)c2cccc3c2oc2ccccc23)cc1 ; CC(C)c1cc(N(c2ccc([Si](C)(C)C)cc2)c2cccc3c2oc2ccccc23)c2ccc3c(C(C)C)cc(N(c4ccc([Si](C)(C)C)cc4)c4cccc5c4oc4ccccc45)c4ccc1c2c34]

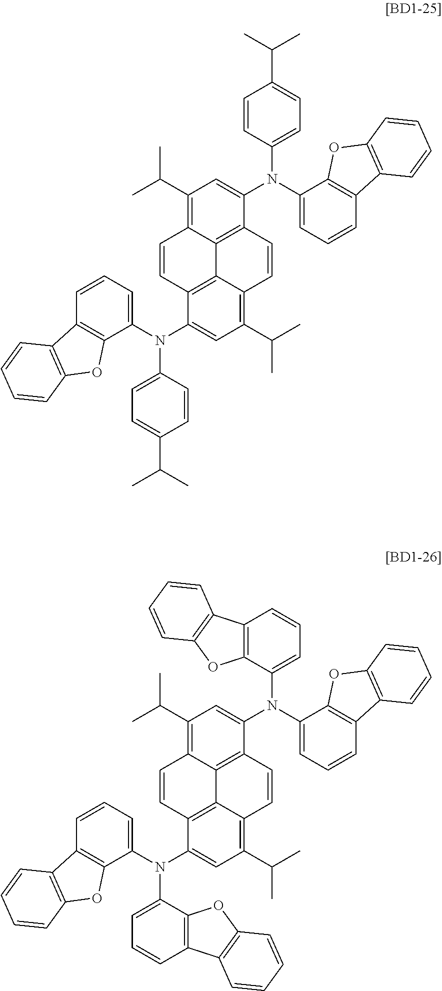 [SMILES: CC(C)c1ccc(N(c2cc(C(C)C)c3ccc4c(N(c5ccc(C(C)C)cc5)c5cccc6c5oc5ccccc56)cc(C(C)C)c5ccc2c3c54)c2cccc3c2oc2ccccc23)cc1 ; CC(C)c1cc(N(c2cccc3c2oc2ccccc23)c2cccc3c2oc2ccccc23)c2ccc3c(C(C)C)cc(N(c4cccc5c4oc4ccccc45)c4cccc5c4oc4ccccc45)c4ccc1c2c34]

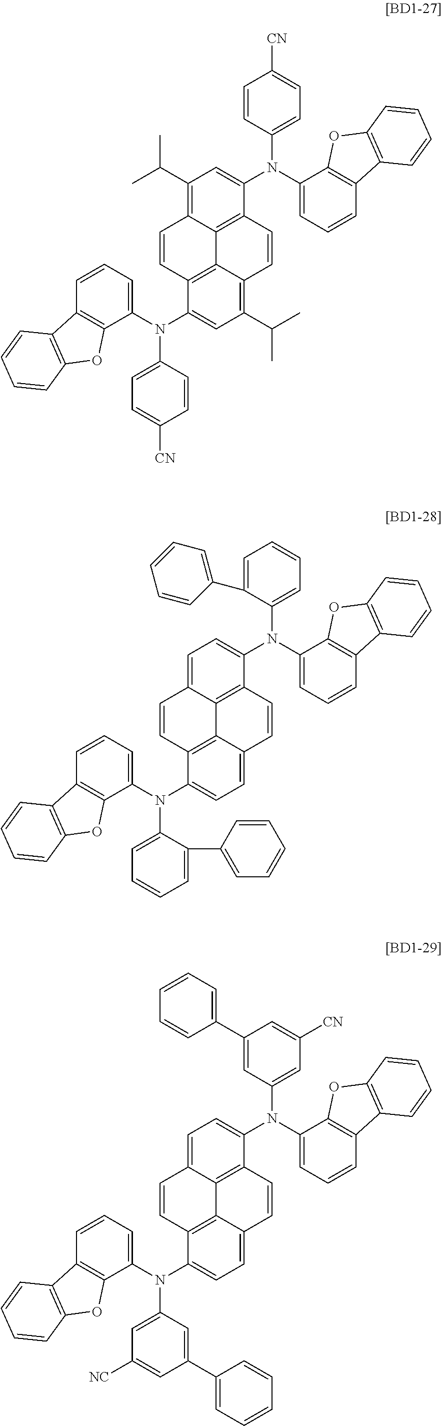 [SMILES: CC(C)c1cc(N(c2ccc(C#N)cc2)c2cccc3c2oc2ccccc23)c2ccc3c(C(C)C)cc(N(c4ccc(C#N)cc4)c4cccc5c4oc4ccccc45)c4ccc1c2c34 ; c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1 ; N#Cc1cc(-c2ccccc2)cc(N(c2ccc3ccc4c(N(c5cc(C#N)cc(-c6ccccc6)c5)c5cccc6c5oc5ccccc56)ccc5ccc2c3c54)c2cccc3c2oc2ccccc23)c1]

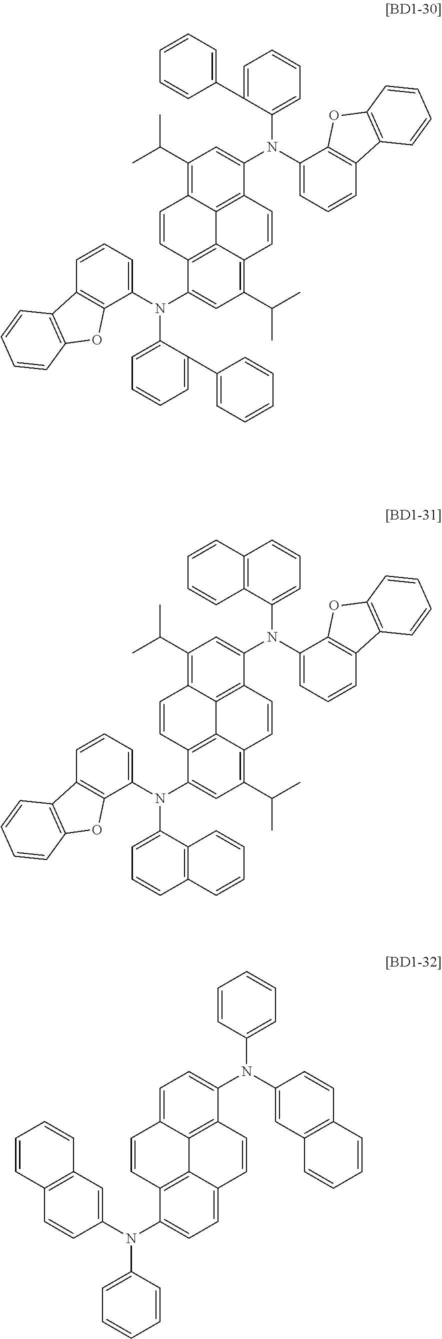 [SMILES: CC(C)c1cc(N(c2ccccc2-c2ccccc2)c2cccc3c2oc2ccccc23)c2ccc3c(C(C)C)cc(N(c4ccccc4-c4ccccc4)c4cccc5c4oc4ccccc45)c4ccc1c2c34 ; CC(C)c1cc(N(c2cccc3ccccc23)c2cccc3c2oc2ccccc23)c2ccc3c(C(C)C)cc(N(c4cccc5ccccc45)c4cccc5c4oc4ccccc45)c4ccc1c2c34 ; c1ccc(N(c2ccc3ccccc3c2)c2ccc3ccc4c(N(c5ccccc5)c5ccc6ccccc6c5)ccc5ccc2c3c54)cc1]

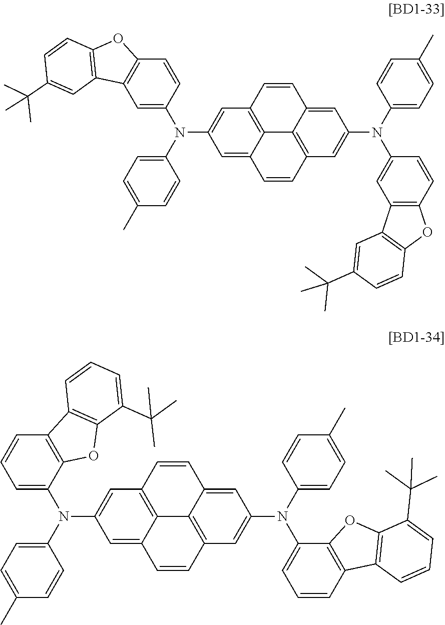 [SMILES: Cc1ccc(N(c2cc3ccc4cc(N(c5ccc(C)cc5)c5ccc6oc7ccc(C(C)(C)C)cc7c6c5)cc5ccc(c2)c3c45)c2ccc3oc4ccc(C(C)(C)C)cc4c3c2)cc1 ; Cc1ccc(N(c2cc3ccc4cc(N(c5ccc(C)cc5)c5cccc6c5oc5c(C(C)(C)C)cccc56)cc5ccc(c2)c3c45)c2cccc3c2oc2c(C(C)(C)C)cccc23)cc1]

In some embodiments, any one of the hydrogen atoms of the Compounds BD1-1 to BD1-34 may be independently replaced with a deuterium atom.

For example, the second light emitting layer may include a green phosphorescent host and a second dopant that emits light of a second wavelength. For example, the second wavelength may be greater than or equal to about 520 nm and less than or equal to about 600 nm, and the second dopant may be a green phosphorescent dopant.

The second light emitting layer may include a composition in which two different host materials are mixed.

In some embodiments, the second light emitting layer may include a composition in which a hole-transporting host and an electron-transporting host are mixed.

Examples of the hole-transporting host included in the second light emitting layer may include carbazole-based compounds. For example, it may be a compound in which a carbazole core, a bicarbazole core, or an indolocarbazole core is substituted with an aryl group, an amine group, a dibenzofuranyl group, etc.

Examples of the electron-transporting host included in the second light emitting layer may include carbazole-based compounds. For example, it may be a compound in which a carbazole core is substituted with a nitrogen-containing heteroaryl group other than carbazole.

As an example, the organic optoelectronic device may further include at least one stack including an additional light emitting layer that is disposed between the first light emitting layer and the second light emitting layer and emits light of the first wavelength

As an example, the intermediate hole transport regions 50-(1), 50-(2), and 50-(3) may include intermediate hole injection layers 52-(1), 52-(2) and 52-(3) disposed on the charge generation layers 40, 40-(1), 40-(2), and 40-(3) and intermediate hole transport layers 51-(1), 51-(2), and 51-(3) disposed on the intermediate hole injection layers. The intermediate hole transport region may further include at least one of an additional intermediate hole transport layer, a hole buffer layer, a light emitting auxiliary layer, and an electron blocking layer.

As an example, the intermediate electron transport region may include the intermediate electron transport layers 60-(1), 60-(2), and 60-(3) disposed on the light emitting layer. The intermediate electron transport region may further include an intermediate electron injection layer between the intermediate electron transport layer and the charge generation layer.

Meanwhile, it may further include the hole transport region 50 disposed between the anode 10 and the first light emitting layer 30-(1), 30-(1′), and 30-(1″), and the electron transport region 60 disposed between the cathode 20 and the second light emitting layers 30-(2).

The hole transport region can further increase hole injection and/or hole mobility and block electrons between the anode and the light emitting layer. Specifically, the hole transport region may optionally include the hole injection layer 52 between the anode and the light emitting layer, the hole transport layer 51 between the light emitting layer and the hole injection layer, and a hole transport auxiliary layer between the light emitting layer and the hole transport layer. At least one of the compounds listed in Group C, below, may be included in at least one layer among the hole injection layer 52, the hole transport layer 51, and the hole transport auxiliary layer.

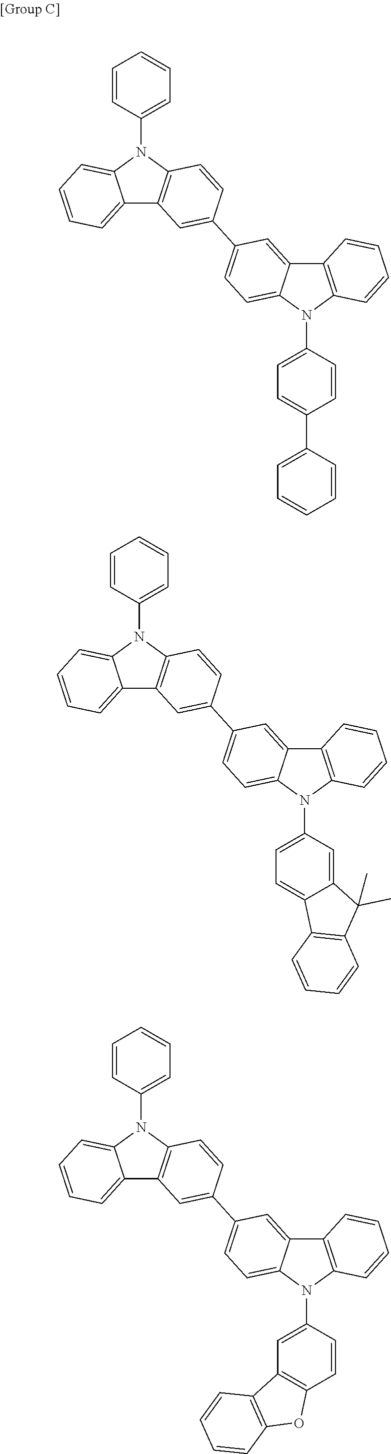 [SMILES: c1ccc(-c2ccc(-n3c4ccccc4c4cc(-c5ccc6c(c5)c5ccccc5n6-c5ccccc5)ccc43)cc2)cc1 ; CC1(C)c2ccccc2-c2ccc(-n3c4ccccc4c4cc(-c5ccc6c(c5)c5ccccc5n6-c5ccccc5)ccc43)cc21 ; c1ccc(-n2c3ccccc3c3cc(-c4ccc5c(c4)c4ccccc4n5-c4ccc5oc6ccccc6c5c4)ccc32)cc1]

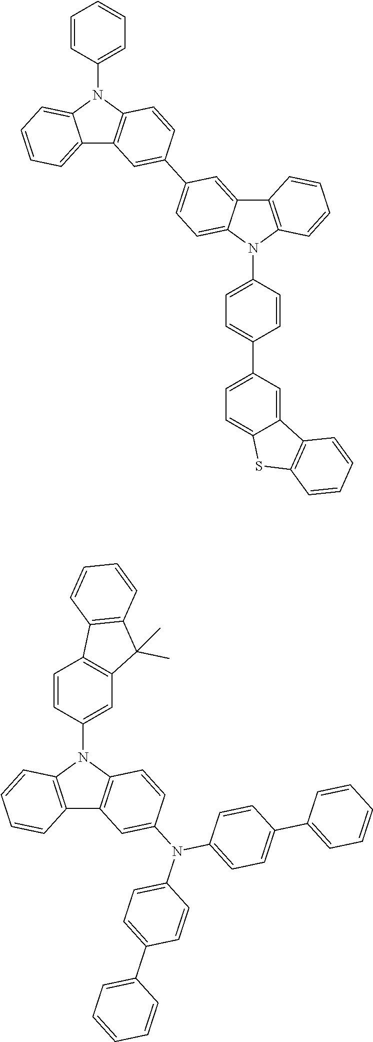 [SMILES: c1ccc(-n2c3ccccc3c3cc(-c4ccc5c(c4)c4ccccc4n5-c4ccc(-c5ccc6sc7ccccc7c6c5)cc4)ccc32)cc1 ; CC1(C)c2ccccc2-c2ccc(-n3c4ccccc4c4cc(N(c5ccc(-c6ccccc6)cc5)c5ccc(-c6ccccc6)cc5)ccc43)cc21]

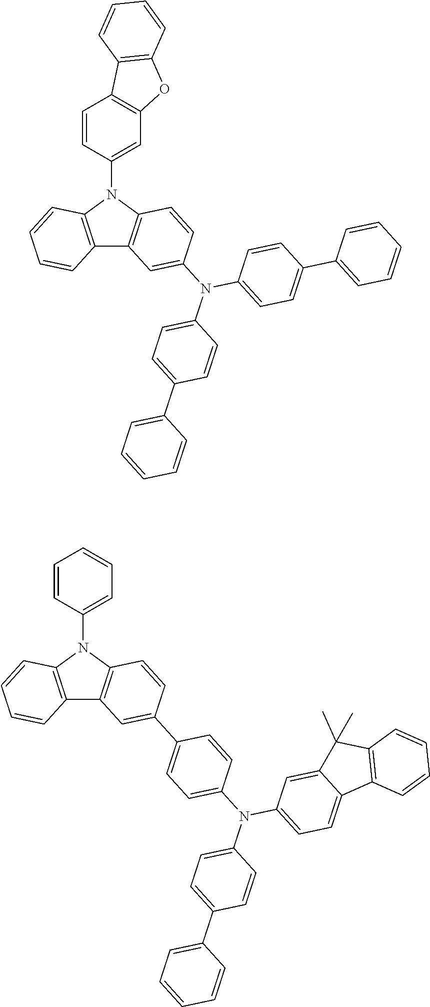 [SMILES: c1ccc(-c2ccc(N(c3ccc(-c4ccccc4)cc3)c3ccc4c(c3)c3ccccc3n4-c3ccc4c(c3)oc3ccccc34)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

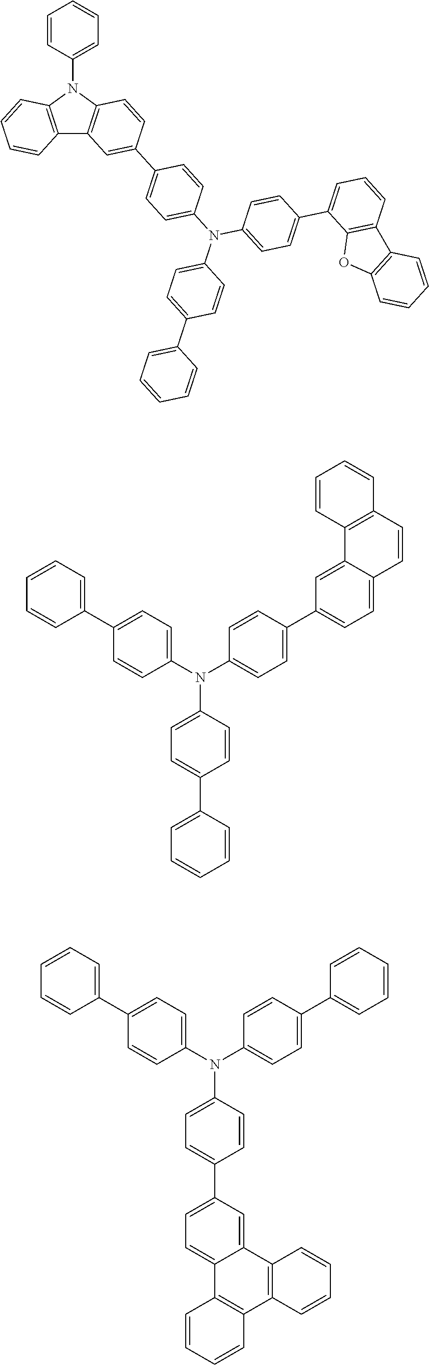 [SMILES: c1ccc(-c2ccc(N(c3ccc(-c4ccc5c(c4)c4ccccc4n5-c4ccccc4)cc3)c3ccc(-c4cccc5c4oc4ccccc45)cc3)cc2)cc1 ; c1ccc(-c2ccc(N(c3ccc(-c4ccccc4)cc3)c3ccc(-c4ccc5ccc6ccccc6c5c4)cc3)cc2)cc1 ; c1ccc(-c2ccc(N(c3ccc(-c4ccccc4)cc3)c3ccc(-c4ccc5c6ccccc6c6ccccc6c5c4)cc3)cc2)cc1]

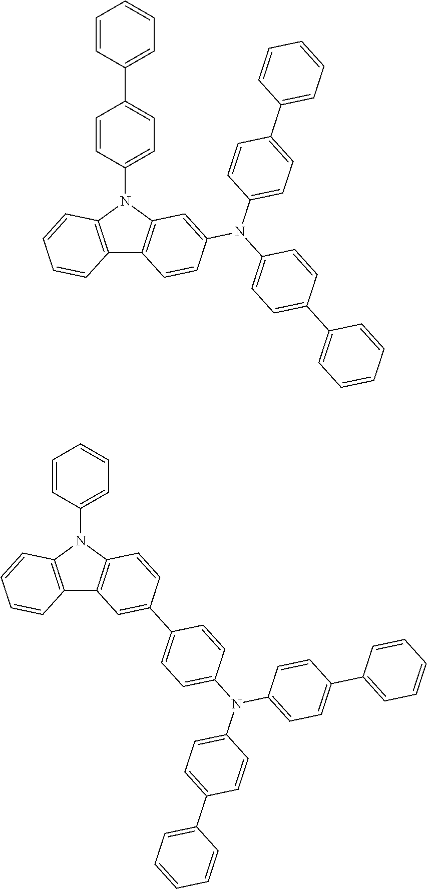 [SMILES: c1ccc(-c2ccc(N(c3ccc(-c4ccccc4)cc3)c3ccc4c5ccccc5n(-c5ccc(-c6ccccc6)cc5)c4c3)cc2)cc1 ; c1ccc(-c2ccc(N(c3ccc(-c4ccccc4)cc3)c3ccc(-c4ccc5c(c4)c4ccccc4n5-c4ccccc4)cc3)cc2)cc1]

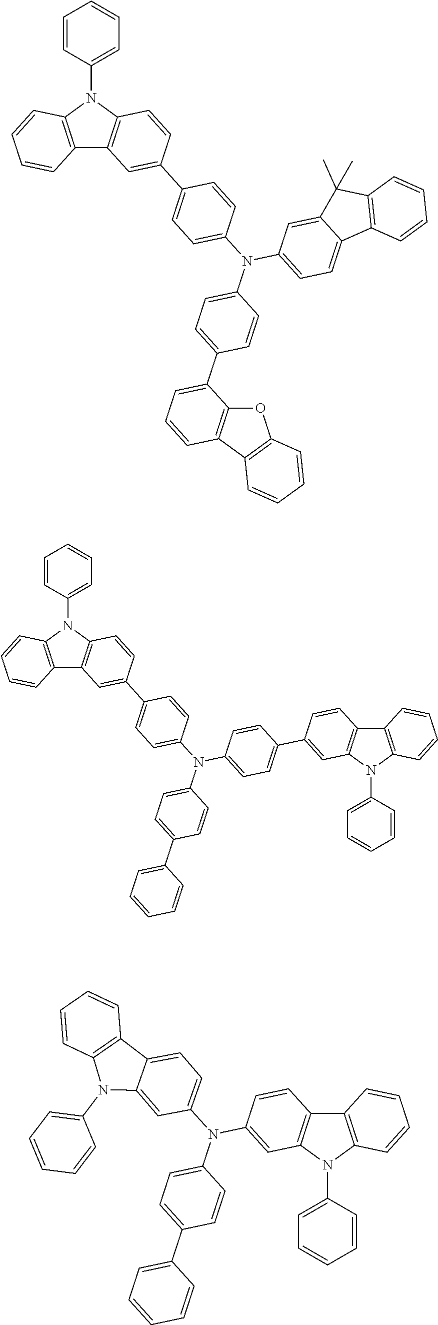 [SMILES: CC1(C)c2ccccc2-c2ccc(N(c3ccc(-c4ccc5c(c4)c4ccccc4n5-c4ccccc4)cc3)c3ccc(-c4cccc5c4oc4ccccc45)cc3)cc21 ; c1ccc(-c2ccc(N(c3ccc(-c4ccc5c(c4)c4ccccc4n5-c4ccccc4)cc3)c3ccc(-c4ccc5c6ccccc6n(-c6ccccc6)c5c4)cc3)cc2)cc1 ; c1ccc(-c2ccc(N(c3ccc4c5ccccc5n(-c5ccccc5)c4c3)c3ccc4c5ccccc5n(-c5ccccc5)c4c3)cc2)cc1]

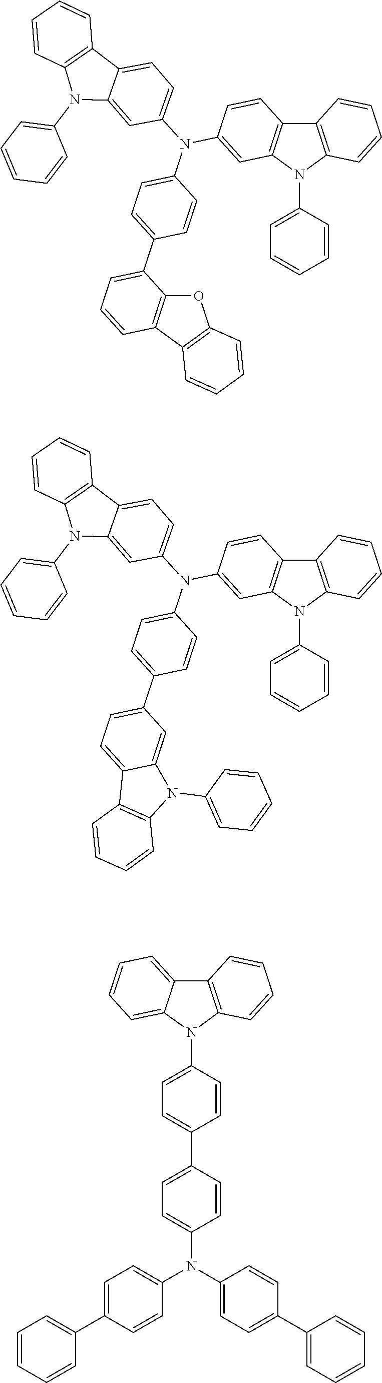 [SMILES: c1ccc(-n2c3ccccc3c3ccc(N(c4ccc(-c5cccc6c5oc5ccccc56)cc4)c4ccc5c6ccccc6n(-c6ccccc6)c5c4)cc32)cc1 ; c1ccc(-n2c3ccccc3c3ccc(-c4ccc(N(c5ccc6c7ccccc7n(-c7ccccc7)c6c5)c5ccc6c7ccccc7n(-c7ccccc7)c6c5)cc4)cc32)cc1 ; c1ccc(-c2ccc(N(c3ccc(-c4ccccc4)cc3)c3ccc(-c4ccc(-n5c6ccccc6c6ccccc65)cc4)cc3)cc2)cc1]

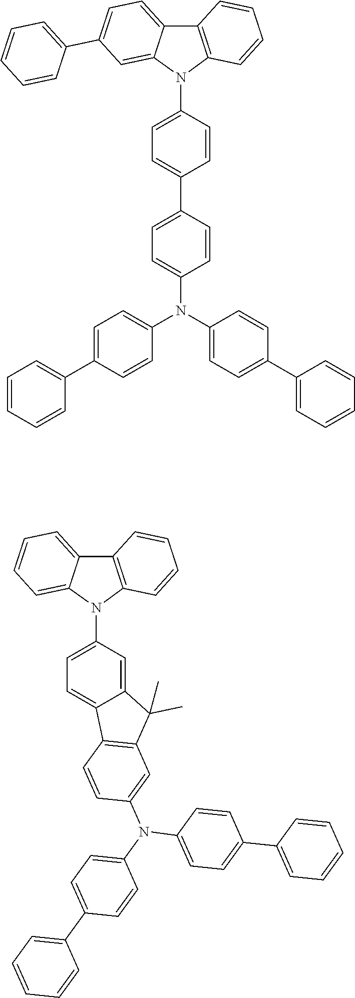 [SMILES: c1ccc(-c2ccc(N(c3ccc(-c4ccccc4)cc3)c3ccc(-c4ccc(-n5c6ccccc6c6ccc(-c7ccccc7)cc65)cc4)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21]

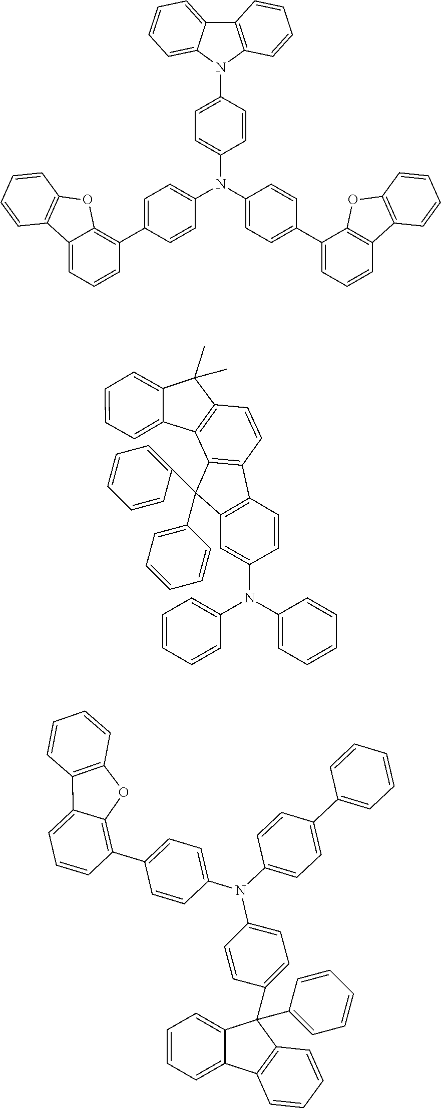 [SMILES: c1ccc2c(c1)oc1c(-c3ccc(N(c4ccc(-c5cccc6c5oc5ccccc56)cc4)c4ccc(-n5c6ccccc6c6ccccc65)cc4)cc3)cccc12 ; CC1(C)c2ccccc2-c2c1ccc1c2C(c2ccccc2)(c2ccccc2)c2cc(N(c3ccccc3)c3ccccc3)ccc2-1 ; c1ccc(-c2ccc(N(c3ccc(-c4cccc5c4oc4ccccc45)cc3)c3ccc(C4(c5ccccc5)c5ccccc5-c5ccccc54)cc3)cc2)cc1]

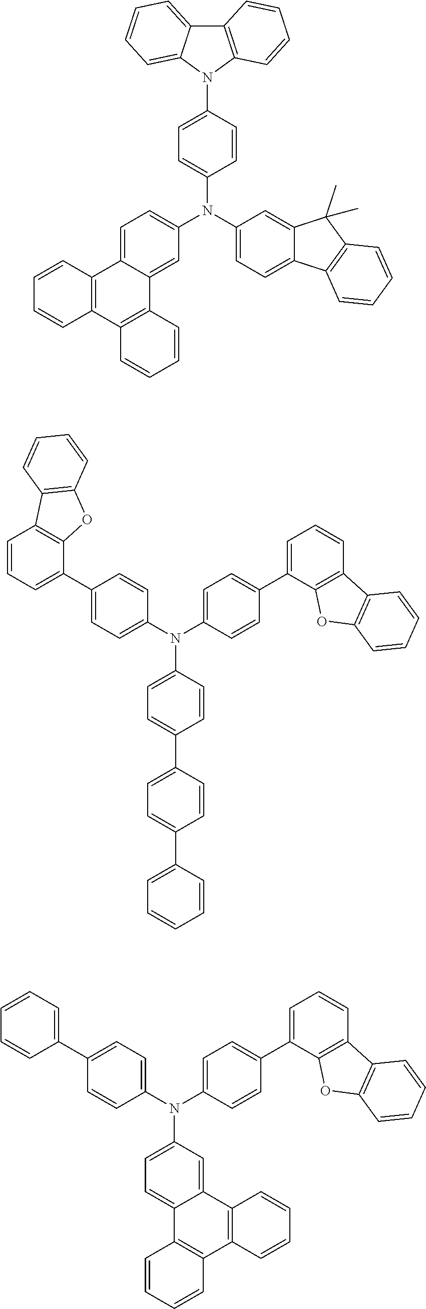 [SMILES: CC1(C)c2ccccc2-c2ccc(N(c3ccc(-n4c5ccccc5c5ccccc54)cc3)c3ccc4c5ccccc5c5ccccc5c4c3)cc21 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(N(c3ccc(-c4cccc5c4oc4ccccc45)cc3)c3ccc4c5ccccc5c5ccccc5c4c3)cc2)cc1]

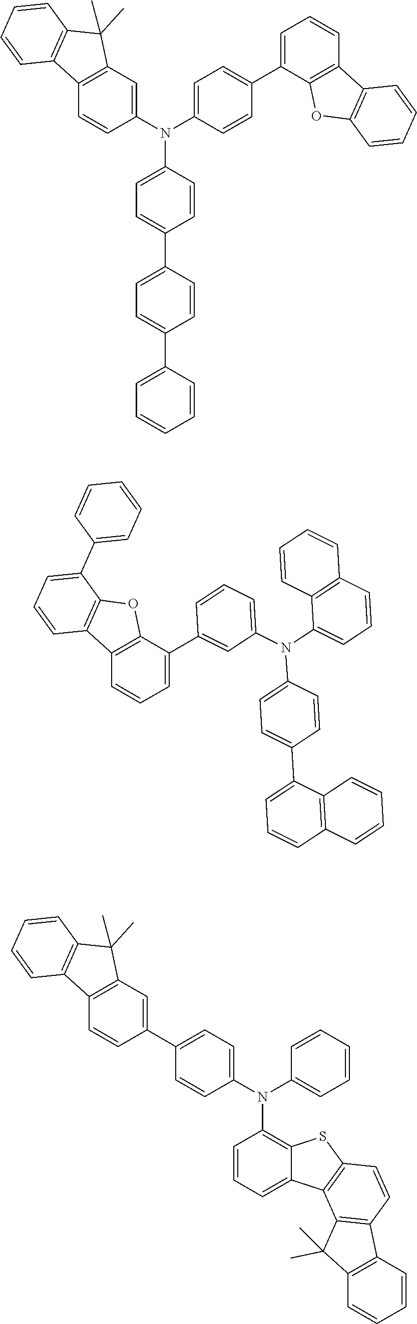 [SMILES: CC1(C)c2ccccc2-c2ccc(N(c3ccc(-c4ccc(-c5ccccc5)cc4)cc3)c3ccc(-c4cccc5c4oc4ccccc45)cc3)cc21 ; c1ccc(-c2cccc3c2oc2c(-c4cccc(N(c5ccc(-c6cccc7ccccc67)cc5)c5cccc6ccccc56)c4)cccc23)cc1 ; CC1(C)c2ccccc2-c2ccc(-c3ccc(N(c4ccccc4)c4cccc5c4sc4ccc6c(c45)C(C)(C)c4ccccc4-6)cc3)cc21]

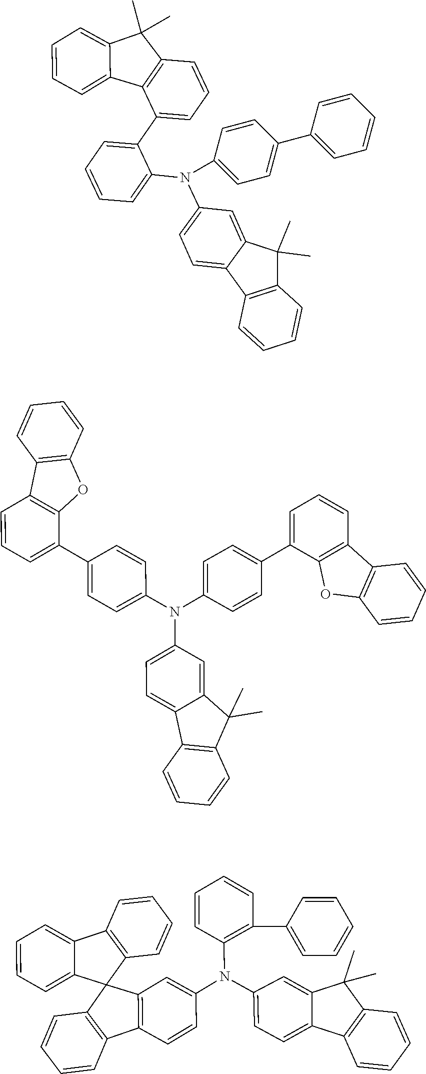 [SMILES: CC1(C)c2ccccc2-c2ccc(N(c3ccc(-c4ccccc4)cc3)c3ccccc3-c3cccc4c3-c3ccccc3C4(C)C)cc21 ; CC1(C)c2ccccc2-c2ccc(N(c3ccc(-c4cccc5c4oc4ccccc45)cc3)c3ccc(-c4cccc5c4oc4ccccc45)cc3)cc21 ; CC1(C)c2ccccc2-c2ccc(N(c3ccc4c(c3)C3(c5ccccc5-c5ccccc53)c3ccccc3-4)c3ccccc3-c3ccccc3)cc21]

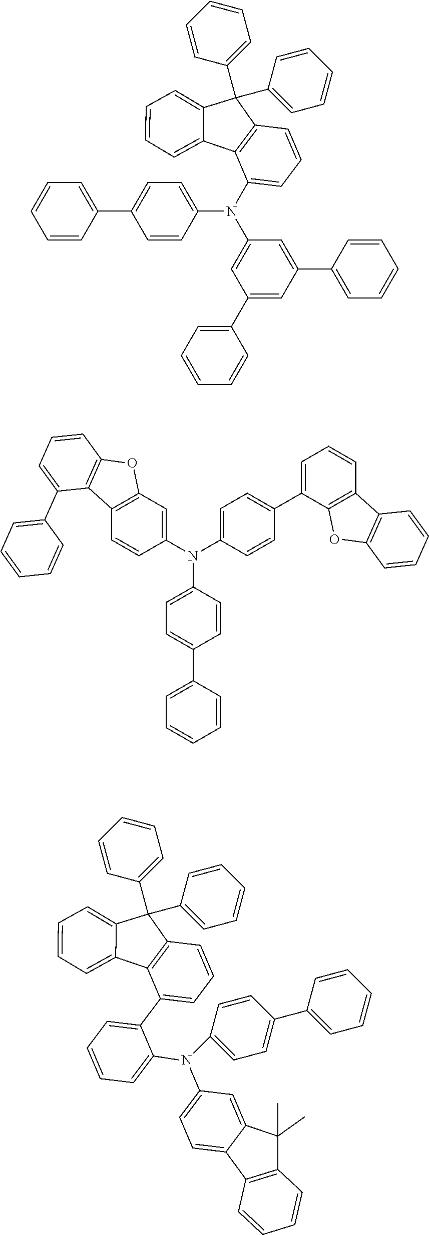 [SMILES: c1ccc(-c2ccc(N(c3cc(-c4ccccc4)cc(-c4ccccc4)c3)c3cccc4c3-c3ccccc3C4(c3ccccc3)c3ccccc3)cc2)cc1 ; c1ccc(-c2ccc(N(c3ccc(-c4cccc5c4oc4ccccc45)cc3)c3ccc4c(c3)oc3cccc(-c5ccccc5)c34)cc2)cc1 ; CC1(C)c2ccccc2-c2ccc(N(c3ccc(-c4ccccc4)cc3)c3ccccc3-c3cccc4c3-c3ccccc3C4(c3ccccc3)c3ccccc3)cc21]

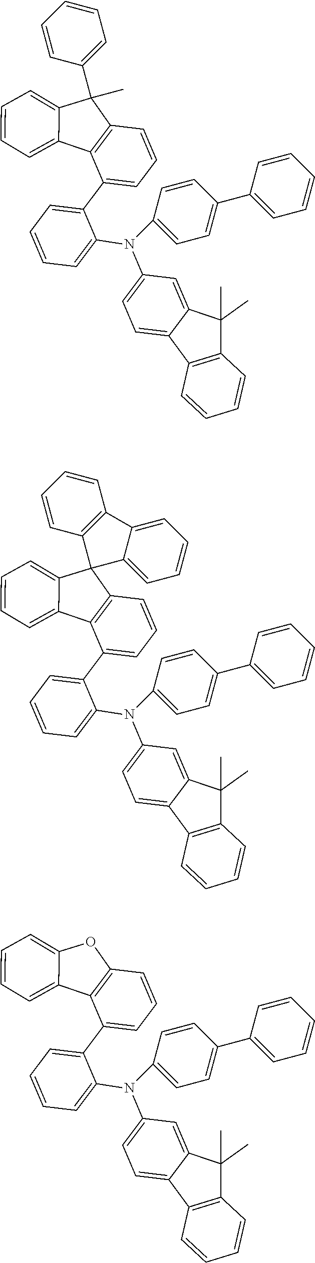 [SMILES: CC1(C)c2ccccc2-c2ccc(N(c3ccc(-c4ccccc4)cc3)c3ccccc3-c3cccc4c3-c3ccccc3C4(C)c3ccccc3)cc21 ; CC1(C)c2ccccc2-c2ccc(N(c3ccc(-c4ccccc4)cc3)c3ccccc3-c3cccc4c3-c3ccccc3C43c4ccccc4-c4ccccc43)cc21 ; CC1(C)c2ccccc2-c2ccc(N(c3ccc(-c4ccccc4)cc3)c3ccccc3-c3cccc4oc5ccccc5c34)cc21]

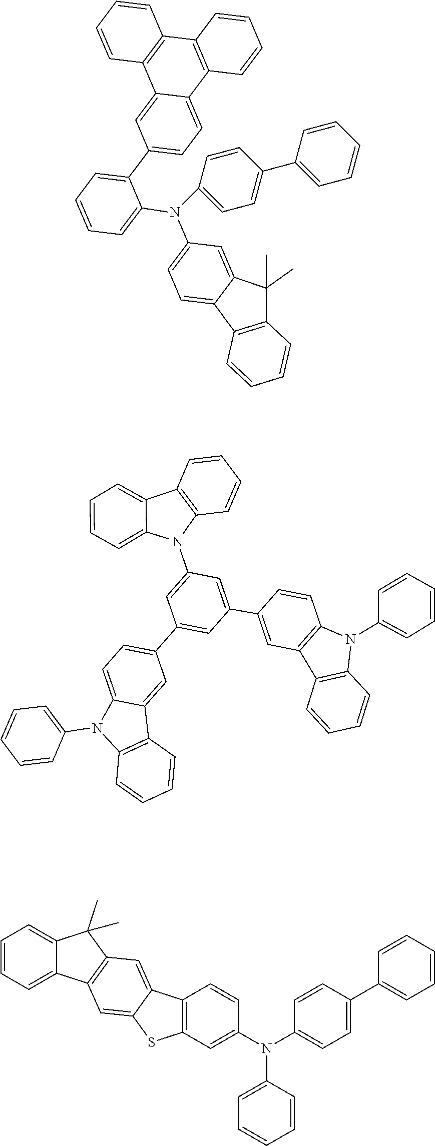 [SMILES: CC1(C)c2ccccc2-c2ccc(N(c3ccc(-c4ccccc4)cc3)c3ccccc3-c3ccc4c5ccccc5c5ccccc5c4c3)cc21 ; c1ccc(-n2c3ccccc3c3cc(-c4cc(-c5ccc6c(c5)c5ccccc5n6-c5ccccc5)cc(-n5c6ccccc6c6ccccc65)c4)ccc32)cc1 ; CC1(C)c2ccccc2-c2cc3sc4cc(N(c5ccccc5)c5ccc(-c6ccccc6)cc5)ccc4c3cc21]

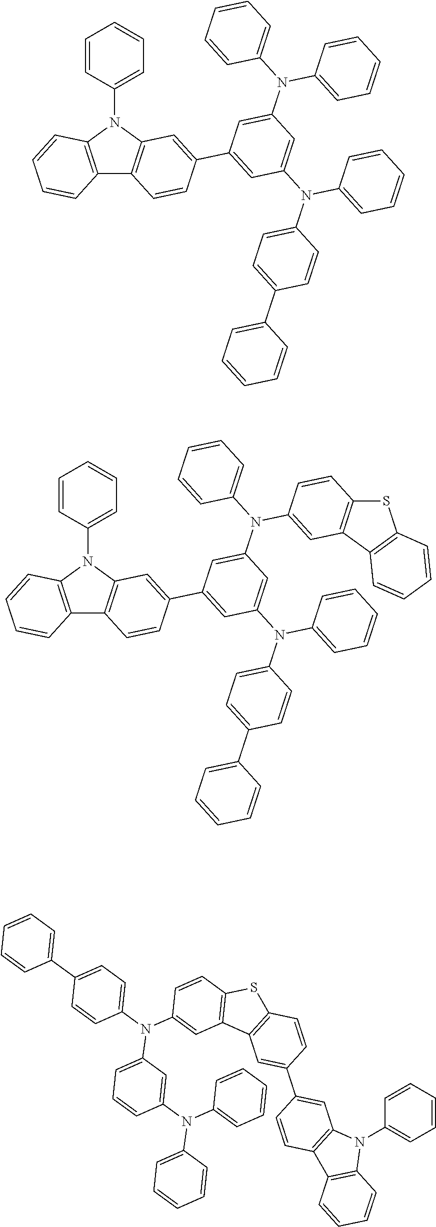 [SMILES: c1ccc(-c2ccc(N(c3ccccc3)c3cc(-c4ccc5c6ccccc6n(-c6ccccc6)c5c4)cc(N(c4ccccc4)c4ccccc4)c3)cc2)cc1 ; c1ccc(-c2ccc(N(c3ccccc3)c3cc(-c4ccc5c6ccccc6n(-c6ccccc6)c5c4)cc(N(c4ccccc4)c4ccc5sc6ccccc6c5c4)c3)cc2)cc1 ; c1ccc(-c2ccc(N(c3cccc(N(c4ccccc4)c4ccccc4)c3)c3ccc4sc5ccc(-c6ccc7c8ccccc8n(-c8ccccc8)c7c6)cc5c4c3)cc2)cc1]

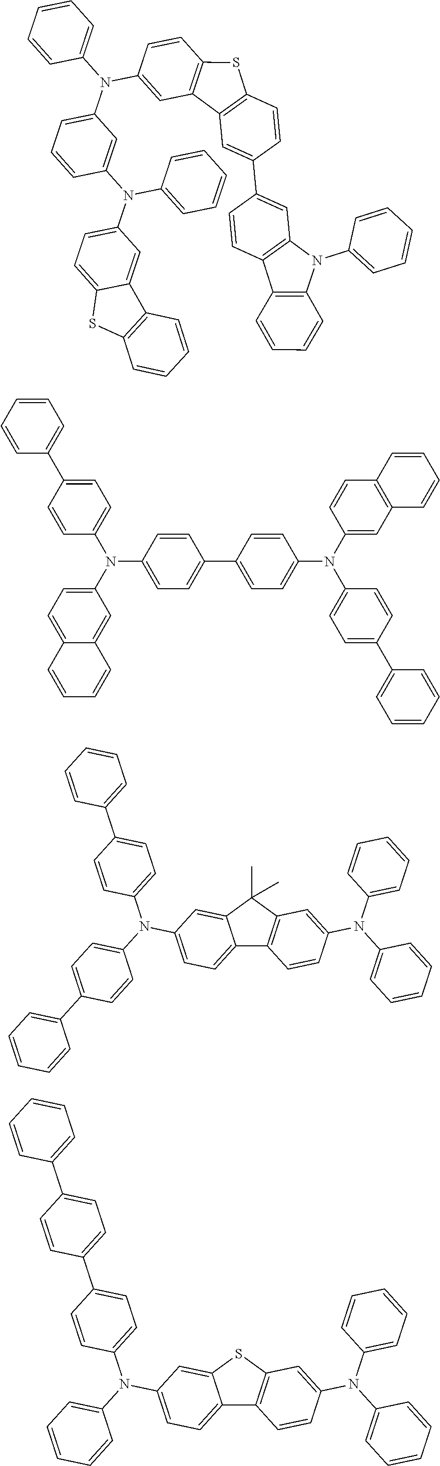

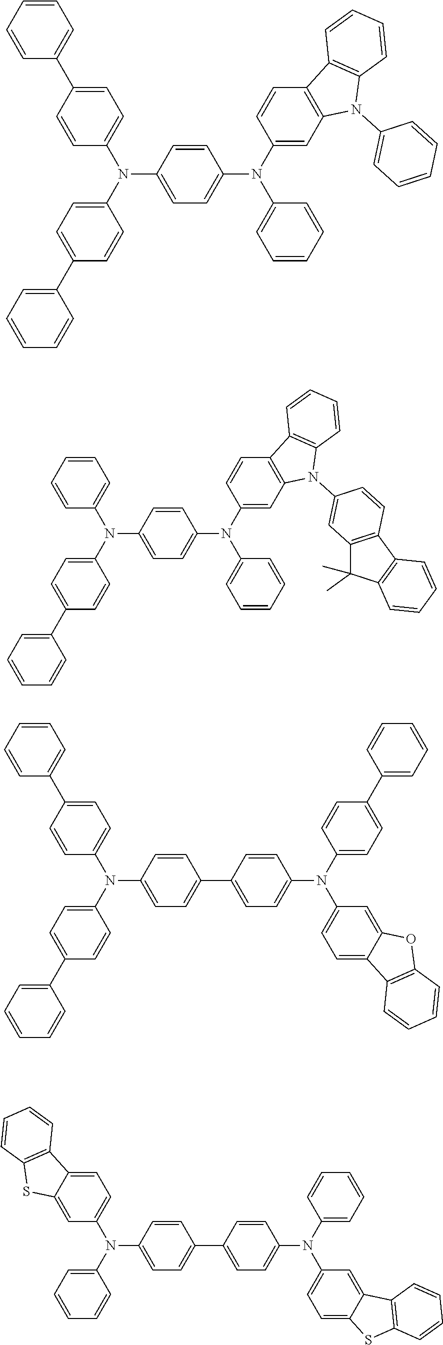

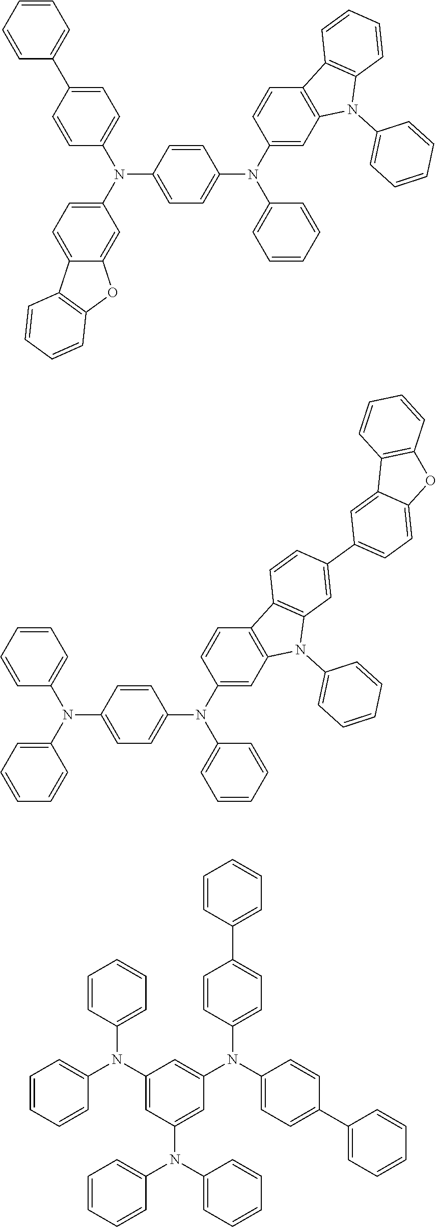 [SMILES: c1ccc(-c2ccc(N(c3ccc(N(c4ccccc4)c4ccc5c6ccccc6n(-c6ccccc6)c5c4)cc3)c3ccc4c(c3)oc3ccccc34)cc2)cc1 ; c1ccc(N(c2ccccc2)c2ccc(N(c3ccccc3)c3ccc4c5ccc(-c6ccc7oc8ccccc8c7c6)cc5n(-c5ccccc5)c4c3)cc2)cc1 ; c1ccc(-c2ccc(N(c3ccc(-c4ccccc4)cc3)c3cc(N(c4ccccc4)c4ccccc4)cc(N(c4ccccc4)c4ccccc4)c3)cc2)cc1]

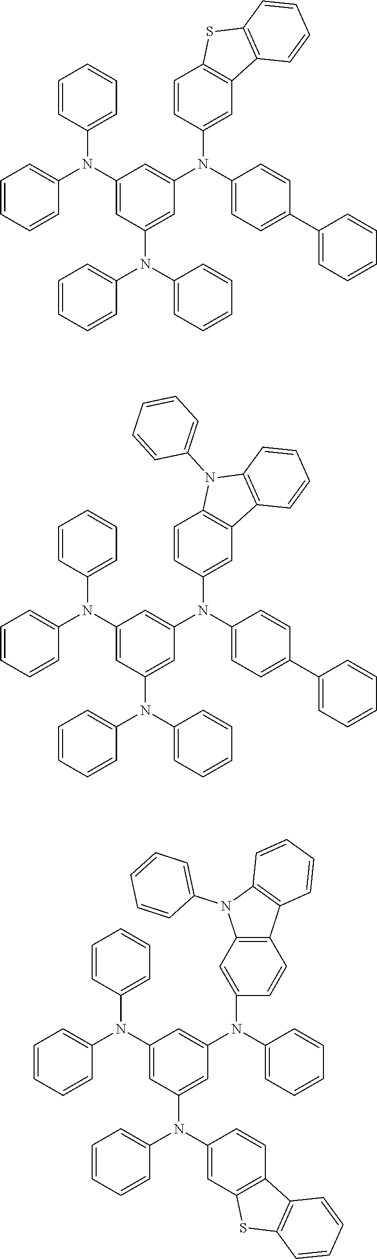 [SMILES: c1ccc(-c2ccc(N(c3cc(N(c4ccccc4)c4ccccc4)cc(N(c4ccccc4)c4ccccc4)c3)c3ccc4sc5ccccc5c4c3)cc2)cc1 ; c1ccc(-c2ccc(N(c3cc(N(c4ccccc4)c4ccccc4)cc(N(c4ccccc4)c4ccccc4)c3)c3ccc4c(c3)c3ccccc3n4-c3ccccc3)cc2)cc1 ; c1ccc(N(c2ccccc2)c2cc(N(c3ccccc3)c3ccc4c(c3)sc3ccccc34)cc(N(c3ccccc3)c3ccc4c5ccccc5n(-c5ccccc5)c4c3)c2)cc1]

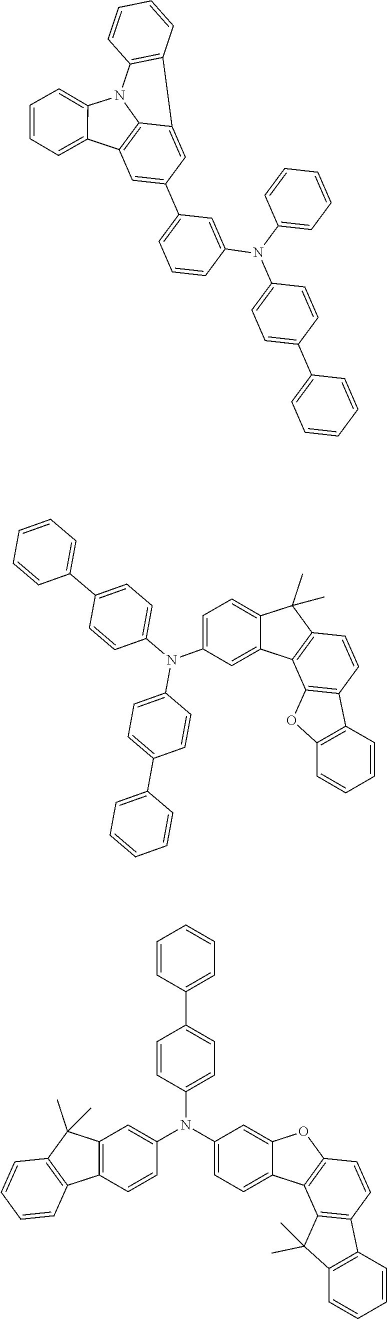 [SMILES: c1ccc(-c2ccc(N(c3ccccc3)c3cccc(-c4cc5c6ccccc6n6c7ccccc7c(c4)c56)c3)cc2)cc1 ; CC1(C)c2ccc(N(c3ccc(-c4ccccc4)cc3)c3ccc(-c4ccccc4)cc3)cc2-c2c1ccc1c2oc2ccccc21 ; CC1(C)c2ccccc2-c2ccc(N(c3ccc(-c4ccccc4)cc3)c3ccc4c(c3)oc3ccc5c(c34)C(C)(C)c3ccccc3-5)cc21]

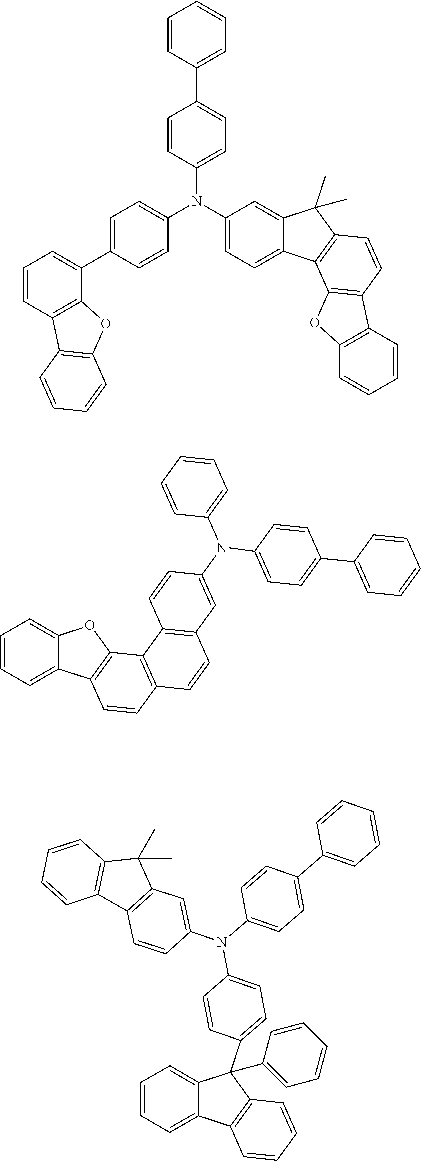 [SMILES: CC1(C)c2cc(N(c3ccc(-c4ccccc4)cc3)c3ccc(-c4cccc5c4oc4ccccc45)cc3)ccc2-c2c1ccc1c2oc2ccccc21 ; c1ccc(-c2ccc(N(c3ccccc3)c3ccc4c(ccc5ccc6c7ccccc7oc6c54)c3)cc2)cc1 ; CC1(C)c2ccccc2-c2ccc(N(c3ccc(-c4ccccc4)cc3)c3ccc(C4(c5ccccc5)c5ccccc5-c5ccccc54)cc3)cc21]

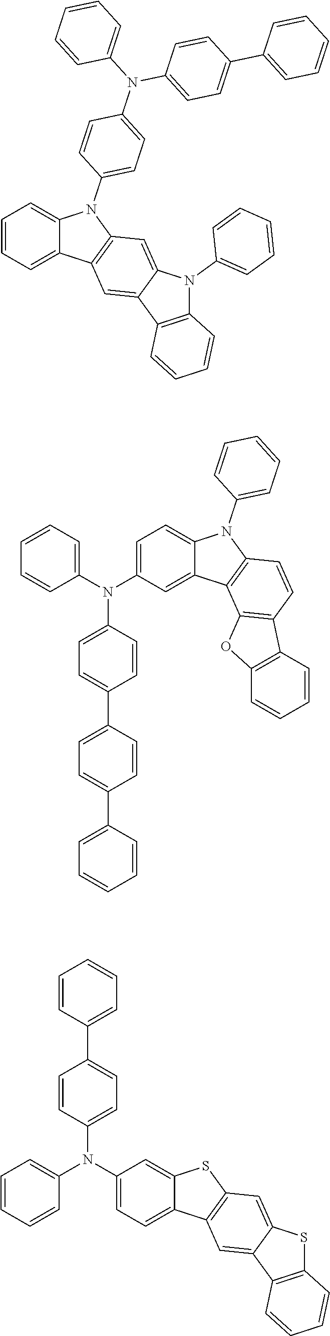 [SMILES: c1ccc(-c2ccc(N(c3ccccc3)c3ccc(-n4c5ccccc5c5cc6c7ccccc7n(-c7ccccc7)c6cc54)cc3)cc2)cc1 ; c1ccc(-c2ccc(-c3ccc(N(c4ccccc4)c4ccc5c(c4)c4c6oc7ccccc7c6ccc4n5-c4ccccc4)cc3)cc2)cc1 ; c1ccc(-c2ccc(N(c3ccccc3)c3ccc4c(c3)sc3cc5sc6ccccc6c5cc34)cc2)cc1]

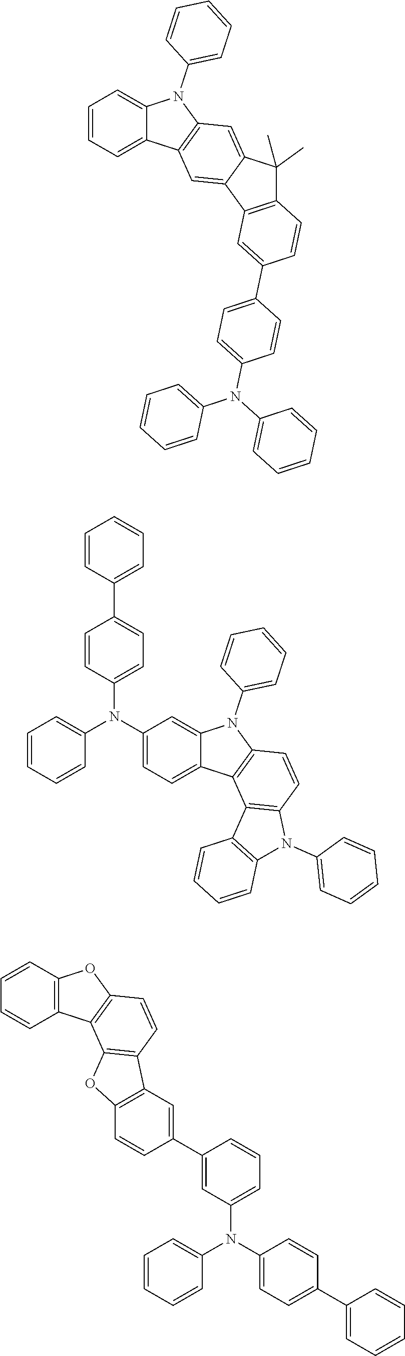 [SMILES: CC1(C)c2ccc(-c3ccc(N(c4ccccc4)c4ccccc4)cc3)cc2-c2cc3c4ccccc4n(-c4ccccc4)c3cc21 ; c1ccc(-c2ccc(N(c3ccccc3)c3ccc4c5c6c7ccccc7n(-c7ccccc7)c6ccc5n(-c5ccccc5)c4c3)cc2)cc1 ; c1ccc(-c2ccc(N(c3ccccc3)c3cccc(-c4ccc5oc6c(ccc7oc8ccccc8c76)c5c4)c3)cc2)cc1]

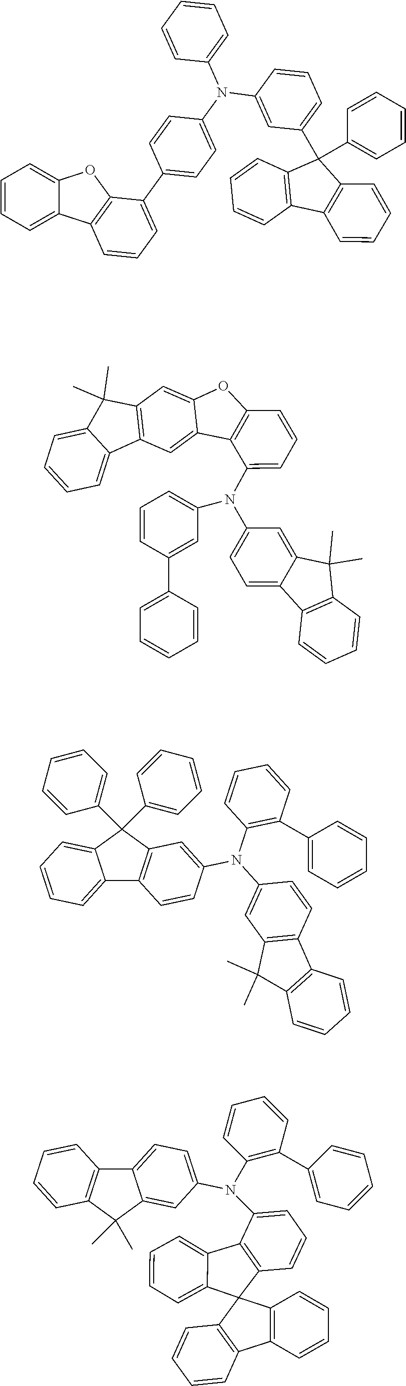 [SMILES: c1ccc(N(c2ccc(-c3cccc4c3oc3ccccc34)cc2)c2cccc(C3(c4ccccc4)c4ccccc4-c4ccccc43)c2)cc1 ; CC1(C)c2ccccc2-c2ccc(N(c3cccc(-c4ccccc4)c3)c3cccc4oc5cc6c(cc5c34)-c3ccccc3C6(C)C)cc21 ; CC1(C)c2ccccc2-c2ccc(N(c3ccc4c(c3)C(c3ccccc3)(c3ccccc3)c3ccccc3-4)c3ccccc3-c3ccccc3)cc21 ; CC1(C)c2ccccc2-c2ccc(N(c3ccccc3-c3ccccc3)c3cccc4c3-c3ccccc3C43c4ccccc4-c4ccccc43)cc21]

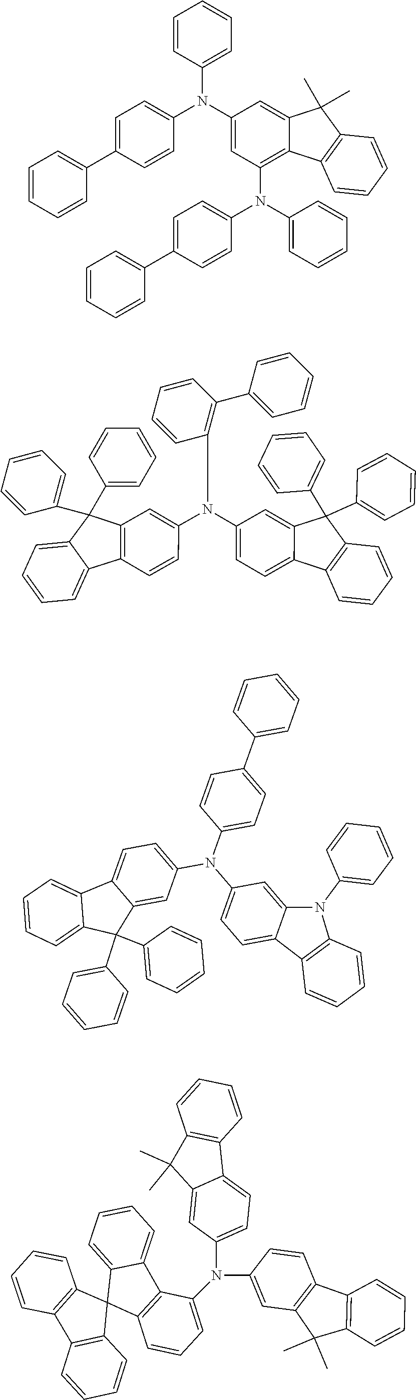 [SMILES: CC1(C)c2ccccc2-c2c(N(c3ccccc3)c3ccc(-c4ccccc4)cc3)cc(N(c3ccccc3)c3ccc(-c4ccccc4)cc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc4c(c3)C(c3ccccc3)(c3ccccc3)c3ccccc3-4)c3ccc4c5ccccc5n(-c5ccccc5)c4c3)cc2)cc1 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

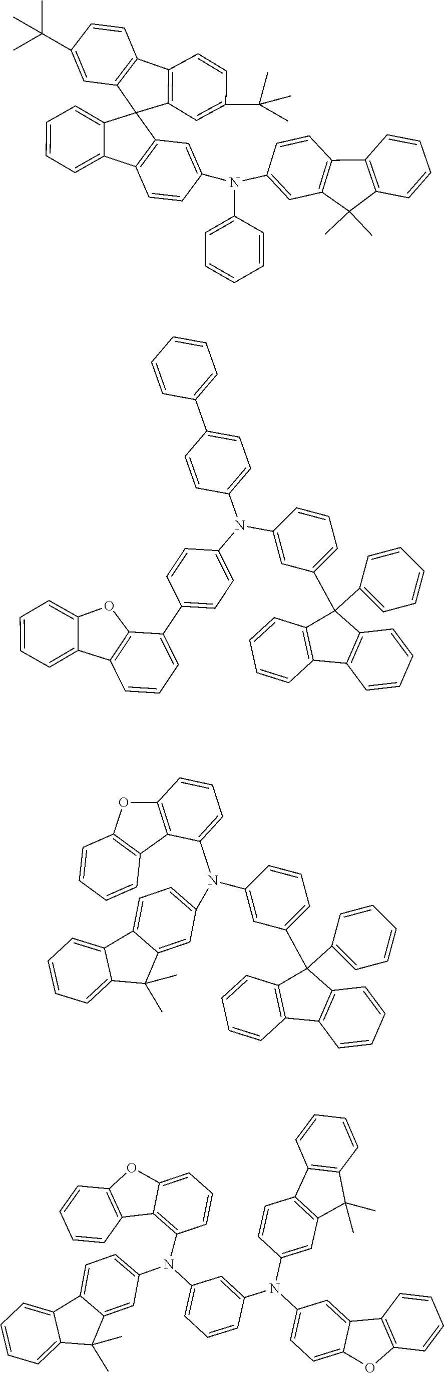

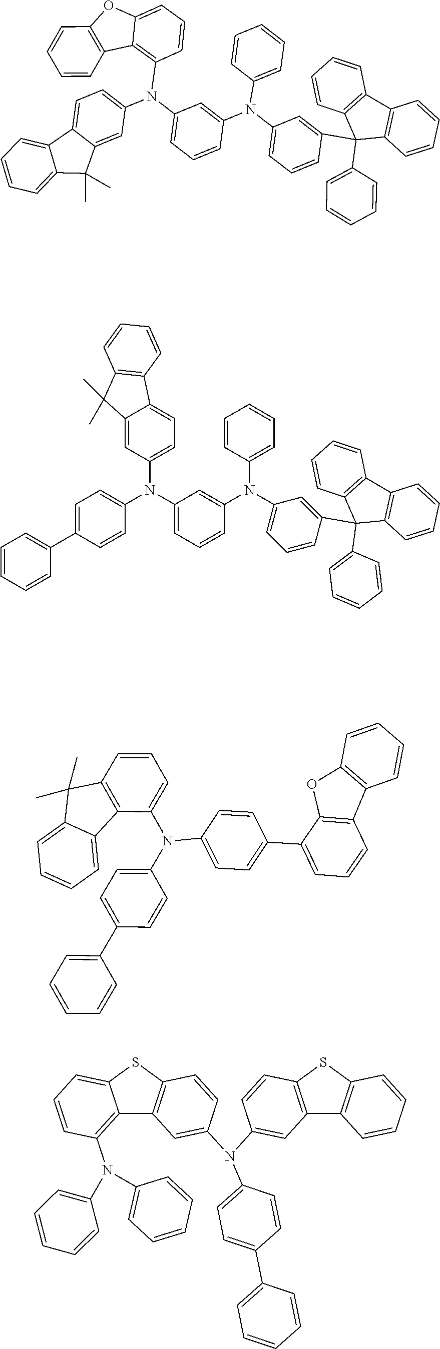 [SMILES: CC1(C)c2ccccc2-c2ccc(N(c3cccc(N(c4ccccc4)c4cccc(C5(c6ccccc6)c6ccccc6-c6ccccc65)c4)c3)c3cccc4oc5ccccc5c34)cc21 ; CC1(C)c2ccccc2-c2ccc(N(c3ccc(-c4ccccc4)cc3)c3cccc(N(c4ccccc4)c4cccc(C5(c6ccccc6)c6ccccc6-c6ccccc65)c4)c3)cc21 ; CC1(C)c2ccccc2-c2c(N(c3ccc(-c4ccccc4)cc3)c3ccc(-c4cccc5c4oc4ccccc45)cc3)cccc21 ; c1ccc(-c2ccc(N(c3ccc4sc5ccccc5c4c3)c3ccc4sc5cccc(N(c6ccccc6)c6ccccc6)c5c4c3)cc2)cc1]

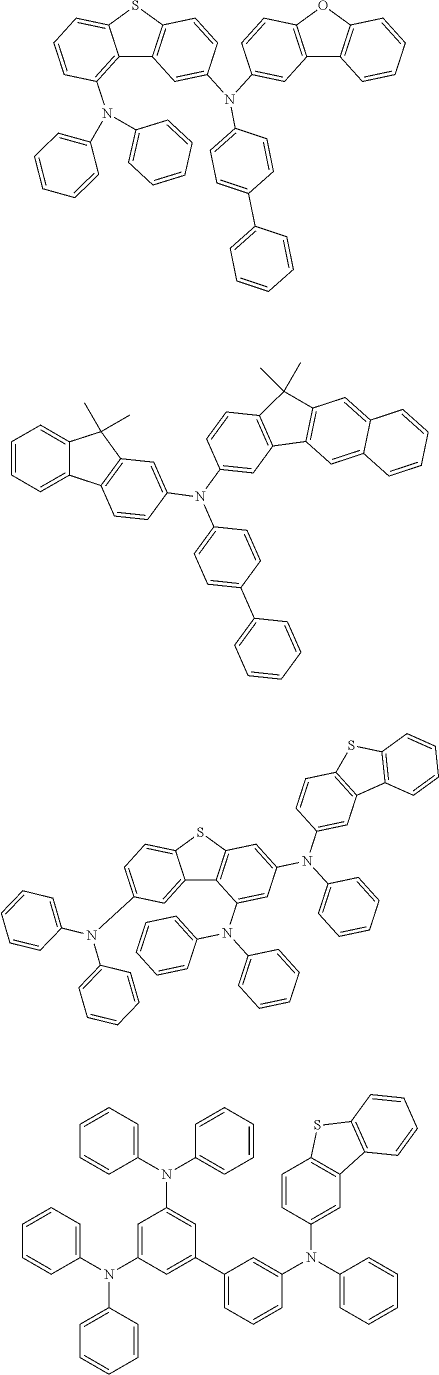 [SMILES: c1ccc(-c2ccc(N(c3ccc4oc5ccccc5c4c3)c3ccc4sc5cccc(N(c6ccccc6)c6ccccc6)c5c4c3)cc2)cc1 ; CC1(C)c2ccccc2-c2ccc(N(c3ccc(-c4ccccc4)cc3)c3ccc4c(c3)-c3cc5ccccc5cc3C4(C)C)cc21 ; c1ccc(N(c2cc(N(c3ccccc3)c3ccccc3)c3c(c2)sc2ccc(N(c4ccccc4)c4ccccc4)cc23)c2ccc3sc4ccccc4c3c2)cc1 ; c1ccc(N(c2ccccc2)c2cc(-c3cccc(N(c4ccccc4)c4ccc5sc6ccccc6c5c4)c3)cc(N(c3ccccc3)c3ccccc3)c2)cc1]

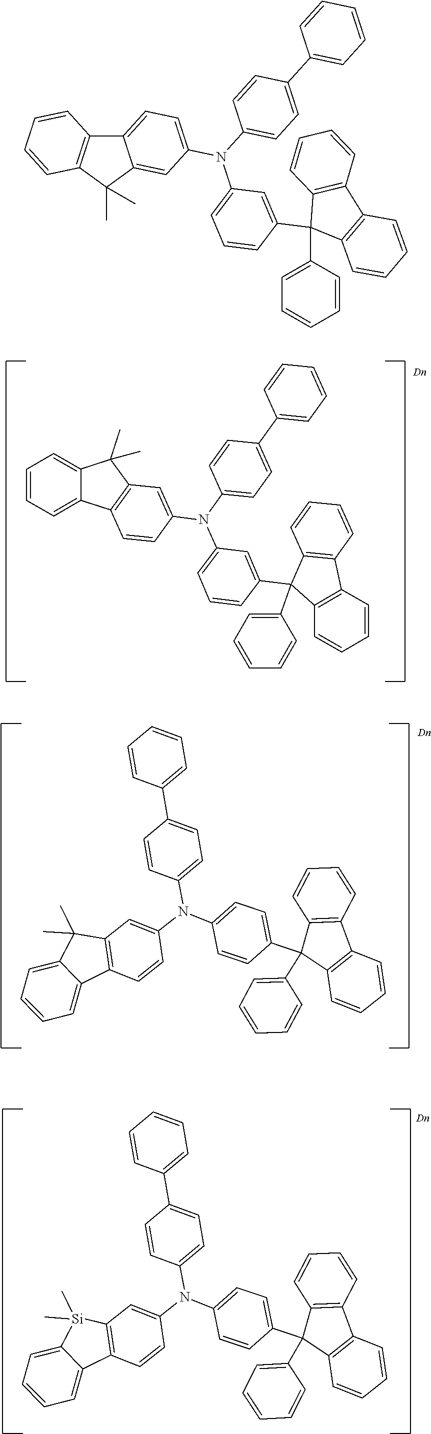

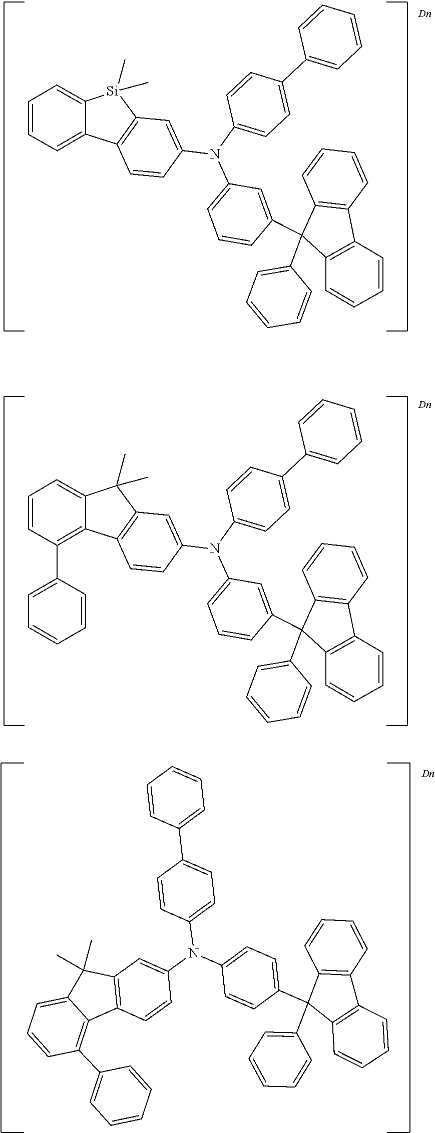

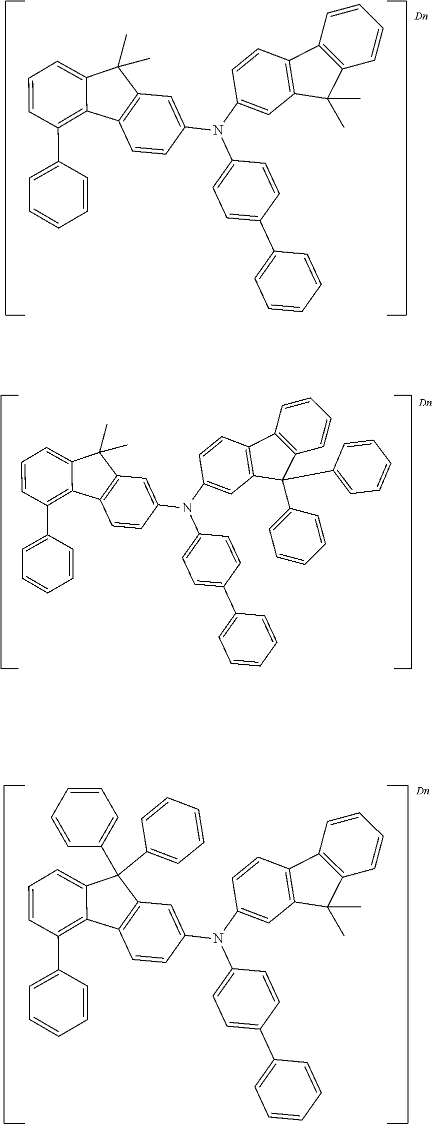

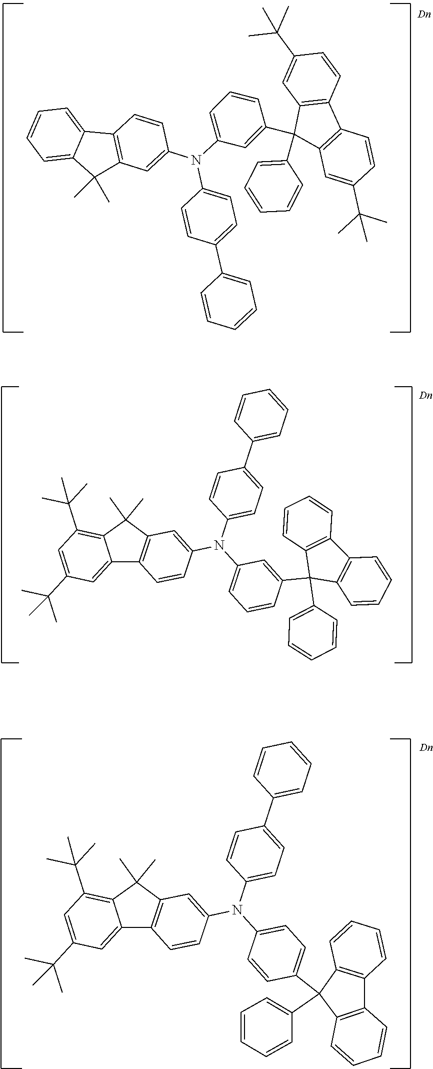

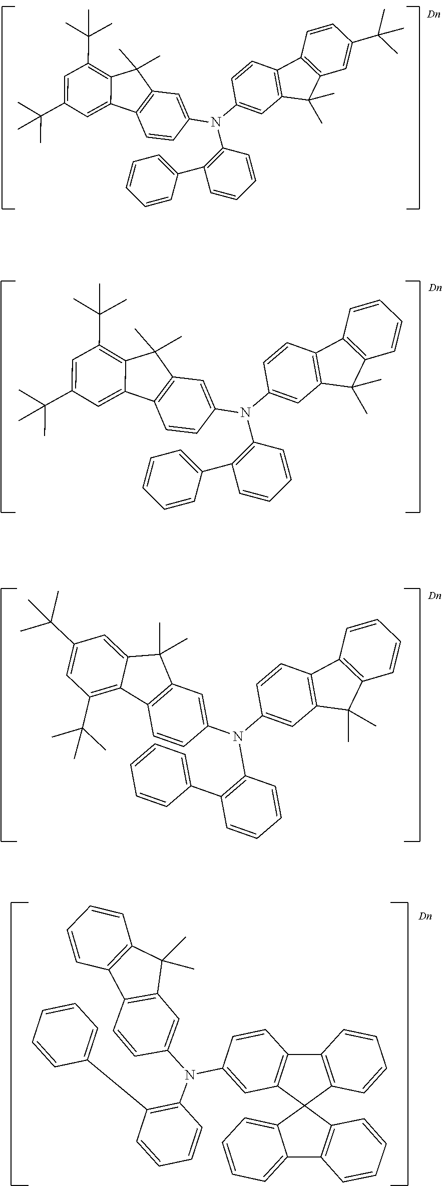

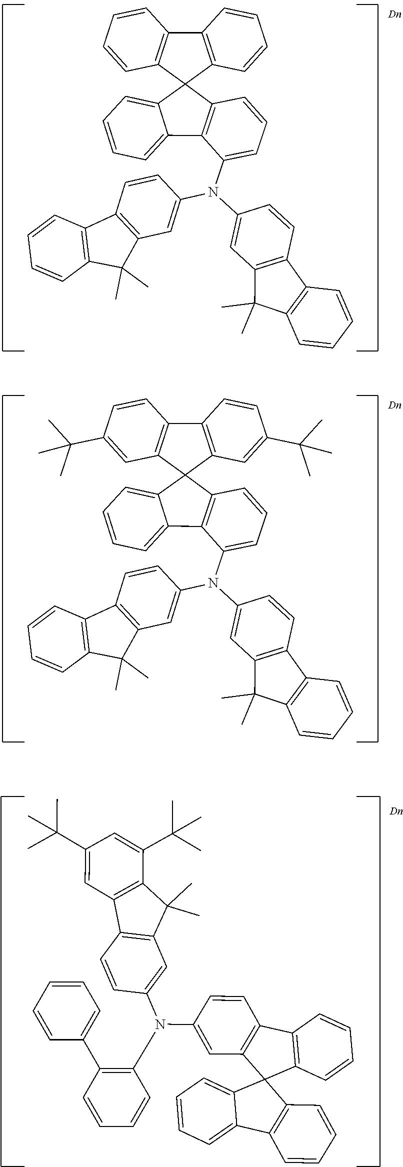

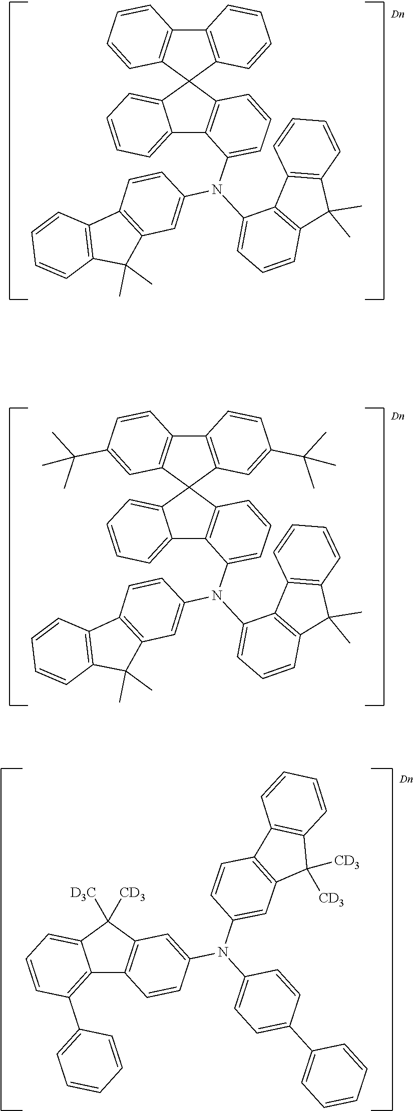

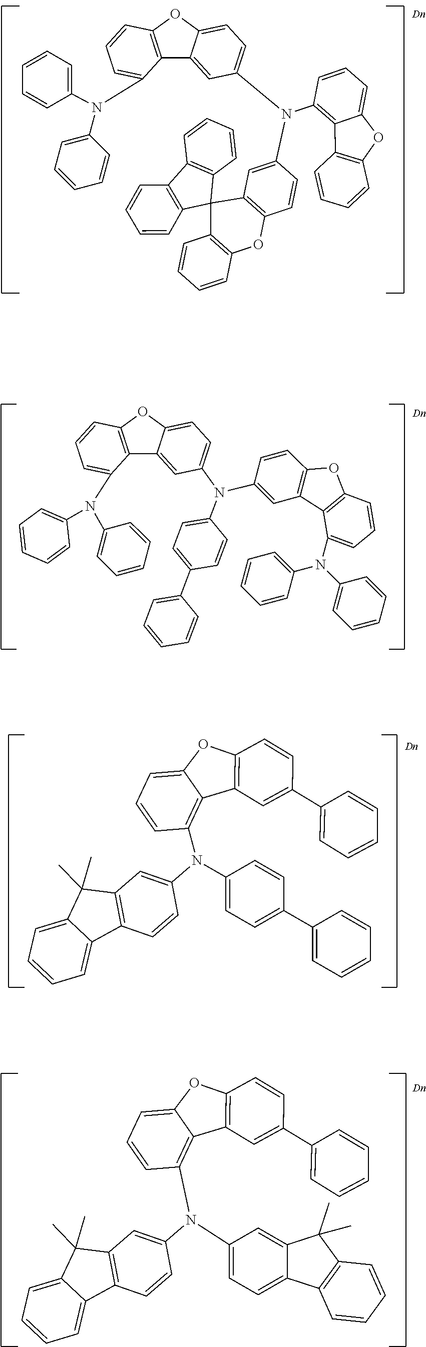

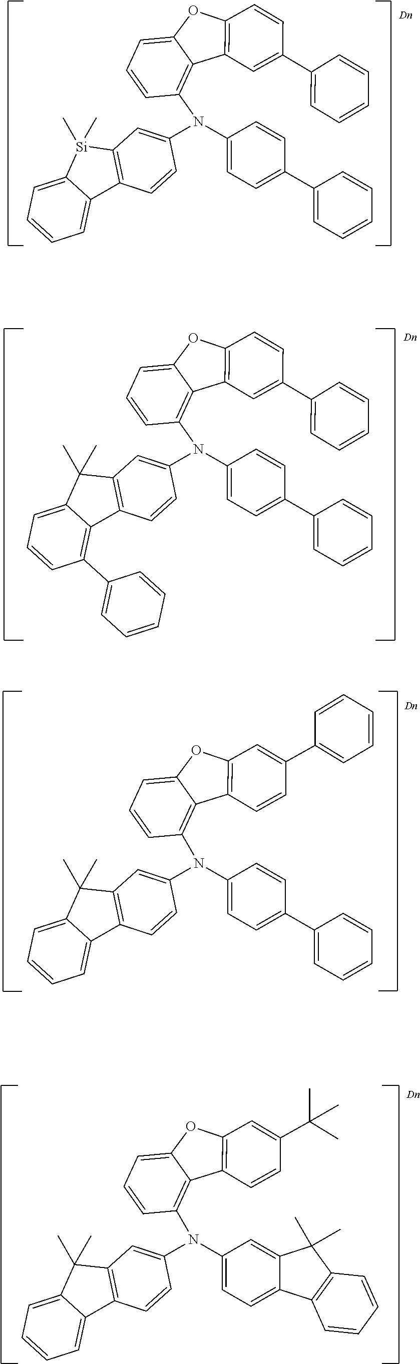

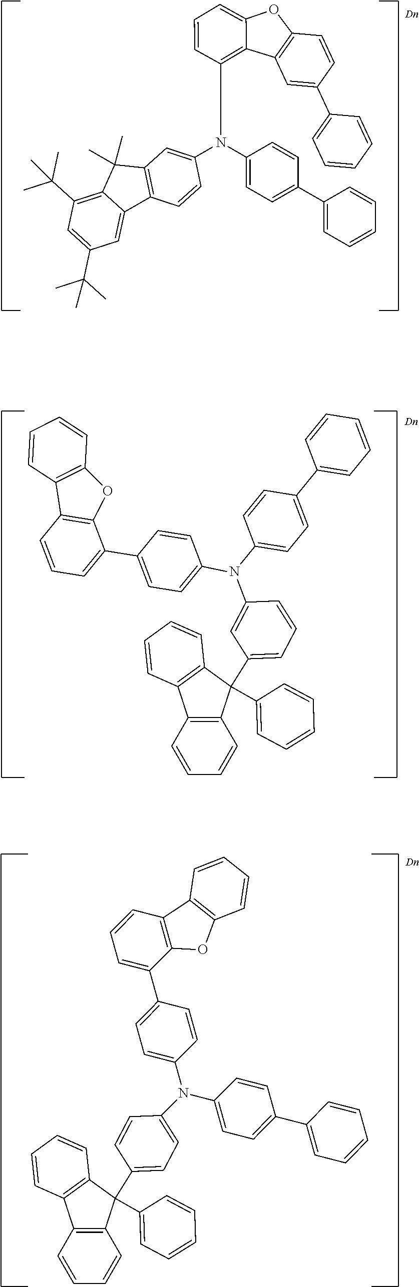

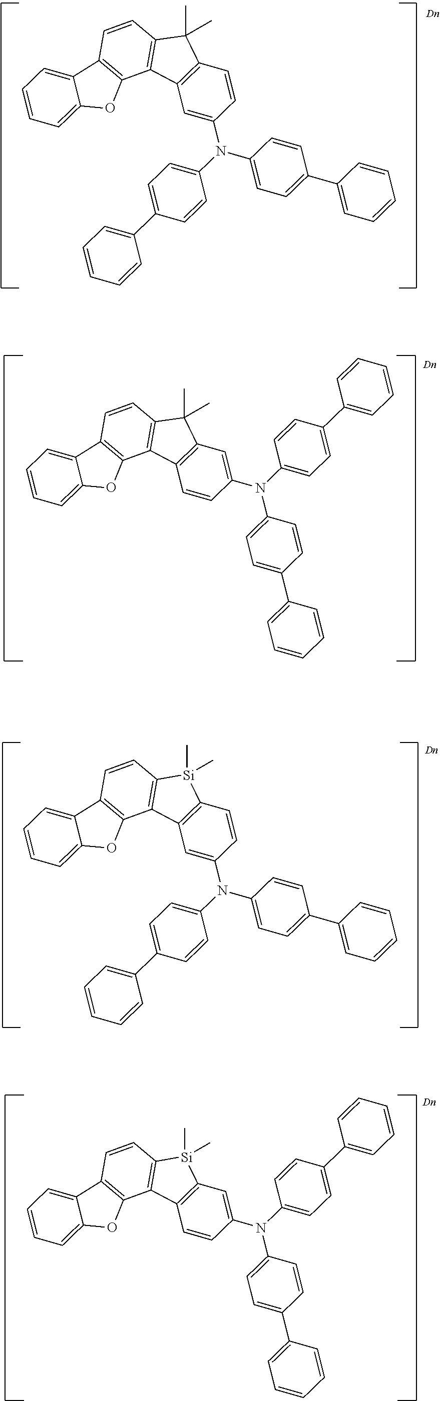

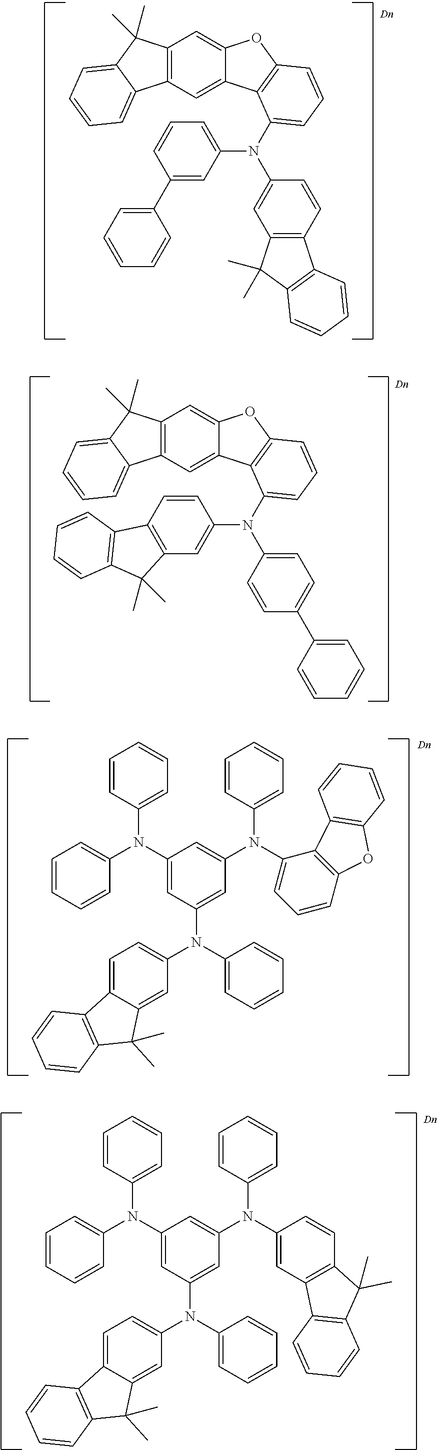

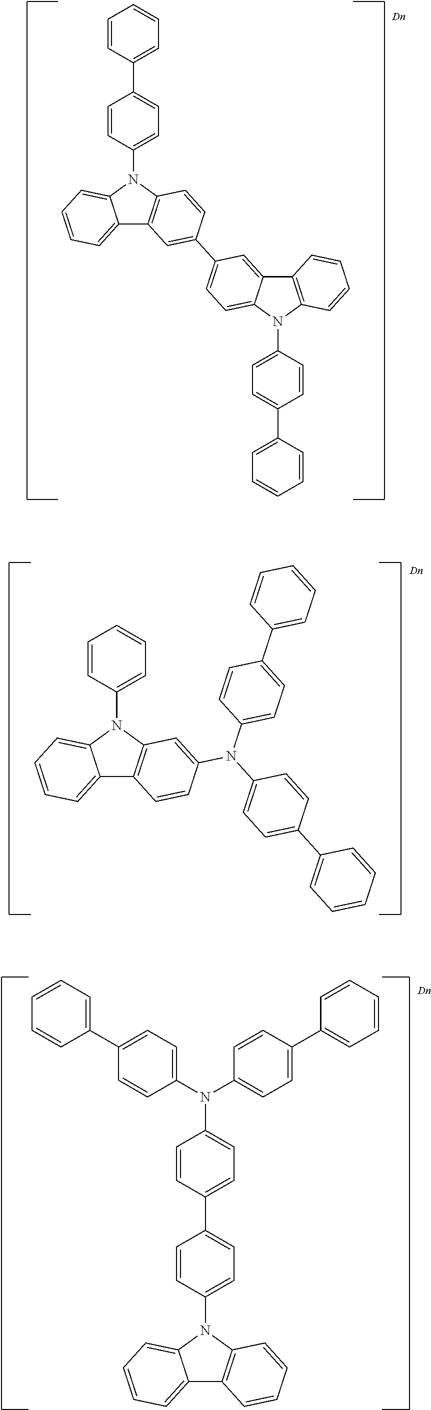

In the hole transport region, in addition to the compounds described above, any suitable known compound or compounds having a similar structure may also be used.

The electron transport region can further increase electron injection and/or electron mobility and block holes between the cathode and the light emitting layer. Specifically, the electron transport region may optionally include the electron injection layer 61 between the cathode and the light emitting layer, the electron transport layer 62 between the light emitting layer and the electron injection layer, and an electron transport auxiliary layer between the light emitting layer and the electron transport layer. At least one of the compounds listed in Group D, below, may be included in at least one layer among the electron injection layer 61, the electron transport layer 62, and the electron transport auxiliary layer.

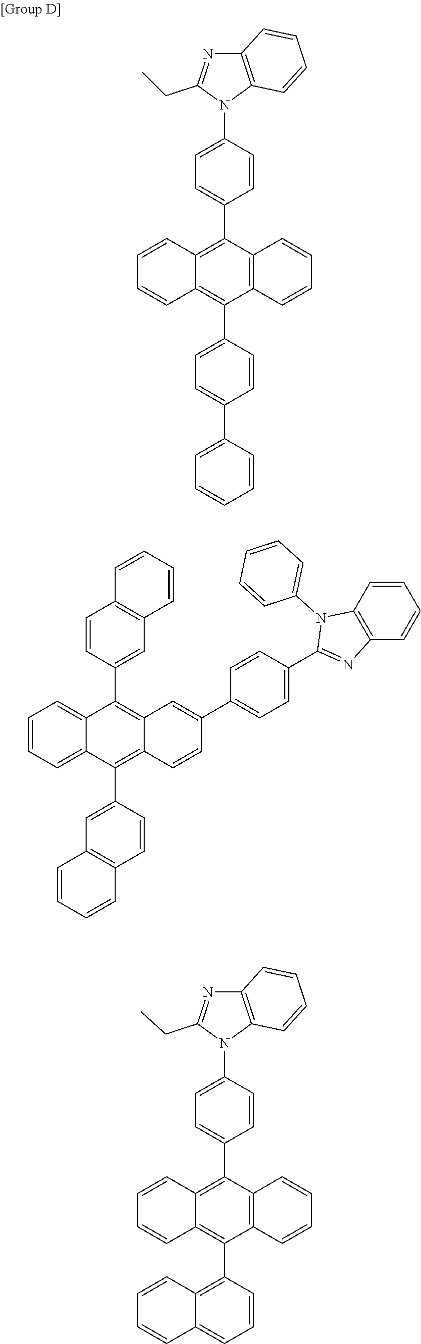

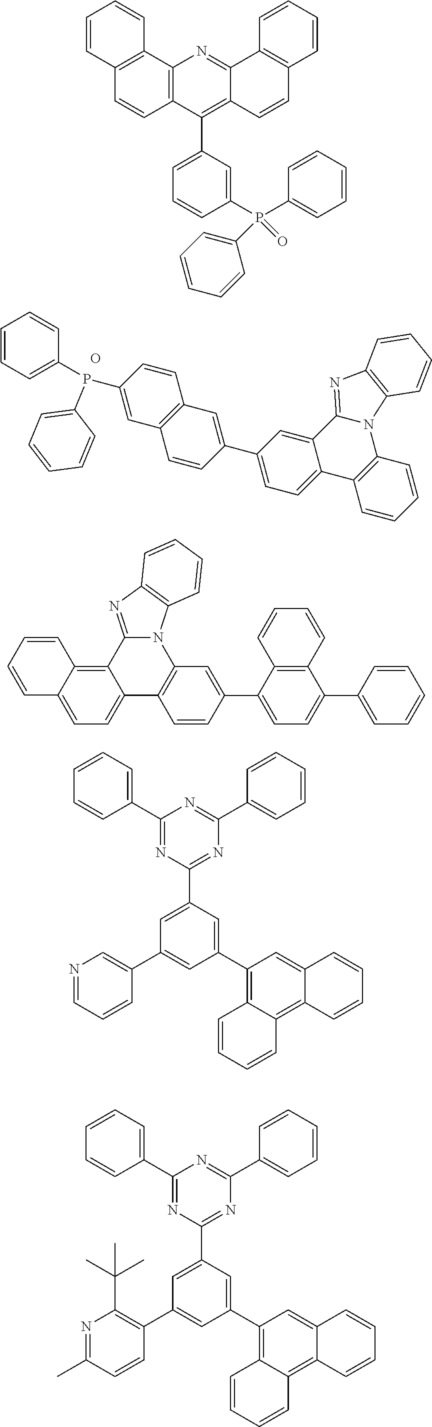

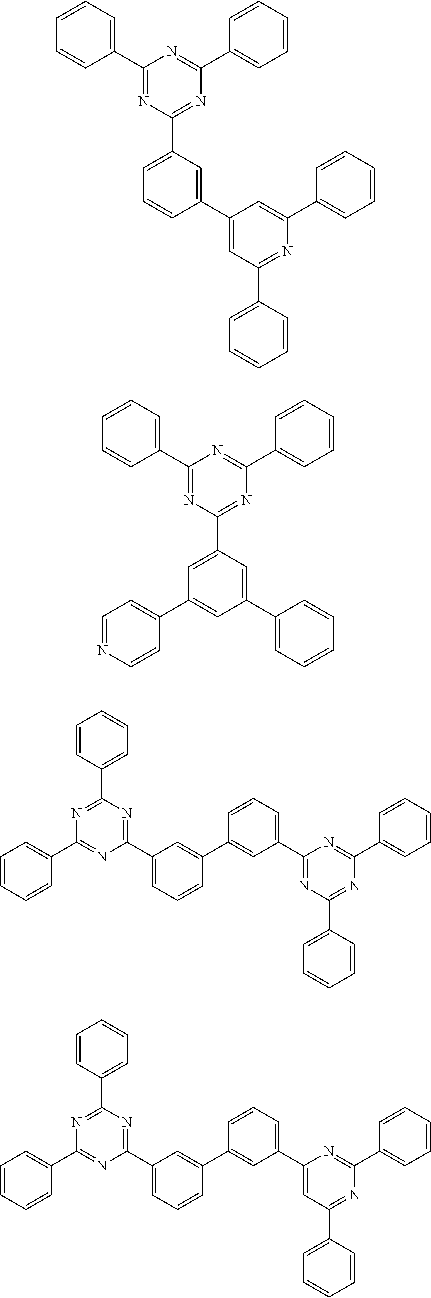 [SMILES: c1ccc(-c2cc(-c3cccc(-c4nc(-c5ccccc5)nc(-c5ccccc5)n4)c3)cc(-c3ccccc3)n2)cc1 ; c1ccc(-c2cc(-c3ccncc3)cc(-c3nc(-c4ccccc4)nc(-c4ccccc4)n3)c2)cc1 ; c1ccc(-c2nc(-c3ccccc3)nc(-c3cccc(-c4cccc(-c5nc(-c6ccccc6)nc(-c6ccccc6)n5)c4)c3)n2)cc1 ; c1ccc(-c2cc(-c3cccc(-c4cccc(-c5nc(-c6ccccc6)nc(-c6ccccc6)n5)c4)c3)nc(-c3ccccc3)n2)cc1]

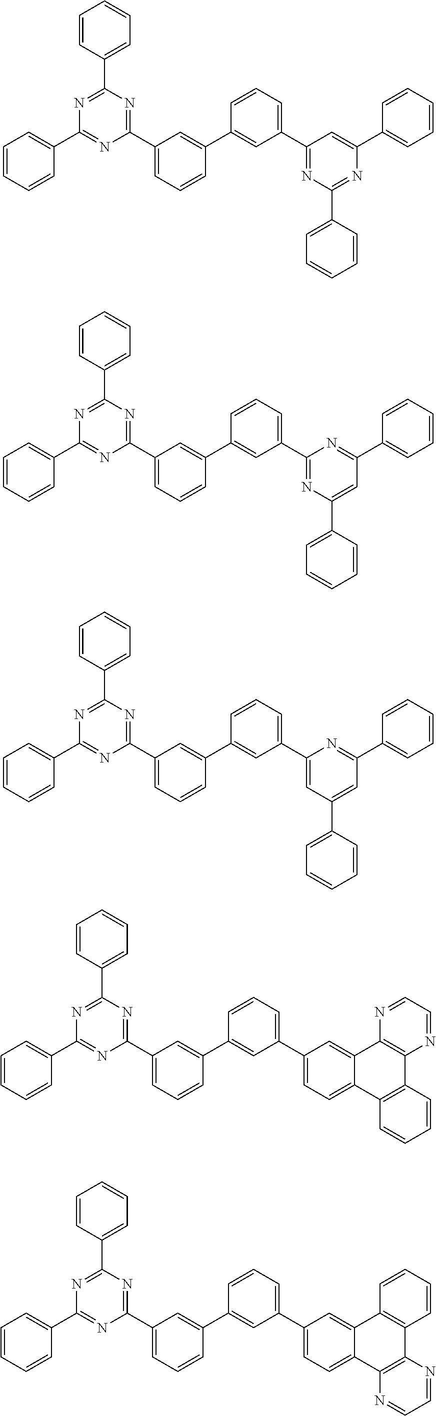 [SMILES: c1ccc(-c2cc(-c3cccc(-c4cccc(-c5nc(-c6ccccc6)nc(-c6ccccc6)n5)c4)c3)nc(-c3ccccc3)n2)cc1 ; c1ccc(-c2cc(-c3ccccc3)nc(-c3cccc(-c4cccc(-c5nc(-c6ccccc6)nc(-c6ccccc6)n5)c4)c3)n2)cc1 ; c1ccc(-c2cc(-c3ccccc3)nc(-c3cccc(-c4cccc(-c5nc(-c6ccccc6)nc(-c6ccccc6)n5)c4)c3)c2)cc1 ; c1ccc(-c2nc(-c3ccccc3)nc(-c3cccc(-c4cccc(-c5ccc6c7ccccc7c7nccnc7c6c5)c4)c3)n2)cc1 ; c1ccc(-c2nc(-c3ccccc3)nc(-c3cccc(-c4cccc(-c5ccc6c(c5)c5ccccc5c5nccnc65)c4)c3)n2)cc1]

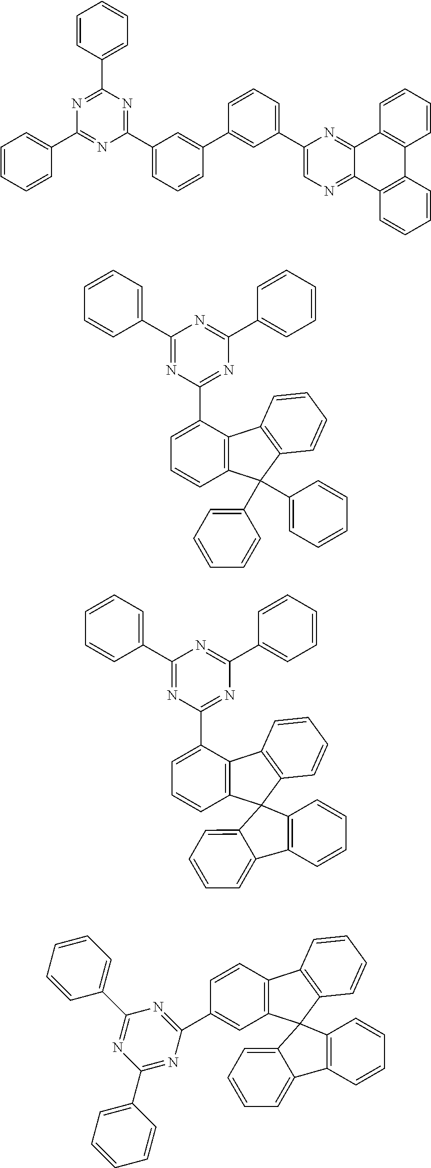 [SMILES: c1ccc(-c2nc(-c3ccccc3)nc(-c3cccc(-c4cccc(-c5cnc6c7ccccc7c7ccccc7c6n5)c4)c3)n2)cc1 ; c1ccc(-c2nc(-c3ccccc3)nc(-c3cccc4c3-c3ccccc3C4(c3ccccc3)c3ccccc3)n2)cc1 ; c1ccc(-c2nc(-c3ccccc3)nc(-c3cccc4c3-c3ccccc3C43c4ccccc4-c4ccccc43)n2)cc1 ; c1ccc(-c2nc(-c3ccccc3)nc(-c3ccc4c(c3)C3(c5ccccc5-c5ccccc53)c3ccccc3-4)n2)cc1]

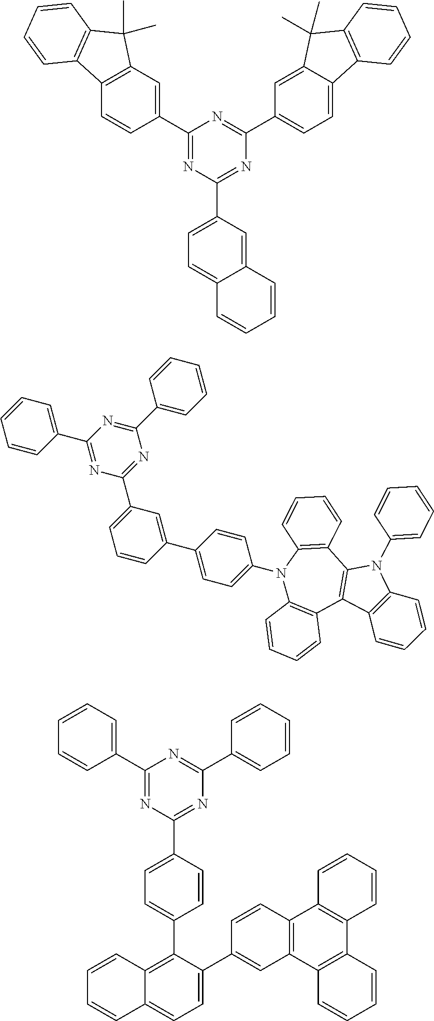 [SMILES: CC1(C)c2ccccc2-c2ccc(-c3nc(-c4ccc5c(c4)C(C)(C)c4ccccc4-5)nc(-c4ccc5ccccc5c4)n3)cc21 ; c1ccc(-c2nc(-c3ccccc3)nc(-c3cccc(-c4ccc(N5c6ccccc6-c6c(n(-c7ccccc7)c7ccccc67)-c6ccccc65)cc4)c3)n2)cc1 ; c1ccc(-c2nc(-c3ccccc3)nc(-c3ccc(-c4c(-c5ccc6c7ccccc7c7ccccc7c6c5)ccc5ccccc45)cc3)n2)cc1]

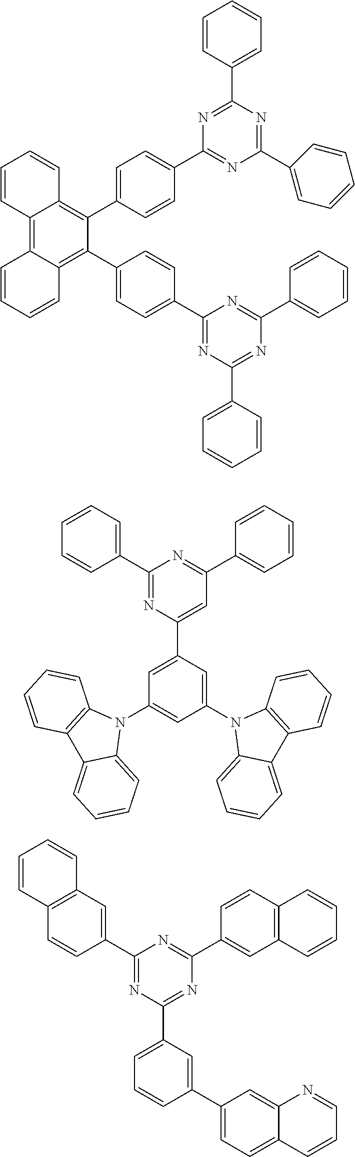

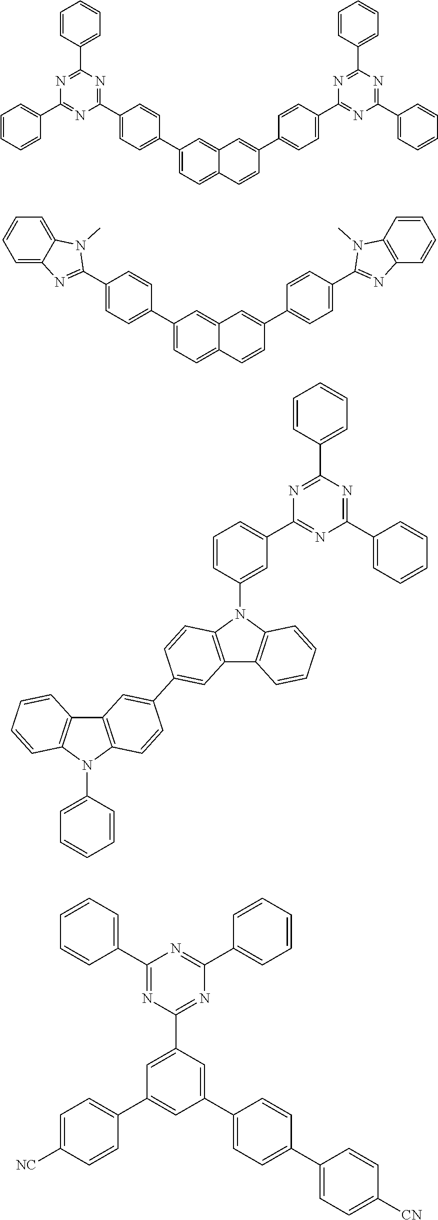 [SMILES: c1ccc(-c2nc(-c3ccccc3)nc(-c3ccc(-c4ccc5ccc(-c6ccc(-c7nc(-c8ccccc8)nc(-c8ccccc8)n7)cc6)cc5c4)cc3)n2)cc1 ; Cn1c(-c2ccc(-c3ccc4ccc(-c5ccc(-c6nc7ccccc7n6C)cc5)cc4c3)cc2)nc2ccccc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; N#Cc1ccc(-c2ccc(-c3cc(-c4ccc(C#N)cc4)cc(-c4nc(-c5ccccc5)nc(-c5ccccc5)n4)c3)cc2)cc1]

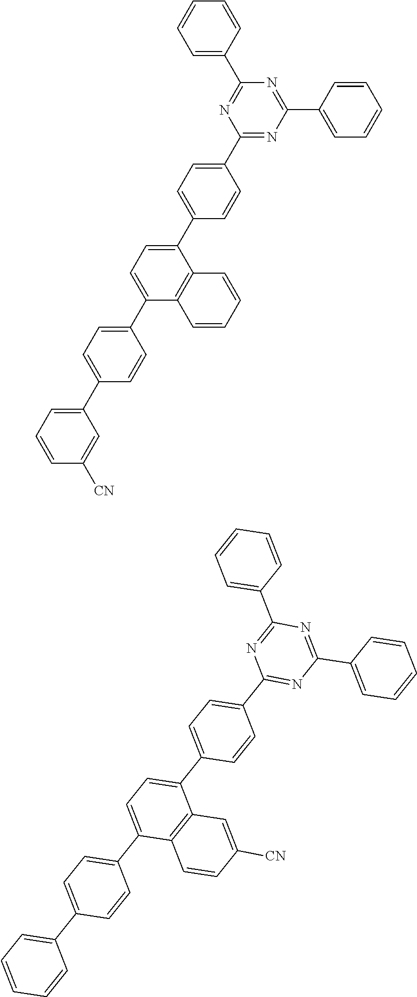 [SMILES: N#Cc1cccc(-c2ccc(-c3ccc(-c4ccc(-c5nc(-c6ccccc6)nc(-c6ccccc6)n5)cc4)c4ccccc34)cc2)c1 ; N#Cc1ccc2c(-c3ccc(-c4ccccc4)cc3)ccc(-c3ccc(-c4nc(-c5ccccc5)nc(-c5ccccc5)n4)cc3)c2c1]

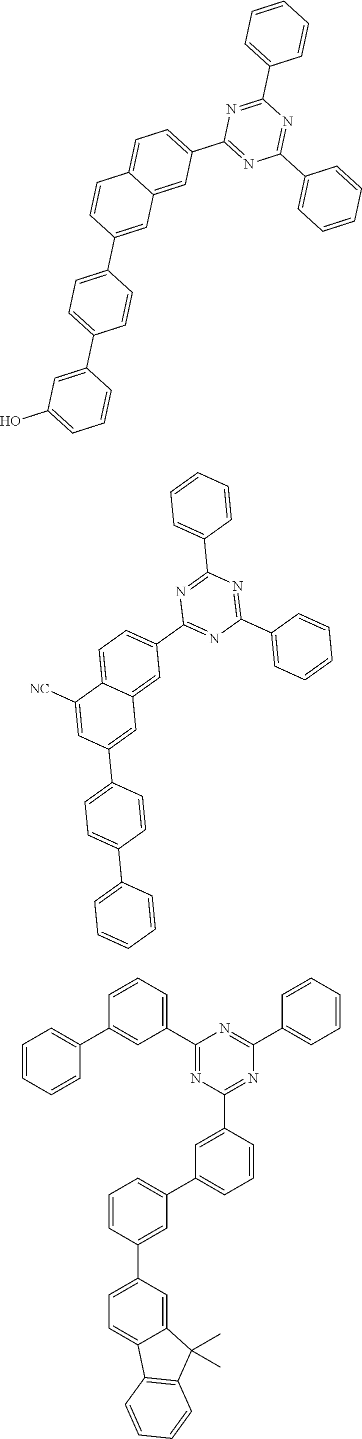

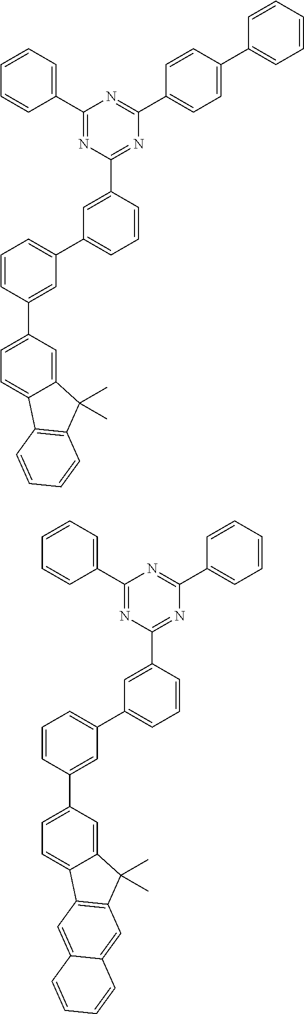

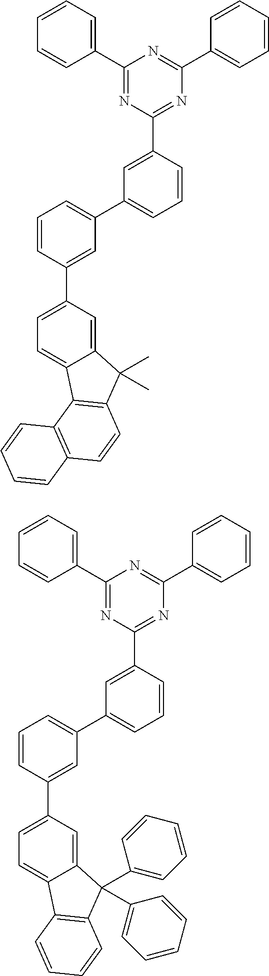

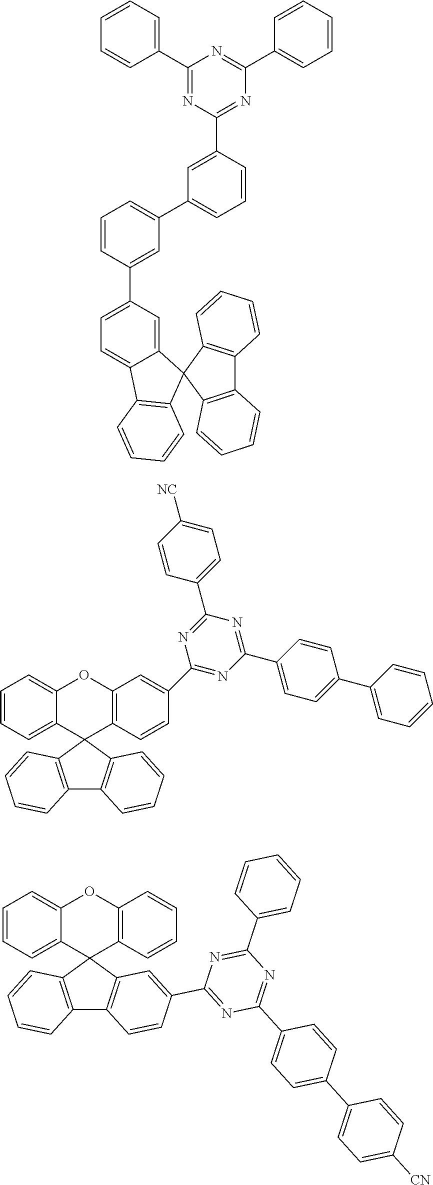

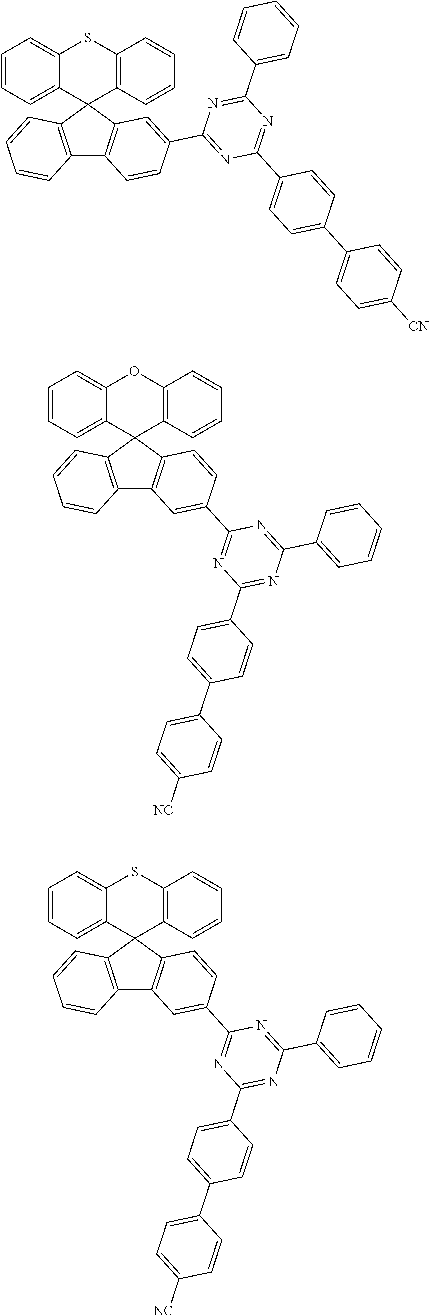 [SMILES: N#Cc1ccc(-c2ccc(-c3nc(-c4ccccc4)nc(-c4ccc5c(c4)C4(c6ccccc6Sc6ccccc64)c4ccccc4-5)n3)cc2)cc1 ; N#Cc1ccc(-c2ccc(-c3nc(-c4ccccc4)nc(-c4ccc5c(c4)-c4ccccc4C54c5ccccc5Oc5ccccc54)n3)cc2)cc1 ; N#Cc1ccc(-c2ccc(-c3nc(-c4ccccc4)nc(-c4ccc5c(c4)-c4ccccc4C54c5ccccc5Sc5ccccc54)n3)cc2)cc1]

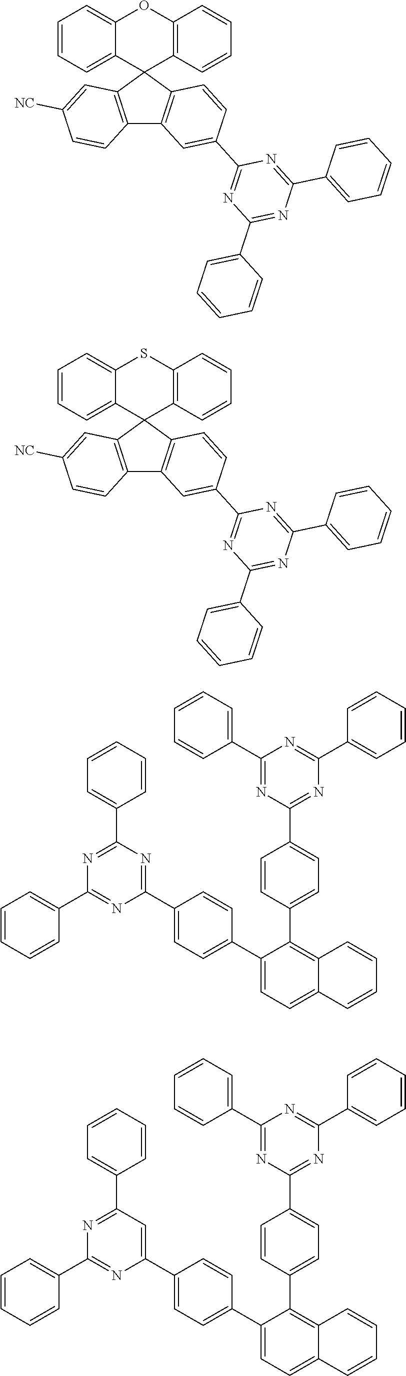

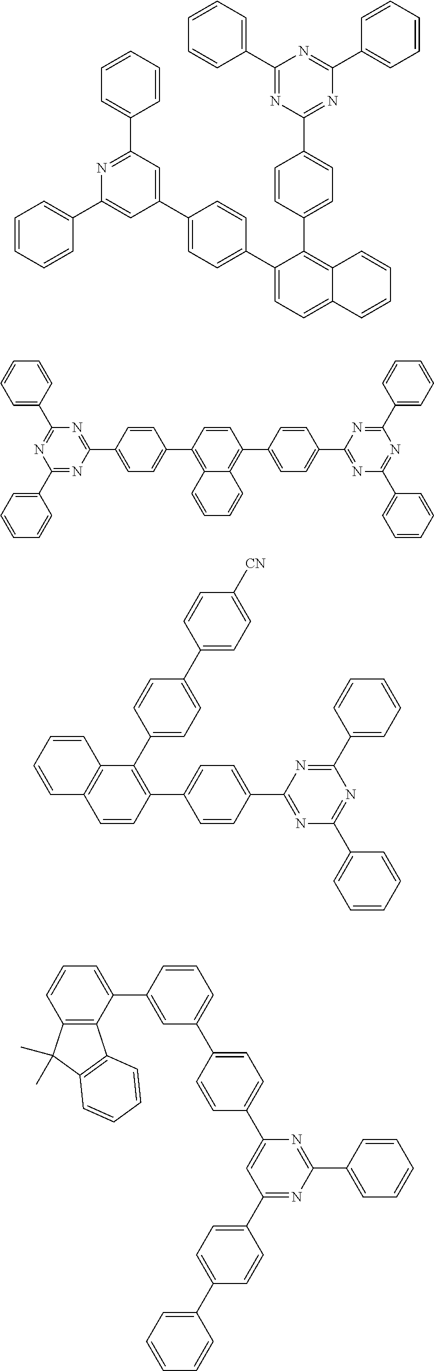 [SMILES: c1ccc(-c2cc(-c3ccc(-c4ccc5ccccc5c4-c4ccc(-c5nc(-c6ccccc6)nc(-c6ccccc6)n5)cc4)cc3)cc(-c3ccccc3)n2)cc1 ; c1ccc(-c2nc(-c3ccccc3)nc(-c3ccc(-c4ccc(-c5ccc(-c6nc(-c7ccccc7)nc(-c7ccccc7)n6)cc5)c5ccccc45)cc3)n2)cc1 ; N#Cc1ccc(-c2ccc(-c3c(-c4ccc(-c5nc(-c6ccccc6)nc(-c6ccccc6)n5)cc4)ccc4ccccc34)cc2)cc1 ; CC1(C)c2ccccc2-c2c(-c3cccc(-c4ccc(-c5cc(-c6ccc(-c7ccccc7)cc6)nc(-c6ccccc6)n5)cc4)c3)cccc21]

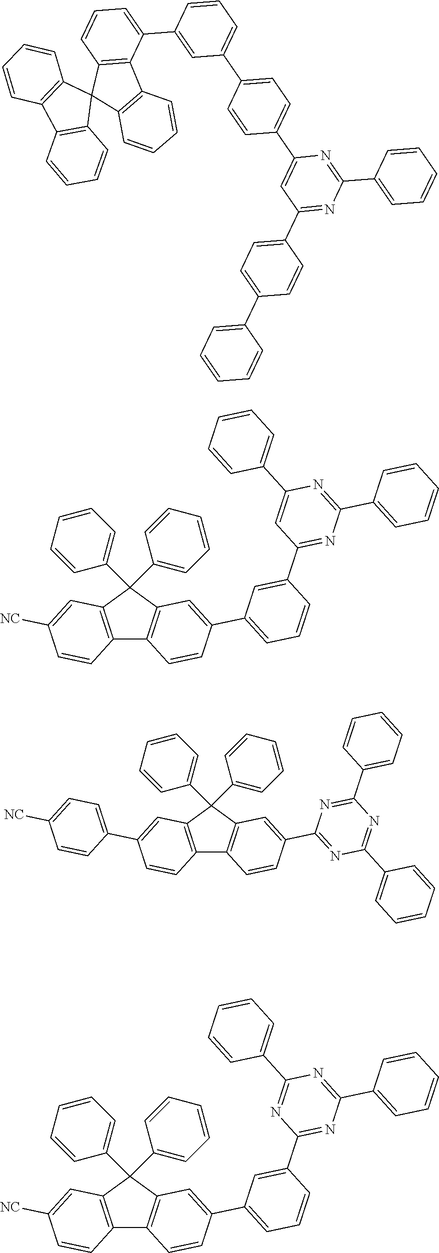

Meanwhile, the organic light emitting diode may further include a capping layer 70 on the anode and/or cathode. The capping layer 70 may be included to increase thermal stability, increase environmental stability, and improve performance of the organic light emitting diode. Examples of materials of the capping layer 70 that can be used to improve the thermal stability of organic light emitting diodes may include SiO, SiO₂, an amine compound, or a mixture thereof.

The organic light emitting diode may be manufactured by forming an anode or cathode on a substrate, then forming a stack using dry film formation methods such as vacuum evaporation, sputtering, plasma plating, and ion plating, and then forming a cathode or anode thereon. The aforementioned organic light emitting diode can be applied to an organic light emitting display device.

Hereinafter, the embodiments are illustrated in more detail with reference to Examples. The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Hereinafter, starting materials and reactants used in the Examples and Synthesis Examples were purchased from Sigma-Aldrich Co. Ltd., TCI Inc., Tokyo chemical industry, or P&H tech as far as there is no particular comment or were synthesized by known methods.

### Preparation of First Compound

### Synthesis Example 1: Synthesis of Compound 1-1

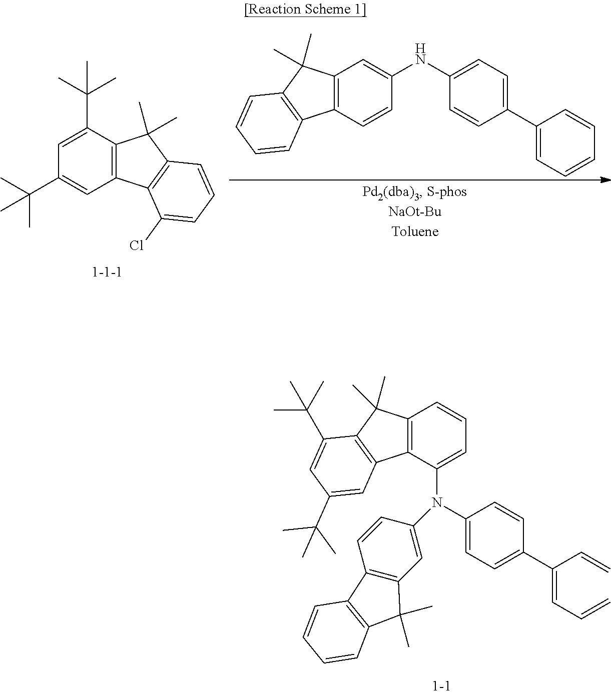 [SMILES: CC(C)(C)c1cc2c(c(C(C)(C)C)c1)C(C)(C)c1cccc(Cl)c1-2 ; CC1(C)c2ccccc2-c2ccc(Nc3ccc(-c4ccccc4)cc3)cc21 ; C=C/C=C(\C=C)c1ccc(N(c2ccc3c(c2)C(C)(C)c2ccccc2-3)c2cccc3c2-c2cc(C(C)(C)C)cc(C(C)(C)C)c2C3(C)C)cc1]

410 g (1.203 mol) of Intermediate 1-1-1 (CAS No. 2924473-03-8), 435 g (1.082 mol) of an amine intermediate (CAS No. 897674-69-1), and 173 g (1.804 mol) of sodium t-butoxide were added to a round-bottomed flask and then dissolved in 4000 ml of toluene. Subsequently, 55 g (0.06 mol) of Pd₂(dba)₃ and 74 g (0.18 mol) of S-phos were sequentially added thereto and then refluxed by stirring under a nitrogen atmosphere for 6 hours. When a reaction was completed, after removing the toluene solvent therefrom, an organic layer was extracted therefrom with toluene and distilled water, dried with magnesium sulfate, and filtered, and a filtrate therefrom was concentrated under a reduced pressure. A product therefrom was recrystallized and purified with n-hexane/methanol, obtaining 600 g (Yield: 71%) of Compound 1-1.

### Synthesis Example 2: Synthesis of Compound 1-5

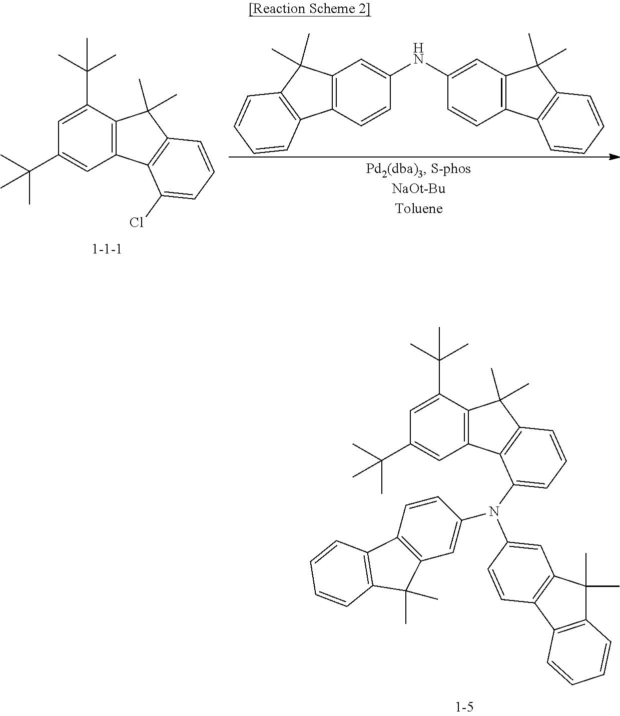

Compound 1-5 was synthesized in the same manner as in Synthesis Example 1, except for using Intermediate 1-1-1 and an amine intermediate (CAS No. 500717-23-7).

### Synthesis Example 3: Synthesis of Compound 2-9

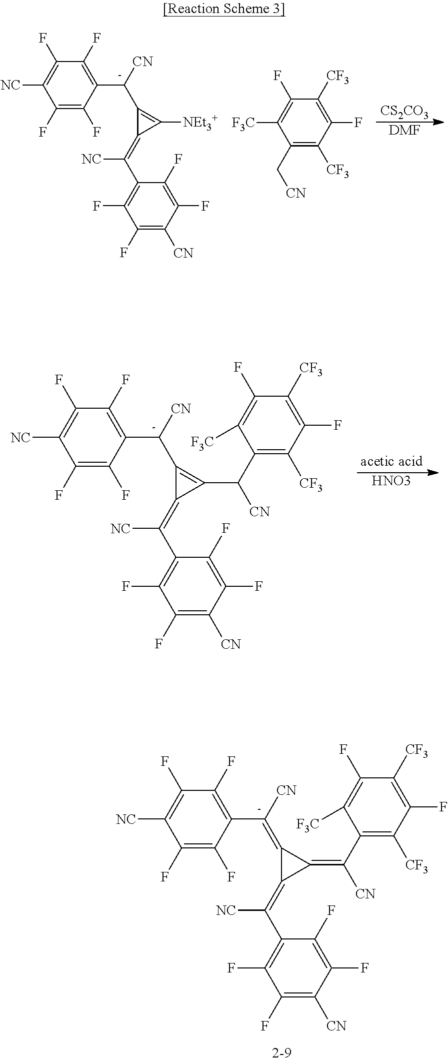

Compound 2-9 was synthesized by referring to the synthesis method known in EP 3034489 A1 published patent.

### (Manufacturing of Organic Light Emitting Diode)

### Example 1

A light emitting diode with a Tandem structure was fabricated in which a first stack (host (BH1-1): dopant (BD1-32)=95:5 wt %) including a first light emitting layer emitting light in a wavelength range of greater than or equal to about 420 nm and less than or equal to about 480 nm, a second stack, and a third stack were stacked, and on the third stack, a fourth stack including a second light emitting layer emitting light in a wavelength range of greater than or equal to about 520 nm and less than or equal to about 600 nm was stacked. Subsequently, 2,2′-(1,3-phenylene)bis[9-phenyl-1,10-phenanthroline]doped with Yb was used to form an n-type charge generation layer between first stack-second stack, second stack-third stack, and third stack-fourth stack, and in addition, ITO/Ag/ITO was used as an anode, Compound A doped with Compound 2-1 was used to form a hole injection layer on the first stack and intermediate hole injection layers on the second and third stacks, Compound A was used to form a hole transport layer on the first stack and intermediate hole transport layers on the second and third stacks, and Compound B was used to form intermediate electron transport layers on the first to third stacks.

On the third stack, an n-type charge generation layer was formed in the above method, on the n-type charge generation layer, Compound 1-1 doped with 7 wt % of Compound 2-9 was vacuum-deposited to form a 100 Å-thick p-type charge generation layer, on the p-type charge generation layer, and Compound D was deposited to form a 250 Å-thick first hole transport layer. On the first hole transport layer, Compound E was deposited to form a 50 Å-thick second hole transport layer, on the second hole transport layer, (host (GH1:GH2=40 wt %: 60 wt %):dopant (IrGD)=95 wt %: 5 wt %) were vacuum-deposited to form a 200 Å-thick second light emitting layer. Subsequently, on the second light emitting layer, Compound F was deposited to form a 420 Å-thick electron transport auxiliary layer, and Compound F and Liq in a weight ratio of 1:1 were simultaneously vacuum-deposited to form a 100 Å-thick electron transport layer. On the electron transport layer, Yb was deposited to form a 10 Å-thick electron injection layer (EIL), Mg and Ag in a weight ratio of 1:9 were simultaneously vacuum-deposited to form a 100 Å-thick cathode, and on the cathode, Compound G was deposited to form a 500 Å-thick capping layer.

The light emitting diode had a structure that ITO/Ag/ITO/first stack (blue light emitting)/second stack (blue light emitting)/third stack (blue light emitting)/Compound 1-1: Compound 2-9 (7% doping, 100 Å)/Compound D (250 Å)/Compound E (50 Å)/second light emitting layer [host (GH1:GH2=40:60):IrGD=95 wt %: 5 wt %)](200 Å) Compound F (420 Å)/Compound F: Liq=1:1 (50% doping, 100 Å)/Yb 10 Å/Mg:Ag=1:9 (100 Å)/Compound G (500 Å).
Compound A: N-(9,9-dimethyl-9H-fluoren-2-yl)-N-(2-phenylphenyl)-9,9′-spirobi[fluorene]-2-amine
Compound B: 2-{3-[3-(9,9-dimethyl-9H-fluoren-2-yl)phenyl]phenyl}-4,6-diphenyl-1,3,5-triazine
Compound D: N-[2-(adamantan-1-yl)phenyl]-N-(4-cyclohexylphenyl)-9,9-dimethyl-9H-fluoren-2-amine
Compound E: 9,9-dimethyl-N-[3-(9-phenyl-9H-fluoren-9-yl)phenyl]-N-(4-phenylphenyl)-9H-fluoren-2-amine
Compound F: 2-(4-{2-[4-(diphenyl-1,3,5-triazin-2-yl)phenyl]naphthalene-1-yl}phenyl)-4,6-diphenyl-1,3,5-triazine
Compound G: N,9-diphenyl-N-(4-{4-[phenyl (9-phenyl-9H-carbazol-3-yl)amino]phenyl}phenyl)-9H-carbazol-3-amine

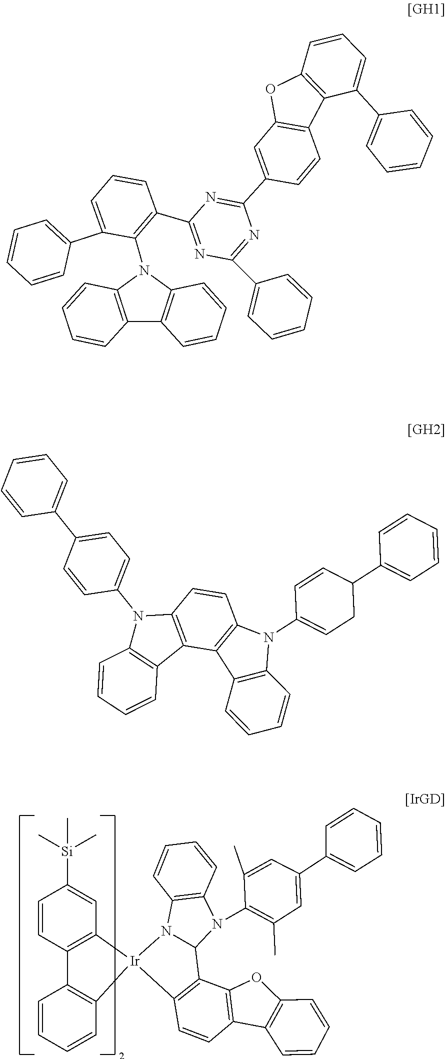

### Example 2

An organic light emitting diode was manufactured in the same manner as in Example 1, except for using Compound 1-5 instead of the first compound 1-1 of the charge generation layer.

### Comparative Example 1

An organic light emitting diode was manufactured in the same manner as in Example 1 except for using Compound E instead of the first compound 1-1 of the charge generation layer.

### Evaluation

Specific measurement methods are as follows, and the results are shown in Table 1.

### (1) Measurement of Current Density Change Depending on Voltage Change

The obtained organic light emitting diodes were measured regarding a current value flowing in the unit device, while increasing the voltage from 0 V to 10 V using a current-voltage meter (Keithley 2400), and the measured current value was divided by area to provide the results.

### (2) Measurement of Luminance Change Depending on Voltage Change

Luminance was measured by using a luminance meter (Minolta Cs-1000A), while the voltage of the organic light emitting diodes was increased from 0 V to 10 V.

### (3) Measurement of Luminous Efficiency

Luminous efficiency (cd/A) at the same current density (10 mA/cm²) were calculated by using the luminance and current density from (1) and (2) above.

### (4) Measurement of Life-span

Time when current efficiency of the manufactured organic light emitting diode was reduced to 97%, while maintaining luminance (cd/m²) at 24000 cd/m², was measured as a life-span.

The life-span values measured for Examples 1 and 2 were calculated as relative values based on the life-span values measured for Comparative Example 1 and are listed in Table 1.

### (5) Measurement of Driving Voltage

The results were obtained by measuring the driving voltage of each diode at 15 mA/cm² using a current-voltage meter (Keithley 2400).

The driving voltages measured for Examples 1 and 2 were calculated as relative values based on the driving voltages measured for Comparative Example 1 and are shown in Table 1.

TABLE 1

| | | | | | Life- |
|---|---|---|---|---|---|
| | p-type charge generation layer | | | Driving | span |
| | First | Second | Weight | Voltage | ratio |
| No. | compound | compound | ratio | ratio %) | (%) |
| Example 1 | 1-1 | 2-9 | 94:6 | 99 | 140 |
| Example 2 | 1-5 | 2-9 | 94:6 | 99 | 146 |
| Comparative | Compound E | 2-9 | 94:6 | 100 | 100 |
| Example 1 | | | | | |

Referring to Table 1, life-spans of the organic light emitting diodes according to Examples 1 and 2 are significantly improved compared to the organic light emitting diodes according to Comparative Example 1.

By way of summation and review, embodiments provide a low driving voltage and long life-span organic optoelectronic device. Embodiments also provide a display device including the organic optoelectronic device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. An organic optoelectronic device, comprising
an anode and a cathode facing each other;
at least one first light emitting layer between the anode and the cathode, the at least one first light emitting layer being configured to emit light of a first wavelength;
at least one second light emitting layer between the anode and the cathode, the at least one second light emitting layer being configured to emit light of a second wavelength different from the first wavelength; and
at least one charge generation layer between the first light emitting layer and the second light emitting layer, the charge generation layer including a first compound represented by Chemical Formula 1 and a second compound represented by Chemical Formula 2: 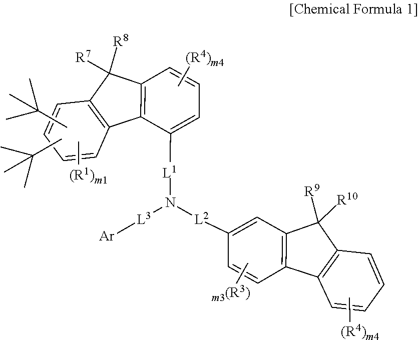
wherein, in Chemical Formula 1,
L¹ to L³ are each independently a single bond, a substituted or unsubstituted C6 to C20 arylene group, or a substituted or unsubstituted C2 to C30 heterocyclic group,
Ar¹ is a substituted or unsubstituted C6 to C20 aryl group or a substituted or unsubstituted C2 to C30 heterocyclic group,
R¹ to R⁴ are each independently hydrogen, deuterium, a cyano group, a substituted or unsubstituted C1 to C30 alkyl group, a substituted or unsubstituted C6 to C30 aryl group, or a substituted or unsubstituted C2 to C30 heterocyclic group,
R⁷ to R¹⁰ are each independently a substituted or unsubstituted C1 to C30 alkyl group, or a substituted or unsubstituted C6 to C30 aryl group,
m1 is an integer of 1 or 2,
m2 and m3 are each independently one of integers of 1 to 3,
m4 is one of integers of 1 to 4,
when m1 is 2 or more, each R¹ is the same or different from each other,
when m2 is 2 or more, each R² is the same or different from each other,
when m3 is 2 or more, each R³ is the same or different from each other, and
when m4 is 2 or more, each R⁴ is the same or different from each other, 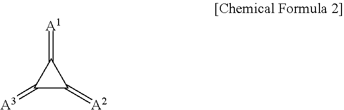
wherein, in Chemical Formula 2,
A¹ is represented by Chemical Formula 2a, 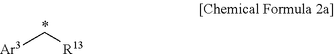
A² is represented by Chemical Formula 2b, 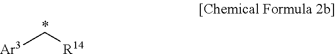
A³ is represented by Chemical Formula 2c, 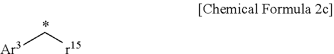
wherein, in Chemical Formula 2a, Chemical Formula 2b, and Chemical Formula 2c,
Ar² to Ar⁴ are each independently a substituted or unsubstituted C6 to C20 aryl group or a substituted or unsubstituted C2 to C30 heterocyclic group,
R¹³ to R¹⁵ are each independently hydrogen, deuterium, halogen, a cyano group, a nitro group, a substituted or unsubstituted C1 to C30 alkyl group, a substituted or unsubstituted C1 to C30 alkoxy group, a substituted or unsubstituted C6 to C20 aryl group, or a substituted or unsubstituted C2 to C30 heterocyclic group, and
* is a linking point with a double bond.

2. The organic optoelectronic device as claimed in claim 1, wherein Ar¹ is a substituted or unsubstituted phenyl group, a substituted or unsubstituted biphenyl group, a substituted or unsubstituted terphenyl group, a substituted or unsubstituted fluorenyl group, a substituted or unsubstituted dibenzofuranyl group, or a substituted or unsubstituted dibenzothiophenyl group.

3. The organic optoelectronic device as claimed in claim 1, wherein L³-Ar¹ is selected from substituents listed in Group I: 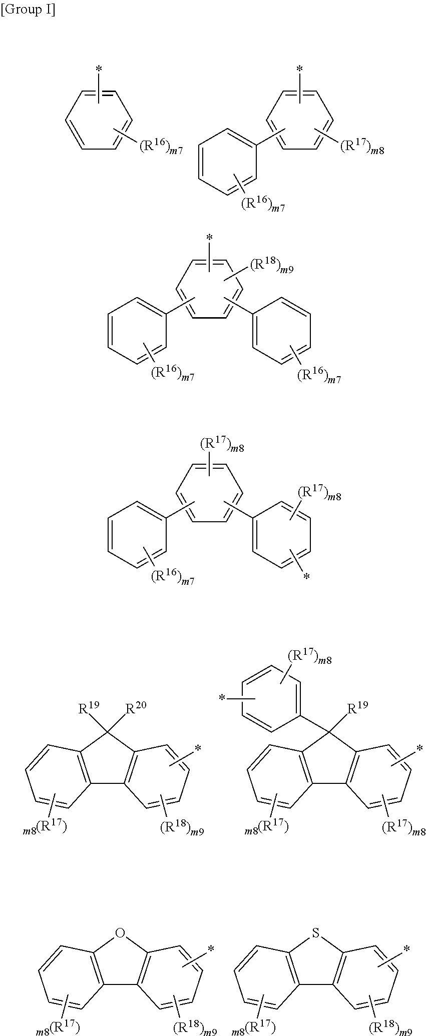
wherein, in Group I,
R¹⁶ to R¹⁸ are each independently hydrogen, deuterium, a cyano group, a substituted or unsubstituted C1 to C10 alkyl group, or a substituted or unsubstituted C6 to C12 aryl group,
R¹⁹ and R²⁰ are each independently a substituted or unsubstituted C1 to C10 alkyl group or a substituted or unsubstituted C6 to C12 aryl group,
m7 is one of integers of 1 to 5,
m8 is one of integers of 1 to 4,
m9 is one of integers of 1 to 3, and
* is a linking point.

4. The organic optoelectronic device as claimed in claim 1, wherein the first compound is represented by Chemical Formula 1A: 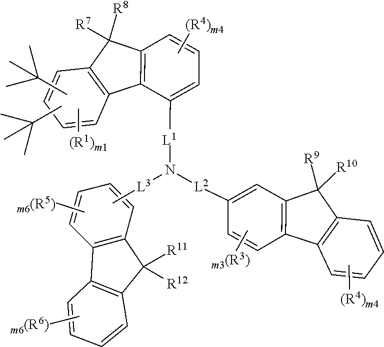
wherein, in Chemical Formula 1A,
L¹ to L³ are each independently a single bond, a substituted or unsubstituted C6 to C20 arylene group, or a substituted or unsubstituted C2 to C30 heterocyclic group,
R¹ to R⁶ are each independently hydrogen, deuterium, a cyano group, a substituted or unsubstituted C1 to C30 alkyl group, a substituted or unsubstituted C6 to C30 aryl group, or a substituted or unsubstituted C2 to C30 heterocyclic group,
R⁷ to R¹² are each independently a substituted or unsubstituted C1 to C30 alkyl group, or a substituted or unsubstituted C6 to C30 aryl group,
m1 is an integer of 1 or 2,
m2, m3, and m5 are each independently one of integers of 1 to 3,
m4 and m6 are each independently one of integers of 1 to 4,
when m1 is 2 or more, each R¹ is the same or different from each other,
when m2 is 2 or more, each R² is the same or different from each other,
when m3 is 2 or more, each R³ is the same or different from each other,
when m4 is 2 or more, each R⁴ is the same or different from each other,
when m5 is 2 or more, each R⁵ is the same or different from each other, and
when m6 is 2 or more, each R⁶ is the same or different from each other.

5. The organic optoelectronic device as claimed in claim 4, wherein:
Chemical Formula 1A is represented by any one of Chemical Formula 1A-1 to Chemical 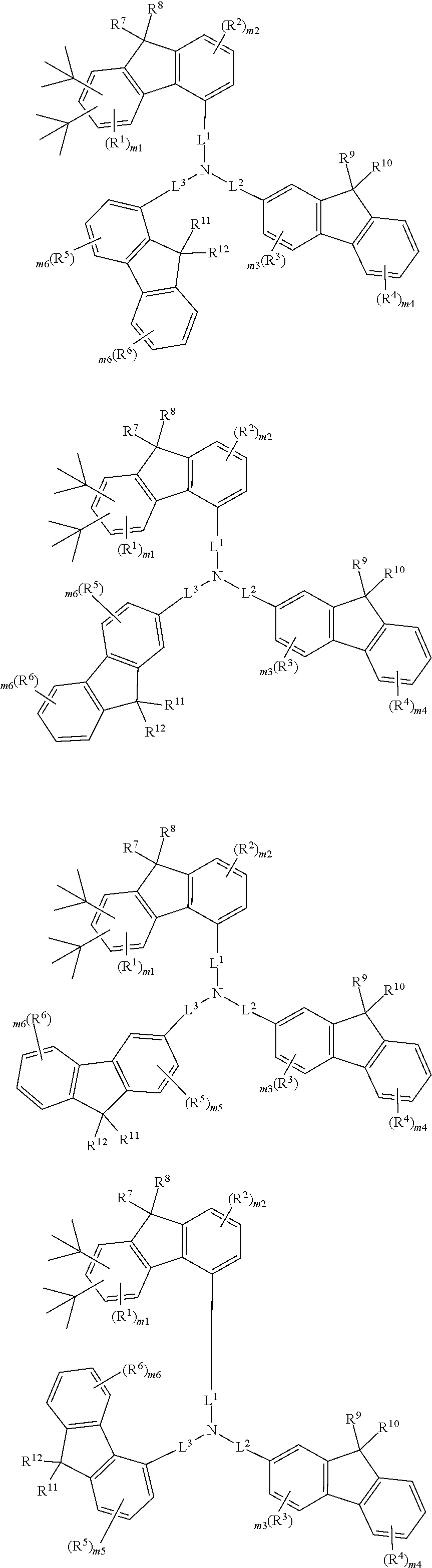
and
in Chemical Formula 1A-1 to Chemical Formula 1-4, L¹ to L³, R¹ to R¹², and m1 to m6 are the same as defined in claim 4.

6. The organic optoelectronic device as claimed in claim 1, wherein the first compound is selected from compounds listed in Group 1:

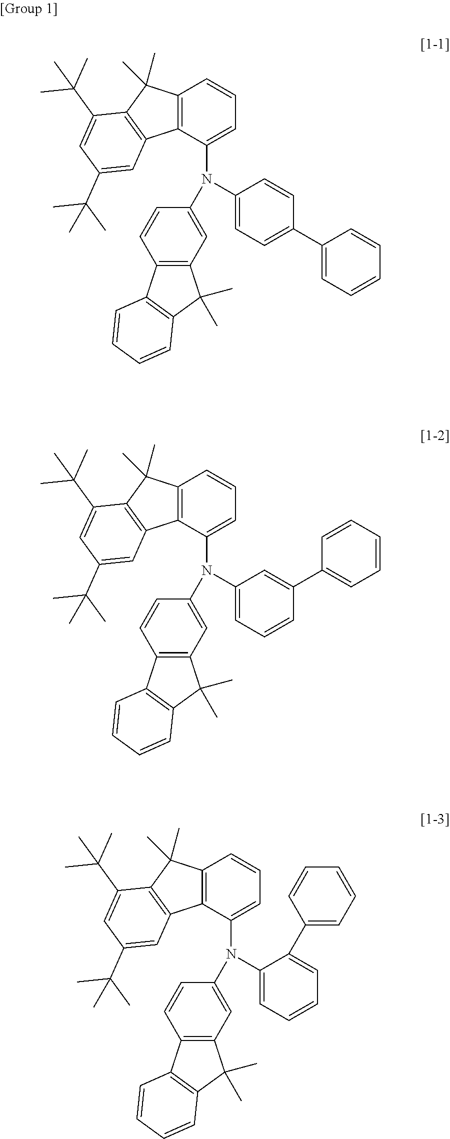 [SMILES: CC(C)(C)c1cc2c(c(C(C)(C)C)c1)C(C)(C)c1cccc(N(c3ccc(-c4ccccc4)cc3)c3ccc4c(c3)C(C)(C)c3ccccc3-4)c1-2 ; CC(C)(C)c1cc2c(c(C(C)(C)C)c1)C(C)(C)c1cccc(N(c3cccc(-c4ccccc4)c3)c3ccc4c(c3)C(C)(C)c3ccccc3-4)c1-2 ; CC(C)(C)c1cc2c(c(C(C)(C)C)c1)C(C)(C)c1cccc(N(c3ccc4c(c3)C(C)(C)c3ccccc3-4)c3ccccc3-c3ccccc3)c1-2]

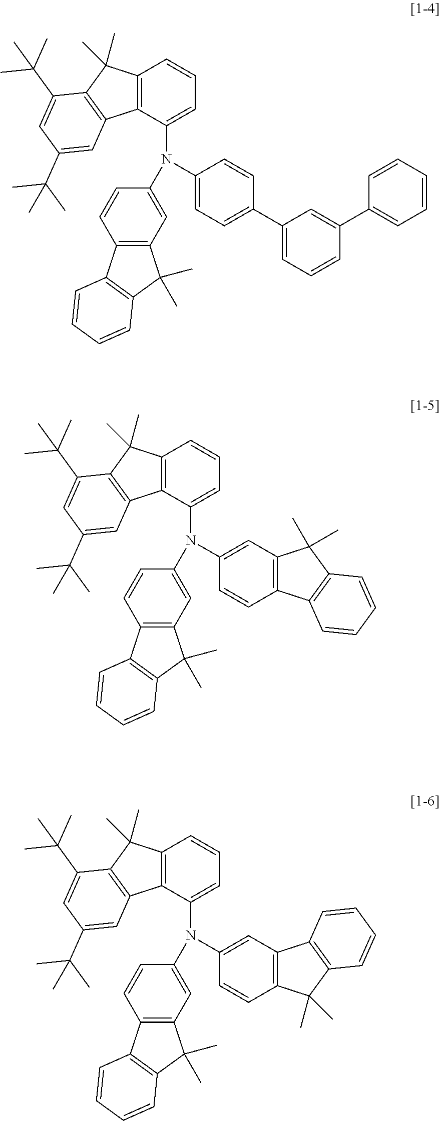 [SMILES: CC(C)(C)c1cc2c(c(C(C)(C)C)c1)C(C)(C)c1cccc(N(c3ccc(-c4cccc(-c5ccccc5)c4)cc3)c3ccc4c(c3)C(C)(C)c3ccccc3-4)c1-2 ; CC(C)(C)c1cc2c(c(C(C)(C)C)c1)C(C)(C)c1cccc(N(c3ccc4c(c3)C(C)(C)c3ccccc3-4)c3ccc4c(c3)C(C)(C)c3ccccc3-4)c1-2 ; CC(C)(C)c1cc2c(c(C(C)(C)C)c1)C(C)(C)c1cccc(N(c3ccc4c(c3)-c3ccccc3C4(C)C)c3ccc4c(c3)C(C)(C)c3ccccc3-4)c1-2]

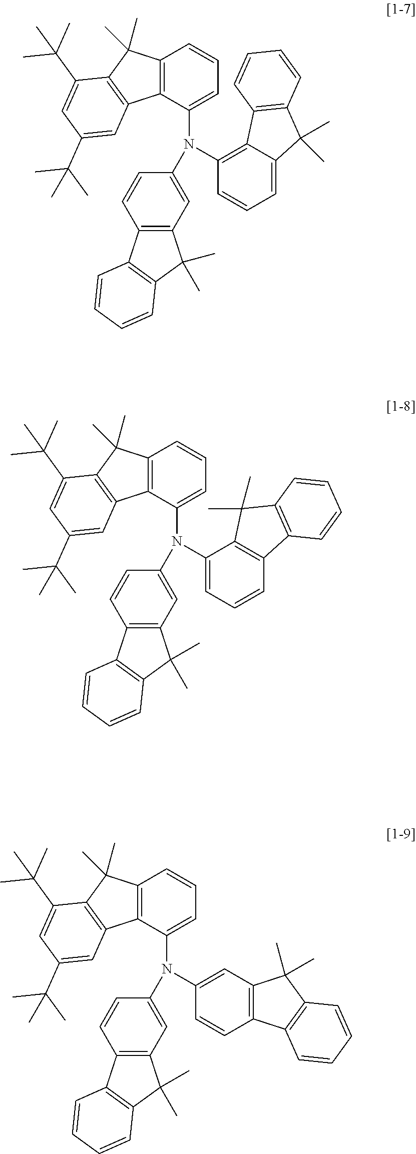

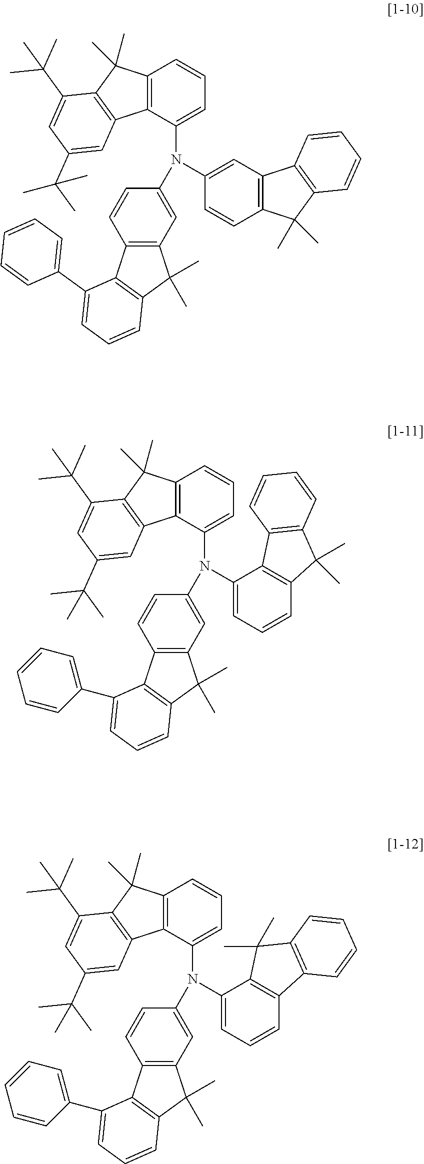 [SMILES: CC(C)(C)c1cc2c(c(C(C)(C)C)c1)C(C)(C)c1cccc(N(c3ccc4c(c3)-c3ccccc3C4(C)C)c3ccc4c(c3)C(C)(C)c3cccc(-c5ccccc5)c3-4)c1-2 ; CC(C)(C)c1cc2c(c(C(C)(C)C)c1)C(C)(C)c1cccc(N(c3ccc4c(c3)C(C)(C)c3cccc(-c5ccccc5)c3-4)c3cccc4c3-c3ccccc3C4(C)C)c1-2 ; CC(C)(C)c1cc2c(c(C(C)(C)C)c1)C(C)(C)c1cccc(N(c3ccc4c(c3)C(C)(C)c3cccc(-c5ccccc5)c3-4)c3cccc4c3C(C)(C)c3ccccc3-4)c1-2]

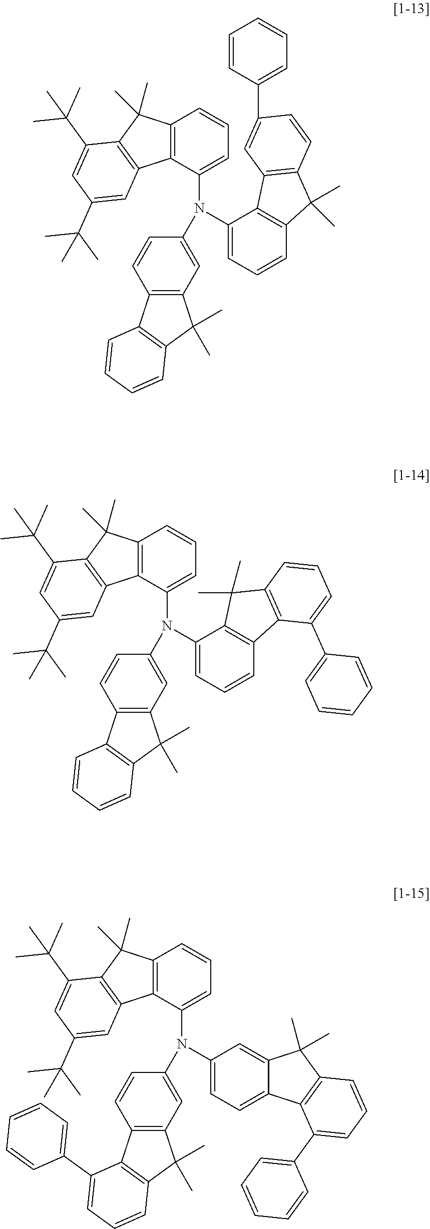

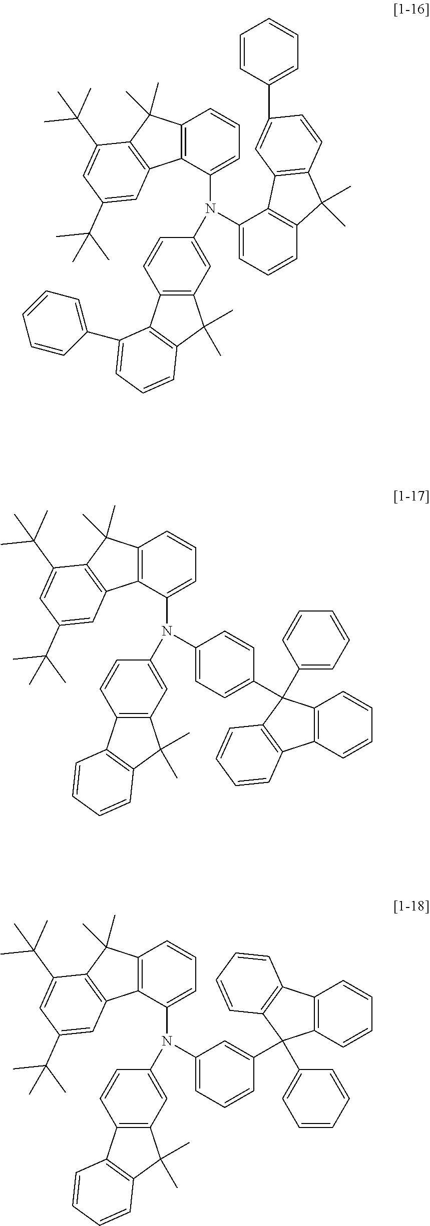

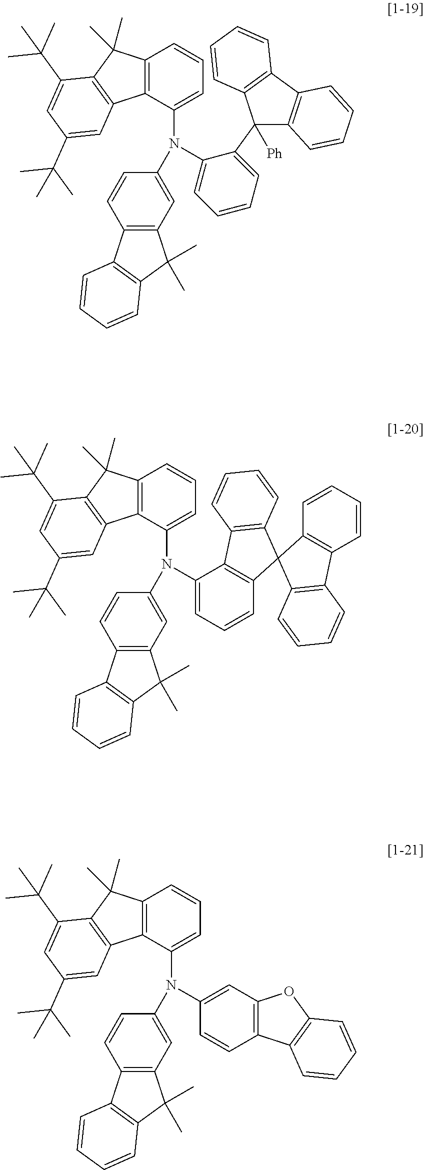 [SMILES: CC(C)(C)c1cc2c(c(C(C)(C)C)c1)C(C)(C)c1cccc(N(c3ccc4c(c3)C(C)(C)c3ccccc3-4)c3ccccc3C3(c4ccccc4)c4ccccc4-c4ccccc43)c1-2 ; CC(C)(C)c1cc2c(c(C(C)(C)C)c1)C(C)(C)c1cccc(N(c3ccc4c(c3)C(C)(C)c3ccccc3-4)c3cccc4c3-c3ccccc3C43c4ccccc4-c4ccccc43)c1-2 ; CC(C)(C)c1cc2c(c(C(C)(C)C)c1)C(C)(C)c1cccc(N(c3ccc4c(c3)C(C)(C)c3ccccc3-4)c3ccc4c(c3)oc3ccccc34)c1-2]

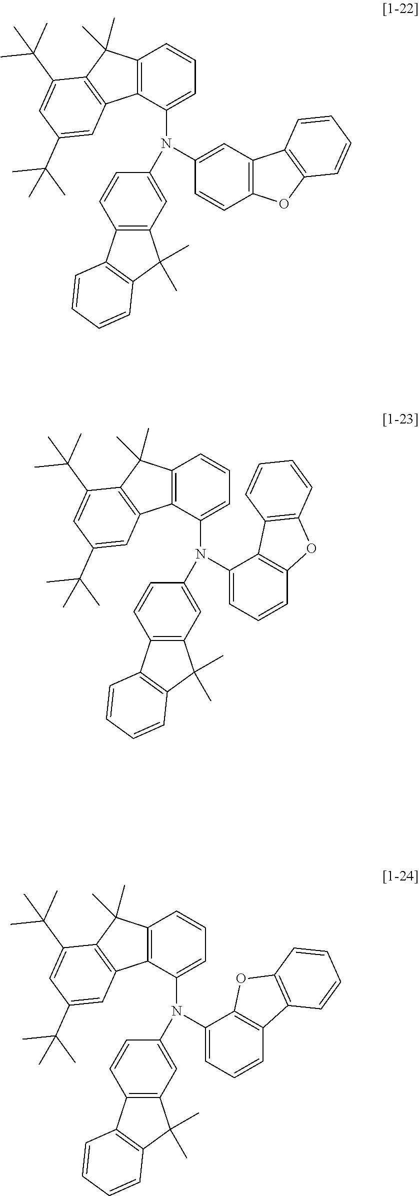 [SMILES: CC(C)(C)c1cc2c(c(C(C)(C)C)c1)C(C)(C)c1cccc(N(c3ccc4c(c3)C(C)(C)c3ccccc3-4)c3ccc4oc5ccccc5c4c3)c1-2 ; CC(C)(C)c1cc2c(c(C(C)(C)C)c1)C(C)(C)c1cccc(N(c3ccc4c(c3)C(C)(C)c3ccccc3-4)c3cccc4oc5ccccc5c34)c1-2 ; CC(C)(C)c1cc2c(c(C(C)(C)C)c1)C(C)(C)c1cccc(N(c3ccc4c(c3)C(C)(C)c3ccccc3-4)c3cccc4c3oc3ccccc34)c1-2]

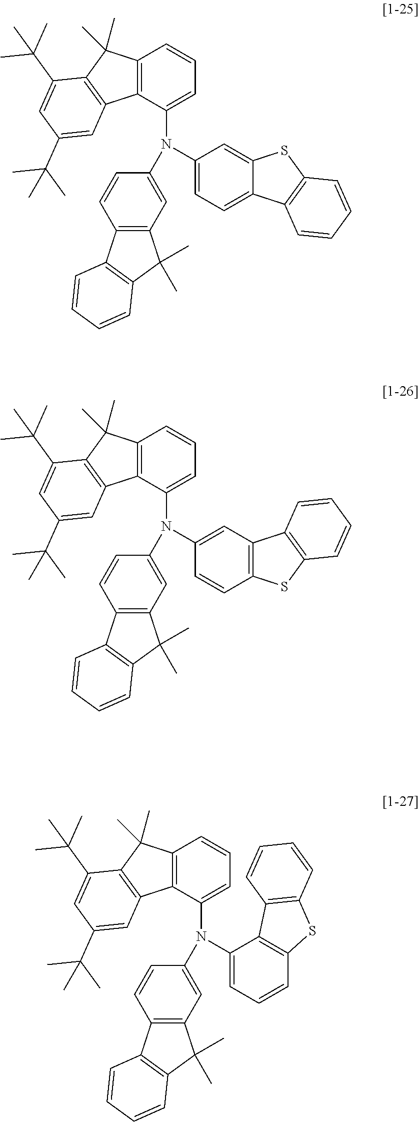 [SMILES: CC(C)(C)c1cc2c(c(C(C)(C)C)c1)C(C)(C)c1cccc(N(c3ccc4c(c3)C(C)(C)c3ccccc3-4)c3ccc4c(c3)sc3ccccc34)c1-2 ; CC(C)(C)c1cc2c(c(C(C)(C)C)c1)C(C)(C)c1cccc(N(c3ccc4c(c3)C(C)(C)c3ccccc3-4)c3ccc4sc5ccccc5c4c3)c1-2 ; CC(C)(C)c1cc2c(c(C(C)(C)C)c1)C(C)(C)c1cccc(N(c3ccc4c(c3)C(C)(C)c3ccccc3-4)c3cccc4sc5ccccc5c34)c1-2]

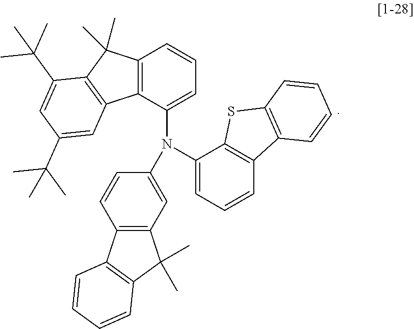 [SMILES: CC(C)(C)c1cc2c(c(C(C)(C)C)c1)C(C)(C)c1cccc(N(c3ccc4c(c3)C(C)(C)c3ccccc3-4)c3cccc4c3sc3ccccc34)c1-2]

7. The organic optoelectronic device as claimed in claim 1, wherein:
the second compound is represented by any one of Chemical Formula 2-1 to Chemical Formula 2-8: 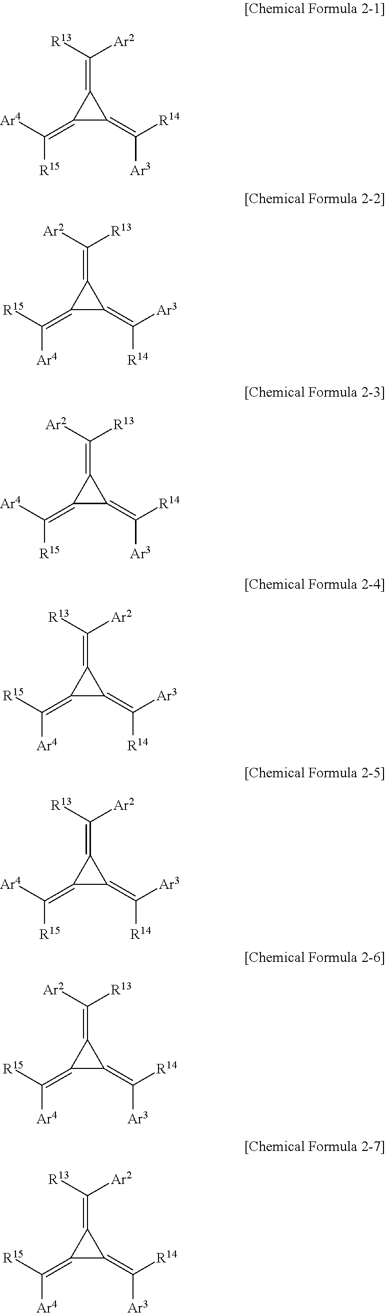 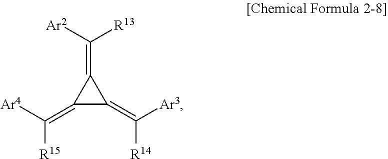
in Chemical Formula 2-1 to Chemical Formula 2-8, Ar² to Ar⁴ and R¹³ to R¹⁵ are the same as defined in claim 1.

8. The organic optoelectronic device as claimed in claim 1, wherein at least one of A¹ to A³ includes at least one of a halogen, a cyano group, and a nitro group.

9. The organic optoelectronic device as claimed in claim 1, wherein at least one of R¹³ to R¹⁵ is at least one of a halogen, a cyano group, and a nitro group.

10. The organic optoelectronic device as claimed in claim 1, wherein at least one of Ar² to Ar⁴ is a C6 to C20 aryl group substituted with at least one of CN, NO₂, F, and a trifluoromethyl group or a C2 to C30 heterocyclic group substituted with at least one of CN, NO₂, F, and a trifluoromethyl group.

11. The organic optoelectronic device as claimed in claim 1, wherein Ar² to Ar⁴ are each independently selected from a substituted or unsubstituted phenyl group, a substituted or unsubstituted biphenyl group, a substituted or unsubstituted naphthyl group, a substituted or unsubstituted pyridyl group, a substituted or unsubstituted pyrimidinyl group, a substituted or unsubstituted triazinyl group, and a substituted or unsubstituted pyrazinyl group.

12. The organic optoelectronic device as claimed in claim 1, wherein:
at least one of R¹³ to R¹⁵ is a cyano group or a nitro group, and
at least one of Ar² to Ar⁴ is a phenyl group substituted with at least one of CN, NO₂, F, and a trifluoromethyl group; a biphenyl group substituted with at least one of CN, NO₂, F, and a trifluoromethyl group; a naphthyl group substituted with at least one of CN, NO₂, F, and a trifluoromethyl group; a pyridyl group substituted with at least one of CN, NO₂, F, and a trifluoromethyl group; a pyrimidinyl group substituted with at least one of CN, NO₂, F, and a trifluoromethyl group; a triazinyl group substituted with at least one of CN, NO₂, F, and a trifluoromethyl group; or a pyrazinyl group substituted with at least one of CN, NO₂, F, and a trifluoromethyl group.

13. The organic optoelectronic device as claimed in claim 1, wherein at least one of Ar² to Ar⁴ is represented by Chemical Formula I-1: 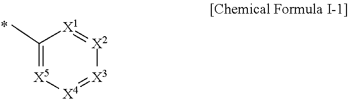
wherein, in Chemical Formula I-1,
X¹ to X⁵ are each independently N or CR^{a},
R^{a} are each independently hydrogen, deuterium, fluoro, a trifluoro group, a cyano group, or a nitro group, and
* is a linking point.

14. The organic optoelectronic device as claimed in claim 13, wherein R¹³ to R¹⁵ are each a cyano group.

15. The organic optoelectronic device as claimed in claim 1, wherein:
Ar² to Ar⁴ are each independently selected from substituents listed in Group I: 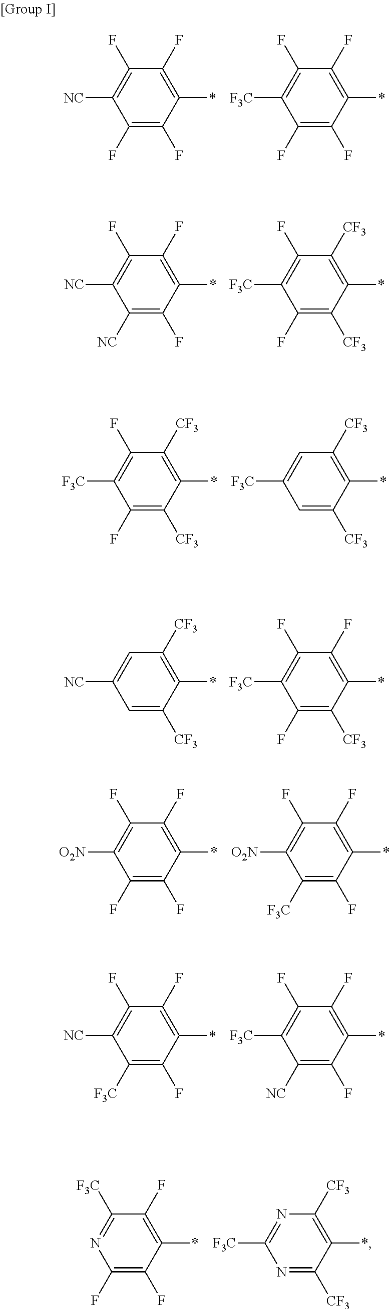
and
in Group I, * is a linking point.

16. The organic optoelectronic device as claimed in claim 1, wherein the second compound is one selected from compounds listed in Group 2:

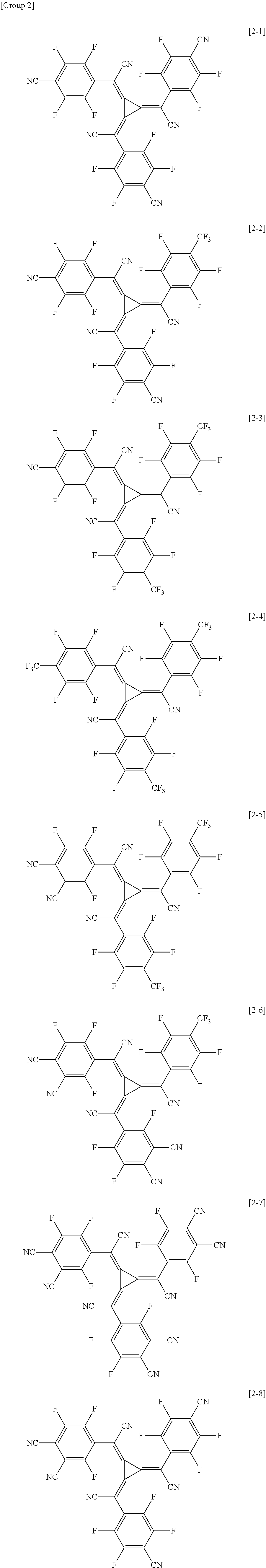

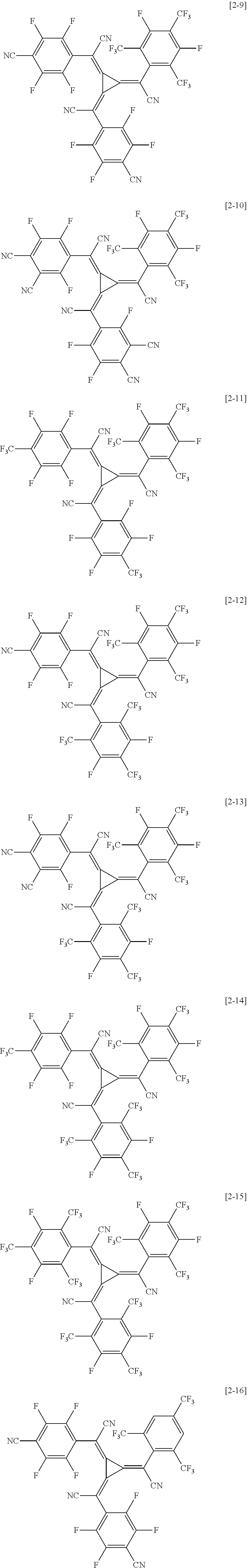

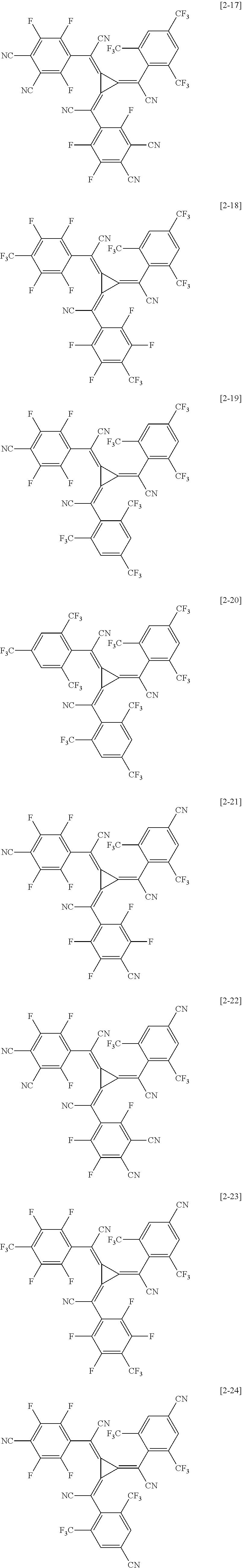

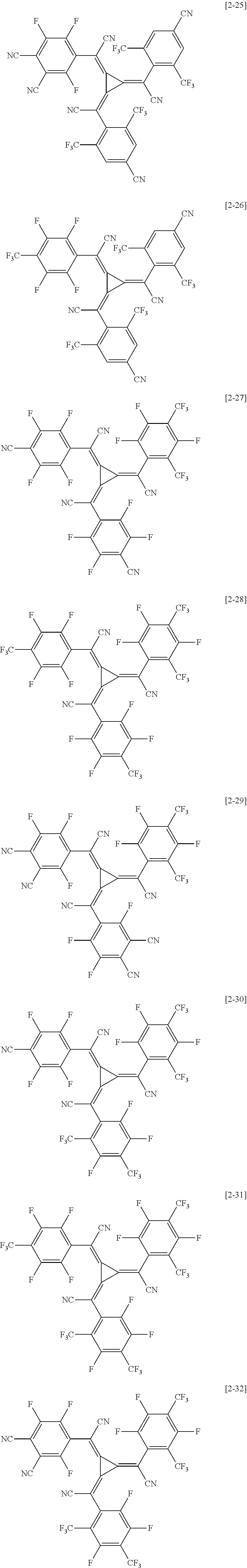

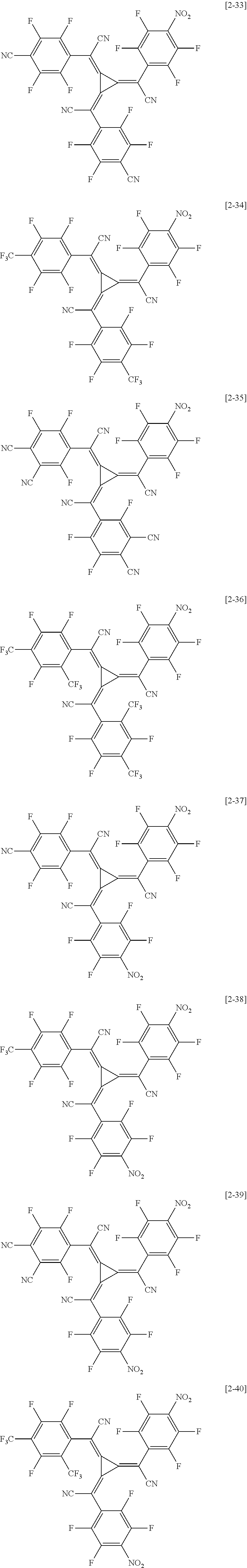

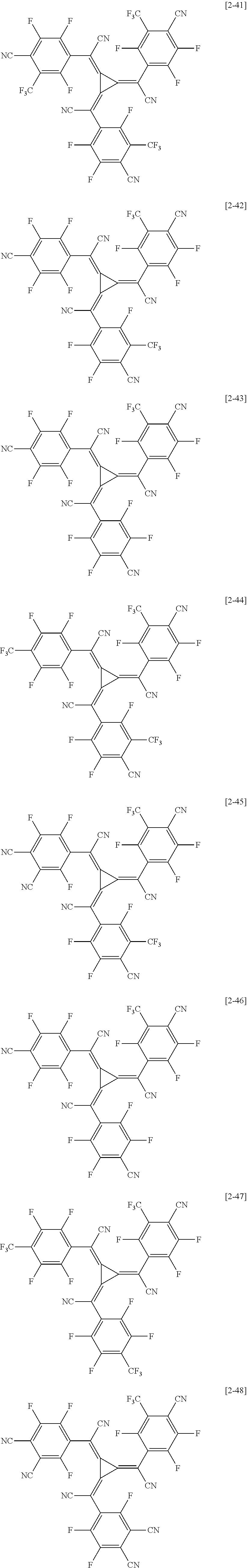

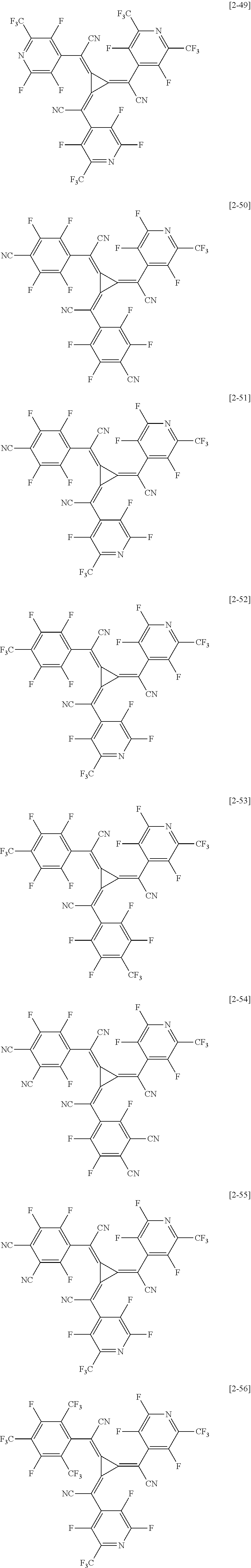

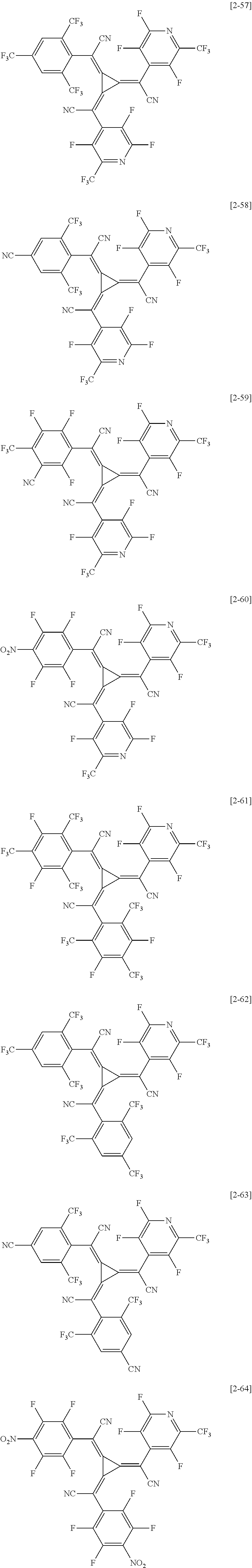

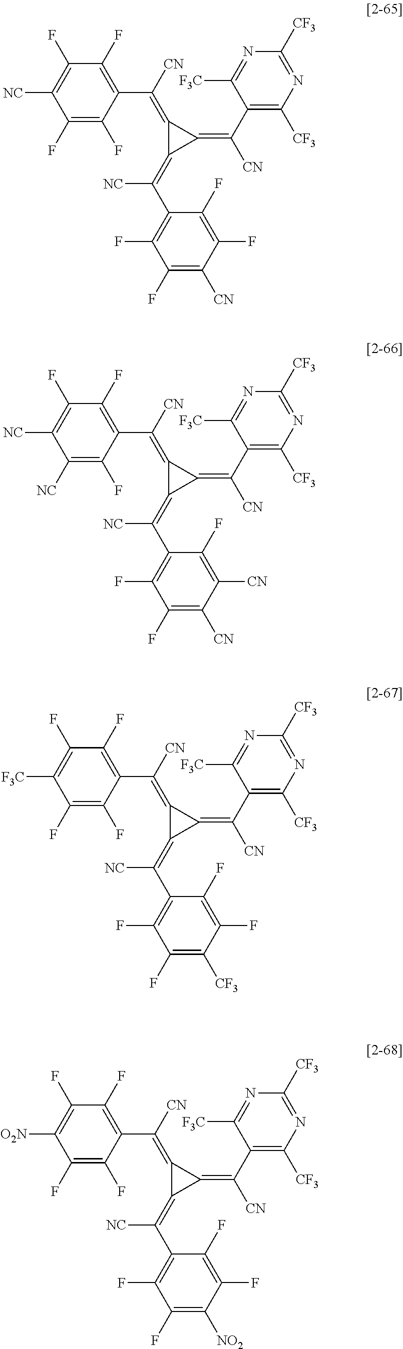

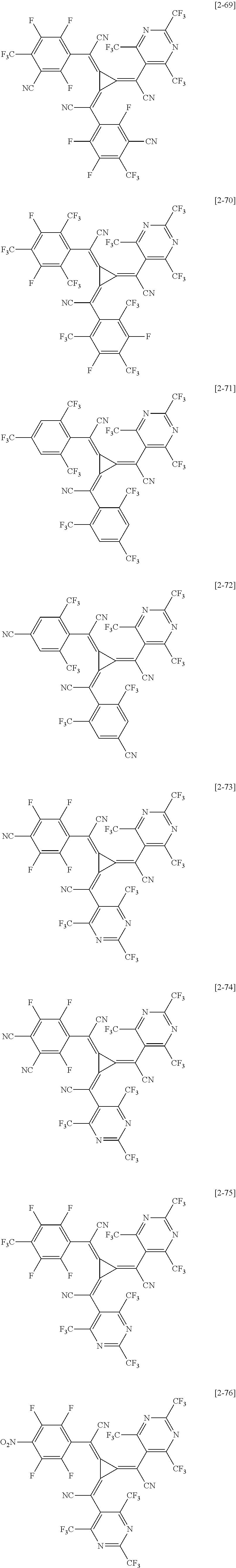

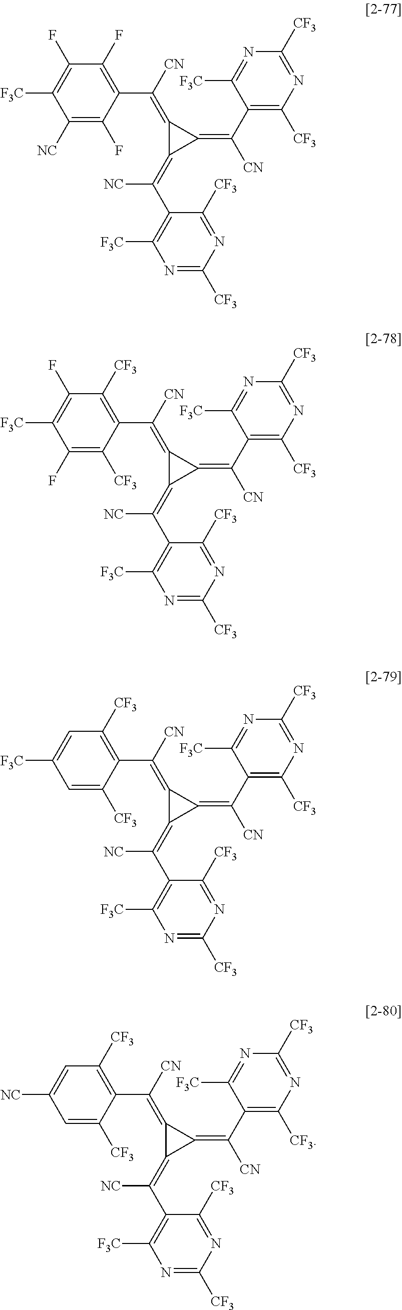

17. The organic optoelectronic device as claimed in claim 1, wherein the first wavelength is greater than or equal to about 420 nm and less than or equal to about 480 nm, and the second wavelength greater than or equal to about 520 nm and less than or equal to about 600 nm.

18. The organic optoelectronic device as claimed in claim 1, further comprising:
a first stack and a second stack are between the anode and the cathode, the first stack including the first light emitting layer, and the second stack including the second light emitting layer;
at least one charge generation layer between the first stack and the second stack; and
an intermediate hole transport region and an intermediate electron transport region between the first light emitting layer and the second light emitting layer.

19. The organic optoelectronic device as claimed in claim 18, further comprising at least one additional stack including an additional light emitting layer that between the first light emitting layer and the second light emitting layer, the additional light emitting layer being configured to emit light of the first wavelength.

20. A display device comprising the organic optoelectronic device according to claim 1.
